(19) United States
(12) Patent Application Publication
(10) Pub. No.: US 2023/0397396 A1
(43) Pub. Date: Dec. 7, 2023

(54) 3D MEMORY CELLS AND ARRAY ARCHITECTURES

(71) Applicant: NEO Semiconductor, Inc., San Jose, CA (US)

(72) Inventor: Fu-Chang Hsu, San Jose, CA (US)

(21) Appl. No.: 18/366,617

(22) Filed: Aug. 7, 2023

Related U.S. Application Data
(63) Continuation-in-part of application No. 17/937,432, filed on Sep. 30, 2022.
(60) Provisional application No. 63/403,775, filed on Sep. 4, 2022.
(60) Provisional application No. 63/403,853, filed on Sep. 5, 2022.
(60) Provisional application No. 63/406,255, filed on Sep. 14, 2022.
(60) Provisional application No. 63/407,145, filed on Sep. 15, 2022.
(60) Provisional application No. 63/409,220, filed on Sep. 23, 2022.
(60) Provisional application No. 63/418,698, filed on Oct. 24, 2022.
(60) Provisional application No. 63/419,161, filed on Oct. 25, 2022.
(60) Provisional application No. 63/434,026, filed on Dec. 20, 2022.
(60) Provisional application No. 63/523,071, filed on Jun. 24, 2023.
(60) Provisional application No. 63/398,807, filed on Aug. 17, 2022.
(60) Provisional application No. 63/295,874, filed on Jan. 1, 2022.
(60) Provisional application No. 63/291,380, filed on Dec. 18, 2021.
(60) Provisional application No. 63/254,841, filed on Oct. 12, 2021.
(60) Provisional application No. 63/251,583, filed on Oct. 1, 2021.
(60) Provisional application No. 63/429,397, filed on Dec. 1, 2022.

(51) Int. Cl. H10B 12/00

(52) U.S. Cl. CPC H10B 12/20

(57) ABSTRACT

Various 3D memory cells, array architectures, and processes are disclosed. In an embodiment, a three-dimensional (3D) stackable memory cell structure is provided that includes a first material, a floating body semiconductor material that surrounds a first portion of the first material, a second material that surrounds a portion of the floating body semiconductor material, and a front gate material. The 3D stackable memory cell structure also includes a first dielectric layer located between the front gate material and the floating body semiconductor material, a back gate material, a second dielectric layer located between the back gate material and the floating body semiconductor material, and a second semiconductor material that surrounds a second portion of the first material and is directly connected to the floating body semiconductor material.

### CROSS-REFERENCE TO RELATED APPLICATIONS

This application is a continuation-in-part (CIP) of U.S. patent application having application Ser. No. 17/937,432 filed on Sep. 30, 2022, and entitled “3D Memory Cells and Array Architectures.”

This application claims the benefit of priority under 35 U.S.C. 119(e) based upon U.S. Provisional patent application having Application No. 63/406,255 filed on Sep. 14, 2022, and entitled “3D Cell and Array Architectures,” and U.S. Provisional patent application having Application No. 63/403,775 filed on Sep. 4, 2022, and entitled “3D Cell and Array Structures,” and U.S. Provisional patent application having Application No. 63/403,853 filed on Sep. 5, 2022, and entitled “3D Cell and Array Structures,” and U.S. Provisional patent application having Application No. 63/407,145 filed on Sep. 15, 2022, and entitled “3D Cell and Array Structures,” and U.S. Provisional patent application having Application No. 63/409,220 filed on Sep. 23, 2022, and entitled “3D Cell and Array Structures,” and U.S. Provisional patent application having Application No. 63/418,698 filed on Oct. 24, 2022, and entitled “3D Cell and Array Structures,” and U.S. Provisional patent application having Application No. 63/419,161 filed on Oct. 25, 2022, and entitled “3D Cell and Array Structures,” and U.S. Provisional patent application having Application No. 63/429,397 filed on Dec. 1, 2022, and entitled “3D Cell and Array Structures,” and U.S. Provisional patent application having Application No. 63/434,026 filed on Dec. 20, 2022, and entitled “3D Cell and Array Structures,” and U.S. Provisional patent application having Application No. 63/523,071 filed on Jun. 24, 2023, and entitled “3D Cell and Array Structures, all of which are hereby incorporated herein by reference in their entireties.

The application Ser. No. 17/937,432 claims the benefit of priority under 35 U.S.C. 119(e) based upon U.S. Provisional patent application having Application No. 63/398,807 filed on Aug. 17, 2022, and entitled “Memory Cell and Array Architectures and Operation Conditions,” and U.S. Provisional patent application having Application No. 63/295,874 filed on Jan. 1, 2022, and entitled “Alpha-RAM (a-RAM) or Alpha-DRAM (a-DRAM) Technology,” and U.S. Provisional patent application having Application No. 63/291,380 filed on Dec. 18, 2021 and entitled “3D DRAM-replacement Technologies,” and U.S. Provisional patent application having Application No. 63/254,841, filed on Oct. 12, 2021 and entitled “3D DRAM-replacement Technologies,” and U.S. Provisional patent application having Application No. 63/251,583 filed on Oct. 1, 2021 and entitled “3D DRAM-replacement Technologies,” all of which are hereby incorporated herein by reference in their entireties.

### FIELD OF THE INVENTION

The exemplary embodiments of the present invention relate generally to the field of memory, and more specifically to memory cells and array structures and associated processes.

### BACKGROUND OF THE INVENTION

With the increasing complexity and density of electronic circuits, memory size, complexity, and cost are important considerations. One approach to increase memory capacity is to use three-dimensional (3D) array structure. The 3D array structure has been successfully used in NAND flash memory today. However, for dynamic random-access memory (DRAM), due to its special one-transistor-one-capacitor (1T1C) cell structure, a cost-effective 3D array structure has not been realized.

### SUMMARY

In various exemplary embodiments, three-dimensional (3D) memory cells, array structures, and associated processes are disclosed. In one embodiment, a novel 3D array structure using floating-body cells to implement DRAM is disclosed. The array structure is formed using a deep trench process similar to 3D NAND flash memory. Therefore, ultra-high-density DRAM can be realized. In one embodiment, 3D NOR-type memory cells and array structures are provided. The disclosed memory cells and array structures are applicable to many technologies. For example, the inventive memory cells and array structures are applicable to dynamic random-access memory (DRAM), floating-body cell (FBC) memory, NOR-type flash memory, and thyristors.

In an exemplary embodiment, a memory cell structure is provided that includes a first semiconductor material, a floating body semiconductor material having an internal side surface that surrounds and connects to the first semiconductor material, and a second semiconductor material having an internal side surface that surrounds and connects to the floating body semiconductor material. The memory cell structure also includes a first dielectric layer connected to a top surface of the floating body material, a second dielectric layer connected to a bottom surface of the floating body material, a front gate connected to the first dielectric layer, and a back gate connected to the second dielectric layer.

In an exemplary embodiment, a three-dimensional (3D) memory array is provided that comprises a plurality of memory cells separated by a dielectric layer to form a stack of memory cells. Each memory cell in the stack of memory cells comprises a bit line formed from one of a first semiconductor material and a first conductor material, a floating body semiconductor material having an internal side surface that surrounds and connects to the bit line, a source line formed from one of a second semiconductor material and a second conductor material having an internal side surface that surrounds and connects to the floating body semiconductor material, and a word line formed from a third conductor material that is coupled to the floating body semiconductor through the dielectric layer to form a gate of the memory cell. Additionally, the bit lines of the stack of memory cells are connected to form a vertical bit line.

In an embodiment, a three-dimensional (3D) stackable memory cell structure is provided that comprises a first material, a floating body semiconductor material that surrounds a first portion of the first material, a second material that surrounds a portion of the floating body semiconductor material, and a front gate material. The 3D stackable memory cell structure also comprises a first dielectric layer located between the front gate material and the floating body semiconductor material, a back gate material, a second dielectric layer located between the back gate material and the floating body semiconductor material, and a second semiconductor material that surrounds a second portion of the first material and is directly connected to the floating body semiconductor material.

In an embodiment, a three-dimensional (3D) stackable memory cell structure is provided that comprises a first material, an insulating layer that surrounds a first portion of the first material, a first floating body semiconductor material that surrounds a second portion of the first material and is located above the insulating layer, and a second floating body semiconductor material that surrounds a third portion of the first material and is located below the insulating layer. The three-dimensional (3D) stackable memory cell structure also comprises a second material that surrounds the first floating body semiconductor material, a third material that surrounds the second floating body semiconductor material, a front gate, a first dielectric layer located between the front gate and the first floating body semiconductor material, a back gate, and a second dielectric layer located between the back gate and the second floating body semiconductor material.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIG. 1A show an exemplary embodiment of a three-dimensional (3D) NOR-type memory cell structure using a floating body cell (FBC) configuration in accordance with the invention.

FIG. 1B shows the cell structure shown in FIG. 1A with a front gate and a gate dielectric layer removed.

FIG. 1C shows a cell formed using a PMOS transistor.

FIG. 1D shows an embodiment of an array structure based on the cell structure shown in FIG. 1A.

FIG. 1E shows another embodiment of an array structure according to the invention.

FIG. 1F shows an equivalent circuit diagram for the array structure shown in FIG. 1D.

FIG. 1G shows another embodiment of an equivalent circuit diagram of the array structure shown in FIG. 1D.

FIGS. 1H-I show embodiments of a junction-less transistor cell structure according to the invention.

FIGS. 1J-K show embodiments of a tunnel field-effect transistor (T-FET) cell structure according to the invention.

FIG. 1L shows another embodiment of the cell structure according to the invention that uses a metal bit line and source line.

FIG. 1M shows embodiments of a thin-film structure and an indium-gallium-zinc-oxide (IGZO) transistor cell structure according to the invention.

FIG. 2A shows an embodiment of a write data ‘1’ condition of the cell according to the invention.

FIG. 2B shows another embodiment of a write data ‘1’ condition of the cell according to the invention.

FIG. 2C shows an embodiment of a write data ‘0’ condition of the cell according to the invention.

FIG. 2D shows an exemplary waveform of the write data ‘0’ condition according to the invention.

FIG. 3A shows a threshold voltage (Vt) of the cell data ‘0’ and data ‘1’.

FIG. 3B shows how a threshold voltage of the cell transistors to become negative.

FIG. 3C shows a special read condition to address issues illustrated in FIG. 3B.

FIG. 3D shows a table that summarizes the bias conditions of write data ‘1’, write data ‘0’, and read operations.

FIGS. 4A-F show simplified process steps for constructing the array structure shown in FIG. 3.

FIGS. 4G-H show additional embodiments of array structures according to the invention.

FIGS. 4I-J show another embodiment of process steps to form the body of the transistors.

FIG. 4K shows an embodiment of the bit line connection of the array structure shown in FIG. 4F.

FIG. 4L shows another embodiment of the array structure according to the invention to solve the previously mentioned issue with using many word line decoders.

FIG. 4M shows the bit line connections of the array embodiment shown in FIG. 4L.

FIG. 4N shows another embodiment of an array architecture according to the invention.

FIG. 4O shows an embodiment of a non-volatile program operation to write data stored in floating bodies and to a charge-trapping layer.

FIG. 4P shows another embodiment of a 3D floating body cell array structure according to the invention.

FIG. 4Q shows a write ‘0’ condition of the array structure embodiment shown in FIG. 4P.

FIG. 4R shows an embodiment of write ‘0’ waveforms.

FIG. 4S shows bias conditions of write data ‘1’, write data ‘0’, and read operations for the array embodiment shown in FIG. 4P.

FIGS. 4T-Z show an embodiment of process steps to form the cell array structure shown in FIG. 4P.

FIG. 5A shows another embodiment of a cell structure according to the invention.

FIG. 5B shows the cell structure of FIG. 5A with a front gate and a gate dielectric layer removed.

FIGS. 5C-D show another embodiment of a cell structure according to the invention.

FIG. 6A shows another embodiment of a cell structure according to the invention.

FIG. 6B shows the cell structure shown in FIG. 6A with a front gate and gate dielectric layer removed.

FIGS. 6C-D show another embodiment of a cell structure according to the invention.

FIG. 7 shows an embodiment of an array structure based on the cell structure shown in FIG. 6A.

FIGS. 8A-F show simplified process steps for forming the array structure shown in FIG. 7.

FIG. 9A shows another embodiment of a cell structure according to the invention.

FIG. 9B shows an embodiment of an array structure based on the cell structure shown in FIG. 9A.

FIGS. 10A-D show simplified process steps for constructing the cell structure shown in FIG. 9A.

FIG. 11A shows another embodiment of a cell structure according to the invention.

FIG. 11B shows an embodiment of an array structure based on the cell structure shown in FIG. 11A.

FIGS. 12A-D shows simplified process steps for constructing the cell structure shown in FIG. 11A.

FIG. 13A shows another embodiment of a DRAM-replacement technology according to the invention.

FIG. 13B shows the cell structure of FIG. 13A with a front gate and a gate dielectric layer removed.

FIG. 13C shows another embodiment of a 3D thyristor cell structure according to the invention.

FIG. 14A shows a circuit diagram in which two bipolar transistors form a gate-assisted thyristor cell.

FIG. 14B shows a circuit diagram that forms a non-gate-assisted thyristor cell.

FIG. 14C shows a current to voltage (I-V) curve of the thyristor cell shown in FIG. 13A.

FIG. 15A shows an embodiment of a 3D array structure based on the cell structure shown in FIG. 13A.

FIG. 15B shows an embodiment of a 3D array structure based on the cell structure shown in FIG. 13C.

FIG. 16A shows another embodiment of a thyristor cell structure according to the invention.

FIG. 16B shows the cell structure shown in FIG. 16A with a front gate and a gate dielectric layer removed.

FIG. 16C shows another embodiment of a thyristor cell structure according to the invention.

FIG. 17A shows an embodiment of a 3D array structure based on the cell structure shown in FIG. 16A.

FIG. 17B shows an embodiment of a 3D array structure based on the cell structure shown in FIG. 16C.

FIG. 18A shows another embodiment of a thyristor cell structure according to the invention.

FIG. 18B shows an embodiment of a 3D array structure based on the cell structure shown in FIG. 16C.

FIG. 19A shows another embodiment of a 3D array structure according to the invention that uses ‘tunnel field-effect transistor (TFET)’ technology.

FIG. 19B shows a cross-section of the array structure shown in FIG. 19A that is taken at cross-section indicator A-A′ to reveal the structure of an insulating layer.

FIG. 20A shows a vertical cross section view of the 3D array structure shown in FIG. 19A.

FIG. 20B shows another embodiment of the vertical cross section view of the 3D array structure shown in FIG. 19A.

FIG. 20C shows another embodiment of the vertical cross section view of the 3D array structure according to the invention.

FIG. 21A shows another embodiment of the 3D array structure according to the invention.

FIG. 21B shows another embodiment of the 3D array structure according to the invention.

FIG. 21C shows another embodiment of a 3D array structure according to the invention.

FIG. 21D shows another embodiment of a 3D array structure according to the invention.

FIG. 22A shows another embodiment of a 3D cell structure according to the invention.

FIG. 22B shows an inner structure of the 3D cell structure shown in FIG. 22A.

FIG. 23A shows another embodiment of a 3D cell structure according to the invention.

FIG. 23B shows the inner structure of the 3D cell structure shown in FIG. 23A.

FIG. 24A shows another embodiment of the 3D cell structure according to the invention.

FIG. 24B shows the inner structure of the 3D cell structure shown in FIG. 24A.

FIG. 25A shows another embodiment of 3D cell structure according to the invention.

FIG. 25B shows an inner structure of the 3D cell structure shown in FIG. 25A.

FIGS. 26A-G shows simplified key process steps of another embodiment of a floating body cell “AND” array according to the invention.

FIG. 27A shows an embodiment of a floating body cell structure constructed according to the invention.

FIG. 27B shows an embodiment of a floating body cell structure that provides a lower intrinsic threshold voltage or lower band-to-band voltage.

FIG. 28A shows an embodiment of a 3D cell structure using a “thin-film transistor (TFT)” structure according to the invention.

FIG. 28B shows an embodiment of the 3D array structure using the cell structure shown in FIG. 28A.

FIG. 29A shows embodiments of a charge trapping layer.

FIG. 29B shows another embodiment of a cell structure constructed according to the invention.

FIG. 30A shows an embodiment of a cell structure in which a charge-trapping layer comprises multiple layers.

FIG. 30B shows an equivalent circuit of the cell shown in FIG. 30A.

FIG. 30C shows an embodiment of programing operations using channel hot electron (CHE) injection for use with the cell structure shown in FIG. 30A.

FIG. 30D shows an embodiment of erase operations using hot-hole injection (HHI) for use with the cell structure shown in FIG. 30A.

FIG. 30E shows an embodiment of non-volatile program operations for use with the cell structure shown in FIG. 30A.

FIG. 31A shows another embodiment of a cell structure for a 3D NOR-type array using ferroelectric field-effect transistors (FeFET) according to the invention.

FIG. 31B shows an equivalent circuit of the cell shown in FIG. 31A.

FIG. 32A show another embodiment of a cell structure for a 3D NOR-type array for ferroelectric random-access memory (FRAM) according to the invention.

FIG. 32B shows the equivalent circuit of the cell structure shown in FIG. 32A.

FIG. 32C shows an equivalent circuit of the cell structure for RRAM and PCM embodiments.

FIG. 32D shows an equivalent circuit of the cell structure for the MRAM embodiment.

FIGS. 33A-F show another embodiment of cell structures according to the invention.

FIG. 34A shows another embodiment of a “floating-gate” cell structure for a 3D NOR-type flash memory according to the invention.

FIG. 34B shows an equivalent circuit of the cell shown in FIG. 34A.

FIG. 35A shows another embodiment of a cell structure according to the invention.

FIGS. 35B-C show cross-section views of the cell shown in FIG. 35A taken along line A-A′ and line B-B′, respectively.

FIG. 36A shows another embodiment of the cell structure constructed according to the invention.

FIGS. 36B-C show cross-section views of the cell structure shown in FIG. 36A taken along line A-A′ and line B-B′, respectively.

FIG. 37A shows another embodiment of a cell structure constructed according to the invention.

FIGS. 37B-C show cross-section views of the cell structure shown in FIG. 37A taken along line A-A′ and line B-B′, respectively.

FIG. 38A shows an equivalent circuit of the embodiments of the cell structures shown in FIG. 35A to FIG. 37C.

FIG. 38B shows an equivalent circuit of the cell structures shown in FIG. 39C to FIG. 40C according to the invention.

FIG. 39A shows another embodiment of a cell structure according to the invention.

FIGS. 39B-C show cross-section views of the cell shown in FIG. 39A taken along line A-A′ and line B-B′, respectively.

FIG. 40A shows another embodiment of a cell structure according to the invention.

FIGS. 40B-C show cross-section views of the cell shown in FIG. 40A taken along line A-A′ and line B-B′, respectively.

FIG. 41A show another embodiment of a 3D ferroelectric memory cell constructed according to the invention.

FIG. 41B shows the cell structure of FIG. 41A with layers removed to show the inner structure of the cell.

FIG. 41C shows another embodiment of a cell structure according to the invention.

FIG. 41D shows the cell structure of FIG. 41C with layers removed to show the inner structure of the cell.

FIG. 41E shows another embodiment of a 3D ferroelectric memory cell constructed according to the invention.

FIG. 41F shows another embodiment of a 3D ferroelectric memory cell constructed according to the invention.

FIG. 42A shows an embodiment of an equivalent circuit of the cell structure shown in FIG. 41C.

FIG. 42B shows an embodiment of an equivalent circuit of the cell structure shown in FIG. 41E.

FIG. 43A shows another embodiment of a floating-body cell structure constructed according to the invention.

FIG. 43B shows a cross section view of the cell structure shown in FIG. 43A taken along line A-A′.

FIG. 43C shows another embodiment of a floating-body cell structure constructed according to the invention.

FIG. 44A shows another embodiment of a floating-body cell structure constructed according to the invention.

FIG. 44B shows another embodiment of a floating-body cell structure constructed according to the invention.

FIG. 45A shows another embodiment of a floating-body cell structure constructed according to the invention.

FIG. 45B shows another embodiment of a floating-body cell structure constructed according to the invention.

FIG. 46A shows another embodiment of a floating-body cell structure constructed according to the invention using a tunnel field-effect transistor (T-FET).

FIGS. 46B-C show cross section views of the cell shown in FIG. 46A taken along line A-A′ and line B-B′, respectively.

FIG. 47A shows another embodiment of a floating-body cell structure constructed according to the invention.

FIG. 47B shows another embodiment of a floating-body cell structure constructed according to the invention.

FIG. 47C shows another embodiment of a floating-body cell structure constructed according to the invention.

FIG. 48A shows another embodiment of a floating-body cell structure constructed according to the invention.

FIG. 48B shows another embodiment of a floating-body cell structure constructed according to the invention using tunnel field-effect transistor (T-FET).

FIG. 48C shows another embodiment of a floating-body cell structure constructed according to the invention using tunnel field-effect transistor (T-FET).

FIG. 48D shows another embodiment of a floating-body cell structure constructed according to the invention using tunnel field-effect transistor (T-FET).

FIG. 49A shows another embodiment of a floating-body cell structure according to the invention using a double-gate, the traditional type of transistor or tunnel field-effect transistor (T-FET).

FIGS. 49B-C show cross-section views of the cell shown in FIG. 49 taken along line A-A′ and line B-B′, respectively.

FIGS. 50A-H show additional embodiments of 3D cell structures constructed according to the invention.

FIGS. 51A-D show additional embodiments of 3D cell structures constructed according to the invention.

FIGS. 52A-F show additional embodiments of 3D cell structures constructed according to the invention.

FIGS. 53A-F show additional embodiments of 3D cell structures constructed according to the invention.

FIG. 54A shows another embodiment of a cell structure constructed according to the invention.

FIG. 54B shows the cell structure shown in FIG. 54A with selected layers removed to show the structure of inner layers.

FIG. 55A shows another embodiment of a ‘split-gate’ cell structure constructed according to the invention.

FIG. 55B shows the cell structure of the cell shown in FIG. 55A with selected layers removed to show the structure of inner layers.

FIG. 56A shows another embodiment of a floating body cell structure constructed according to the invention.

FIG. 56B shows another embodiment of a floating body cell structure constructed according to the invention.

FIG. 56C shows a 3D cell structure of the cell embodiment shown in FIG. 56B.

FIG. 57A shows another embodiment of a cell structure constructed according to the invention.

FIG. 57B shows the cell structure of FIG. 57A with selected layers removed.

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

In various exemplary embodiments, three-dimensional (3D) memory cells, array structures, and associated processes are disclosed. The disclosed memory cells and array structures are applicable to many technologies. For example, the inventive memory cells and array structures are applicable to dynamic random-access memory (DRAM), floating-body cell (FBC) memory, NOR-type flash memory, and thyristors.

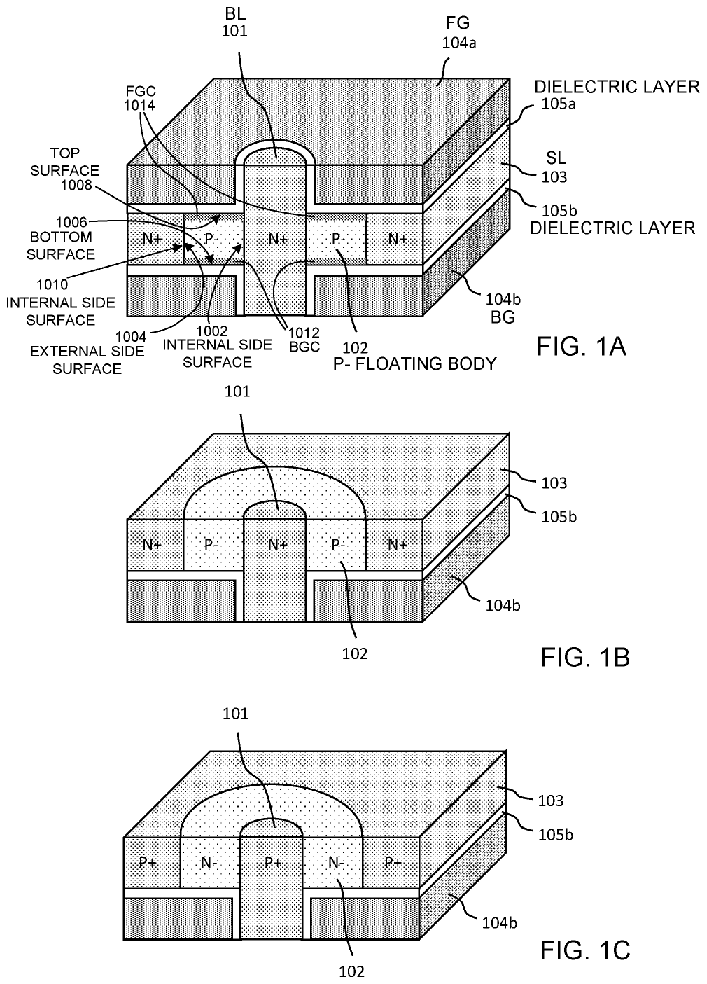

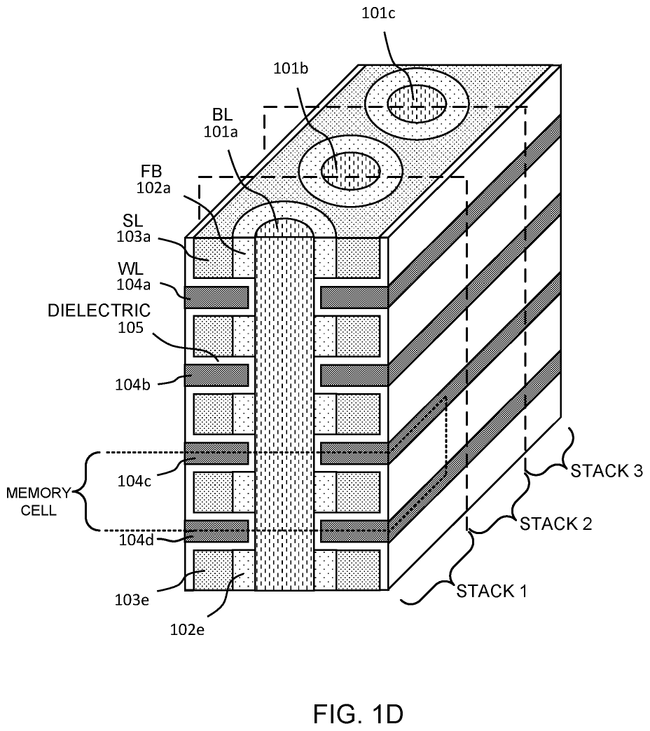

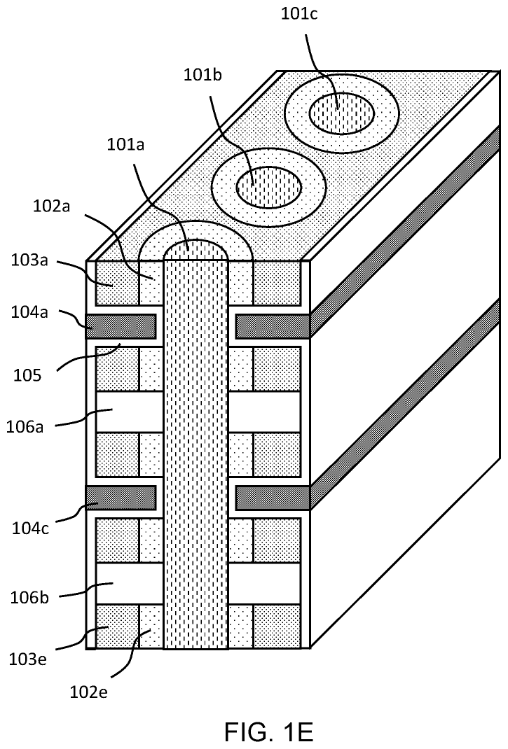

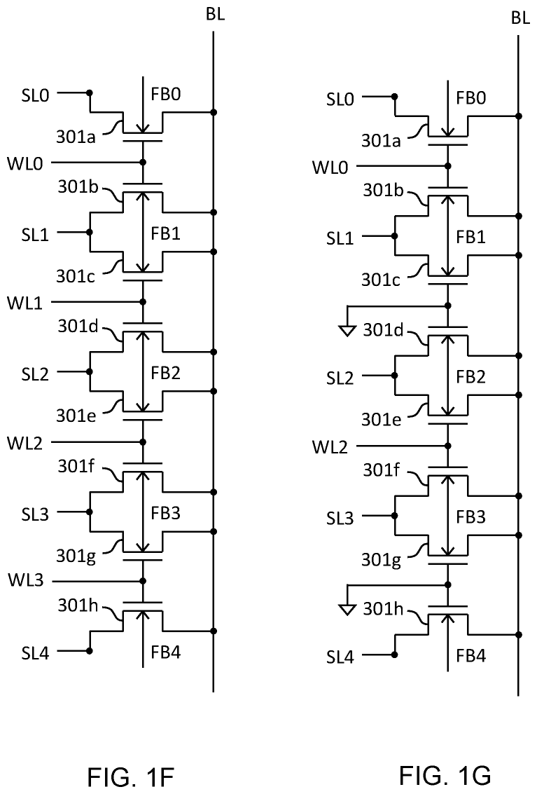

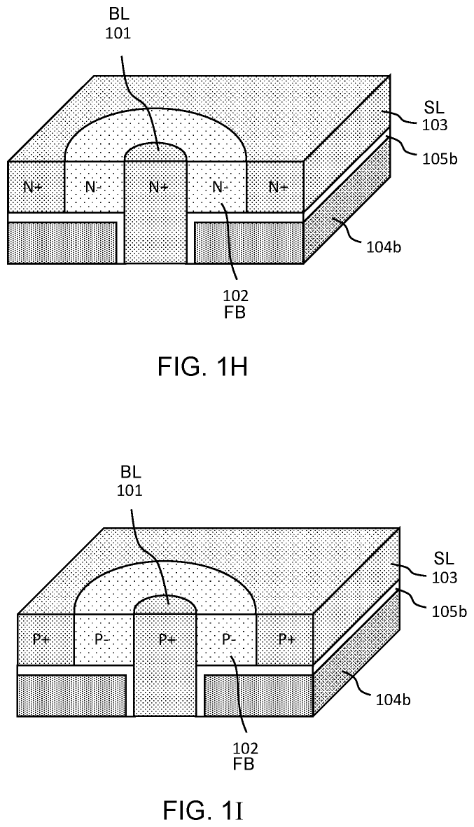

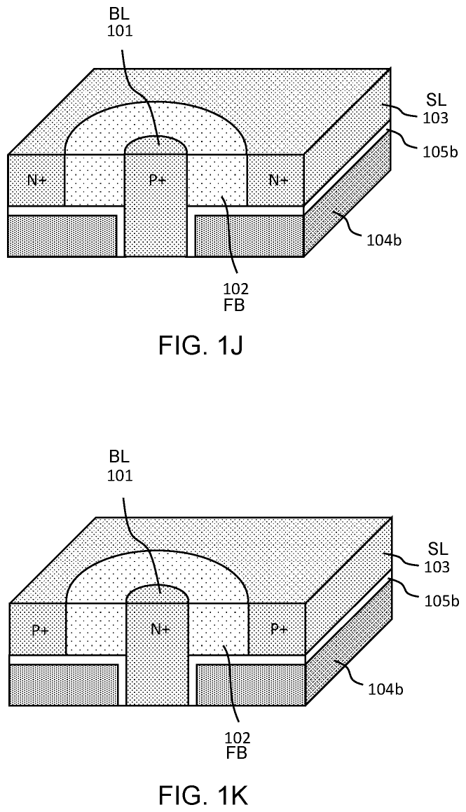

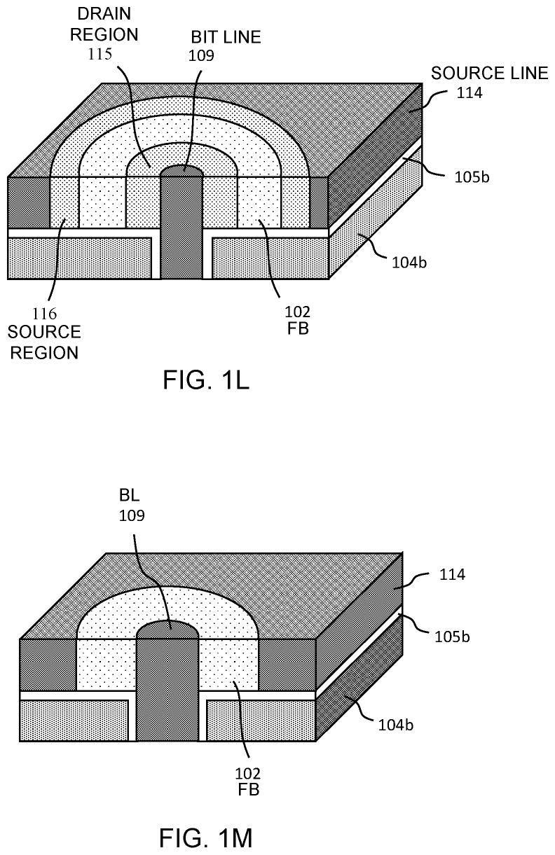

FIG. 1A show an exemplary embodiment of a three-dimensional (3D) NOR-type memory cell structure using a floating body cell (FBC) configuration in accordance with the invention. The 3D NOR-type array may comprise multiple layers of floating-body cell arrays to increase the memory capacity. A floating-body cell is basically a transistor with floating body. The floating body may store electric charges such as electrons or holes to represent the data. The cell structure may comprise a control gate, a drain, a source, and a floating body. In the 3D memory array, the control gate, drain, and source of the cells are connected to word line (WL), bit line (BL), and source line (SL), respectively.

In the cell structure, an N+ silicon or polysilicon forms a bit line (BL) 101 and a P− floating body 102 is used for charge storage. An N+ silicon or polysilicon forms a source line (SL) 103. The cell may be formed as a dual-gate transistor shown in FIG. 1A or a single-gate transistor shown in FIG. 1B. For the dual-gate transistor shown in FIG. 1A, the cell structure comprises two control gates called a front gate 104a and a back gate 104b, respectively. Both the front gate 104a and the back gate 104b are coupled to the floating body 102 through gate dielectric layers 105a and 105b, respectively. The gate dielectric layer is an insulating layer between the gate and the body of the transistor. When a proper voltage is applied to the front gate 104a or the back gate 104b, a front gate channel (FGC) 1014 or a back gate channel (BGC) 1012 are formed in the surface of the floating body 102 under the gate dielectric layer 105a and 105b to conduct current between the bit line 101 and source line 103. In an embodiment, the front gate 104a and back gate 104b are connected to different word lines (WL).

In an embodiment, the P− floating body 102 comprises multiple surfaces as shown in FIG. 1A. An internal side surface 1002 surrounds and connects to the BL 101. An external side surface 1004 connects to the source line 103. A top surface 1008 connects to the dielectric layer 105a, and a bottom surface 1006 connects to the dielectric layer 105b. Thus, in one embodiment, a memory cell structure is provided that includes a first semiconductor material BL 101, a floating body semiconductor material 102 having an internal side surface 1002 that surrounds and connects to the first semiconductor material BL 101, and a second semiconductor material SL 103 having an internal side surface 1010 that surrounds and connects to the floating body semiconductor material 102. The memory cell structure also includes a first dielectric layer 105a connected to a top surface 1008 of the floating body material 102, a second dielectric layer 105b connected to a bottom surface 1006 of the floating body material 102, a front gate 104a connected to the first dielectric layer 105a, and a back gate 104b connected to the second dielectric layer 105b. In various embodiments, minor modifications are made to the disclosed structures, such as adding a lightly doped drain (LDD), halo implantation, pocket implantation, or channel implantation that are all included within the scope of the invention.

FIG. 1B shows the cell structure shown in FIG. 1A with the front gate 104a and the gate dielectric layer 105a removed. The P− floating body 102 forms a donut shape as shown. Please notice, although this embodiment shows that the shapes for the bit line 101 and floating body 102 are circular, it is obvious that they have any desired shape, such as square, rectangle, triangle, hexagon, etc. These variations shall remain in the scope of the invention.

In one embodiment, the cell structure comprises only one single gate, as shown in FIG. 1B. The floating body 102 is coupled to only one gate 104b as shown. An embodiment of a 3D array structure using this cell structure embodiment is shown in FIG. 1D.

The embodiment shown in FIG. 1A uses an NMOS transistor as the cell. In another embodiment, shown in FIG. 1C, the cell is formed using a PMOS transistor. The bit line 101, floating body 102, and source line 103 are formed by P+, N−, and P+ materials, respectively.

FIG. 1D shows an embodiment of an array structure based on the cell structure shown in FIG. 1A. The array structure comprises vertical bit lines 101a to 101c and floating bodies 102a to 102e. The array structure also comprises source lines 103a to 103e and word lines 104a to 104d. The array structure also includes dielectric layer 105 comprising a gate oxide or high-K material, such as HfOx.

In an embodiment, a three-dimensional (3D) memory array comprises a plurality of memory cells separated by a dielectric layer to form a stack of memory cells. For example, FIG. 1D shows a 3D array having three stacks of memory cells and a particular “memory cell” is identified. Each memory cell in the stack of memory cells comprises a bit line 101 formed from one of a first semiconductor material and a first conductor material, a floating body semiconductor material 102 having an internal side surface that surrounds and connects to the bit line, a source line 103 formed from one of a second semiconductor material and a second conductor material having an internal side surface that surrounds and connects to the floating body semiconductor material 102, and a word line 104 formed from a third conductor material that is coupled to the floating body semiconductor 102 through a dielectric layer 105 to form a gate of the memory cell. Additionally, the bit lines of the stack of memory cells are connected to form a vertical bit line (e.g., 101a).

FIG. 1E shows another embodiment of an array structure according to the invention. This embodiment is similar to the embodiment shown in FIG. 1D except that the cells are single-gate transistors. Also shown in FIG. 1E are insulating layers 106a and 106b that are formed from material, such as oxide.

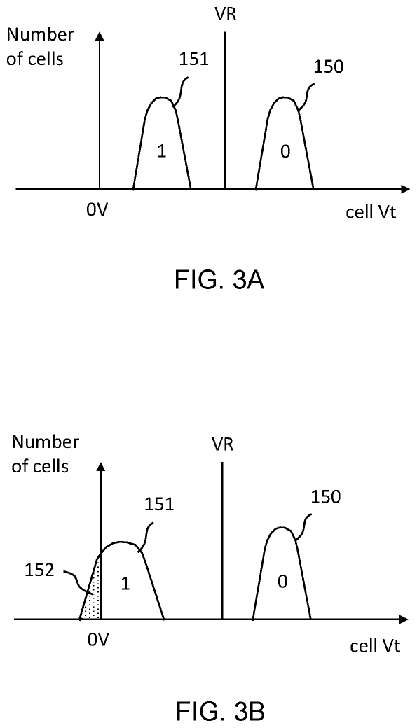

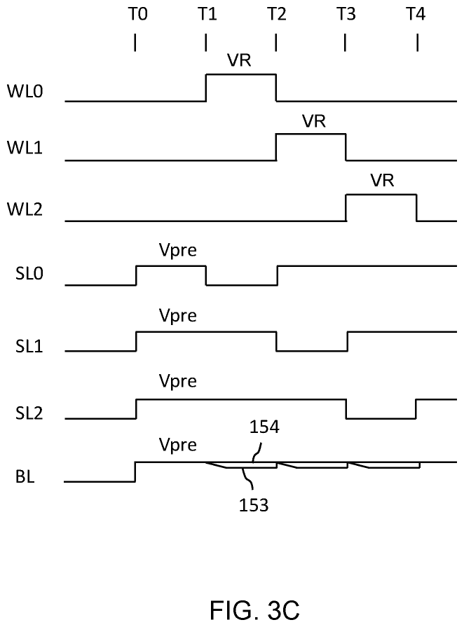

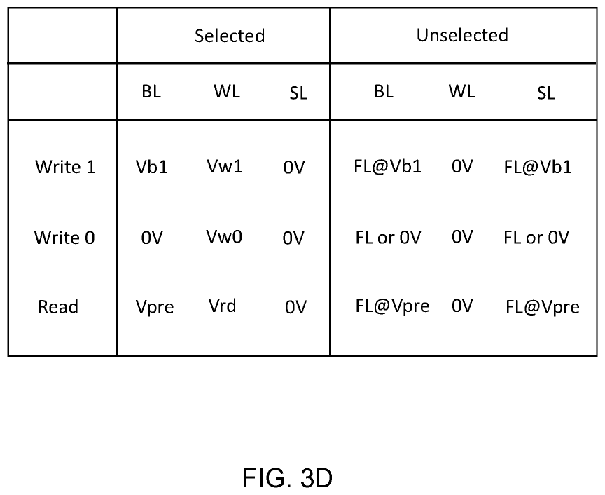

FIG. 1F shows an equivalent circuit diagram for the array structure shown in FIG. 1D. Referring again to the array structure in FIG. 1D, the word line structures 104a to 104d are connected to word lines WL0-WL3. The floating bodies structures 102a to 102e are the floating bodies FB0-FB4. The source line structures 103a to 103e are connected to the source lines SL0-SL4, and the bit line structure 101a is a vertical bit line (BL). In this embodiment, each floating body (e.g., FB0-FB4) is coupled to two word lines. This array requires special bias conditions for read and write operations to avoid two cells being selected at the same time. The detailed bias conditions of this embodiment are described with reference to FIG. 3D.

FIG. 1G shows another embodiment of an equivalent circuit diagram of the array structure shown in FIG. 1D. This embodiment is similar to the embodiment shown in FIG. 1F except that the odd word lines, WL1, WL3, and so on, are connected to ground. This turns off the transistors 301c, 301d, 301g, and 301h. In this embodiment, each floating body is coupled to one word line only. However, the storage capacity of this embodiment is reduced to one half when compared with the embodiment shown in FIG. 1F.

FIGS. 1H-I show embodiments of a junction-less transistor cell structure according to the invention.

FIG. 1H shows an N-channel junction-less transistor cell. The bit line 101 and source line 103 comprise N+ semiconductors, such as silicon, and the floating body 102 comprises an N− semiconductor, such as silicon.

FIG. 1I shows a P-channel junction-less transistor cell. The bit line 101 and source line 103 comprise P+ semiconductors, such as silicon, and the floating body 102 comprises a P− semiconductor, such as silicon.

FIGS. 1J-K show embodiments of a tunnel field-effect transistor (T-FET) cell structure according to the invention. For these embodiments, the bit line 101 and the source line 103 comprise semiconductors, such as silicon, that have the opposite type of doping.

FIG. 1J illustrates how the bit line 101 and source line 103 have P+ type of doping and N+ type of doping, respectively.

FIG. 1K illustrates how the bit line 101 and source line 103 have N+ type of doping and P+ type of doping, respectively. The floating body 102 is an intrinsic semiconductor, such as silicon. In another embodiment, the floating body 102 is lightly doped with P-type or N− type impurity. The tunnel FET behaves like a gated diode. It has an advantage of very low off-state leakage current.

FIG. 1L shows another embodiment of the cell structure according to the invention that uses a metal bit line 109 and a metal source line 114. In this embodiment, the drain region 115 and source region 116 of the cell are connected to conductor layers, such as a metal bit line 109 and a metal source line 114, respectively. This reduces the resistance of the bit line and source line. The source region 116 is formed as a donut shape surrounding the floating body 102 as shown.

FIG. 1M shows embodiments of a thin-film structure and an indium-gallium-zinc-oxide (IGZO) transistor cell structure according to the invention. For the thin-film structure, the bit line 109 and the source line 114 comprise conductors, such as metal or polysilicon. The floating body 102 comprises a thin semiconductor layer, such as silicon. The floating body 102 is either an intrinsic semiconductor or doped with P-type or N-type impurity. This structure forms a junction-less thin-film transistor. In another embodiment, the floating body 102 comprises a semiconductor layer with an oxygen tunnel, such as indium-gallium-zinc-oxide (IGZO). Compared with the traditional silicon-based transistor, this embodiment has the advantages of very low off-state leakage current and higher on-cell current.

For all the embodiments for the cell structures shown above in FIGS. 1H-M, the cell may use the double-gate structure shown in FIG. 1A or single-gate structure shown in FIG. 1B. In addition, the cell structure may use a combination of multiple embodiments disclosed herein.

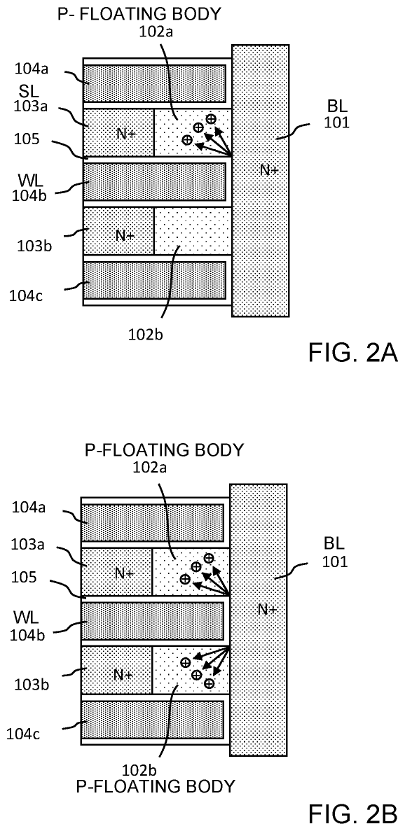

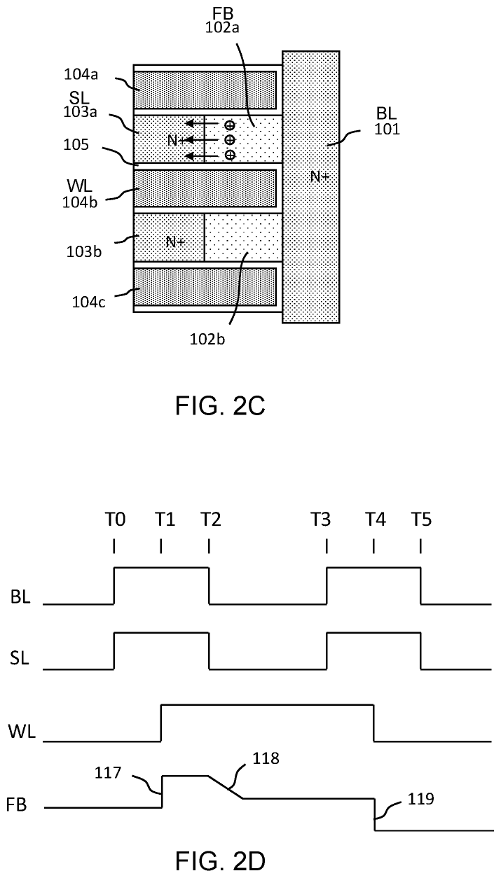

FIG. 2A shows an embodiment of a write data ‘1’ condition of the cell according to the invention. The selected bit line 101 is supplied with a voltage that is high enough to cause impact-ionization to occur. The level of this voltage is dependent on the process technology. In one embodiment, the voltage level is in the range of 1.5V to 2.5V. The selected word line 104b is supplied with a voltage level that is lower than the bit line voltage, such as 0.5V to 1V. The selected source line (SL) 103a is supplied with 0V. This condition turns on the cell transistor in saturation mode and causes impact ionization to occur in the bit line junction to generate electron-hole pairs and inject holes into the P− floating body 102a as shown. The holes trapped in the floating body 102a will reduce the threshold voltage (Vt) of the cell transistor to represent the data ‘1’ state.

In one embodiment, the unselected source line 103b is supplied with an inhibit voltage, such as 0.5V to 1V. This condition turns off the channel under the gate 104b in the floating body 102b, thus the hole injection may not occur in the floating body 102b.

FIG. 2B shows another embodiment of a write data ‘1’ condition of the cell according to the invention. This embodiment uses a band-to-band tunneling mechanism to write the cell. The selected bit line 101 is supplied with a voltage high enough to cause band-to-band tunneling to occur. The level of this voltage is dependent on the process technology. In one embodiment, the voltage level may be 1.5V to 2.5V. The selected word line 104b is supplied with 0V to turn off the cell transistor and cause band-to-band tunneling to occur in the bit line junction to generate electron-hole pairs and inject holes into the P− floating bodies 102a and 102b as shown. The holes trapped in the floating bodies 102a and 102b will reduce the threshold voltage (Vt) of the cell transistor to represent the data ‘1’ state. It should be noted that in this embodiment, the same data ‘1’ will be written into two floating bodies, such as 102a and 102b that are coupled to the same word line 104b.

FIG. 2C shows an embodiment of a write data ‘0’ condition of the cell according to the invention. FIG. 2D shows an exemplary waveform of the write data ‘0’ condition according to the invention.

At time T0, the selected bit line 101 and selected source line 103a are supplied with a positive voltage. The selected word line 104b is supplied with 0V. This will turn off the channel of the cell transistors.

At time T1, the selected word line 104b is supplied with a positive voltage. Because the channel is turned off, the word line voltage will couple up the voltage of the floating body 102a, as shown at indicator 117. The word line voltage is selected so that the coupled floating body voltage is higher than the threshold voltage of the P-N junction diode, such as 0.5V to 0.7V, to cause forward bias from the floating body 102a to the bit line 101 and source line 103a.

At time T2, the selected bit line 101 and source line 103a are supplied with a low voltage, such as 0V. This will cause forward bias current to flow from the floating body 102a to the bit line 101 and source line 103a to evacuate the holes stored in the floating body 102a, as shown at indicator 118. This will increase the threshold voltage (Vt) of the cell transistor to represent the data ‘0’ state.

At time T3, the selected bit line 101 and source line 103a are supplied with a positive voltage again to turn off the channel of the cell transistor.

At time T4, the selected word line 104b supplied with 0V. This will couple low the floating body 102a as shown at indicator 119.

At time T5, the bit line 101 and source line 103a are supplied with 0V and the write ‘0’ operation is completed.

FIG. 3A shows a threshold voltage (Vt) of the cell data ‘0’ 150 and data 1′ 151. During a read operation, the selected word line is supplied with a read voltage (VR) between the Vt of data ‘0’ and ‘1’. This will turn on the data 1′ cell and turn off the data ‘0’ cell. A sensing circuit is coupled to the bit line to sense the current to determine the read data.

It should be noted that under the write 1′ condition, if more than a desired number of holes are injected into the floating body, it may cause the threshold voltage of the cell transistors to become negative, as shown at indicator 152 in FIG. 3B. These cells may leak current even when they are not selected, and their word lines are supplied with the unselected voltage 0V. If many unselected cells have negative Vt, the sum of the leakage current may cause read errors.

FIG. 3C shows a special read condition to address the issues illustrated in FIG. 3B. It will be assumed that three word lines, WL0-WL2 are selected to read.

At time T0, all the bit lines and source lines SL0-SL2 are pre-charged to a voltage Vpre. The voltage Vpre is lower than the bit line voltage during the write mode to avoid accidentally writing. In one embodiment, Vpre is in the range of 0.5V to 1V. All the word lines WL0-WL2 are supplied with 0V.

At time T1, the selected word line WL0 is supplied with the read voltage VR, which is between the Vt of the data ‘1’ and ‘0’. The selected source line SL0 is supplied with 0V. If the selected cell stores data ‘1’, the cell will be turned on and conduct current from the selected bit line to the selected source line to pull low the bit line voltage, as shown at indicator 153. If the selected cell stores data ‘0’, the cell will be turned off, thus the selected bit line will maintain the pre-charged voltage level, as shown at indicator 154. A sense circuit coupled to the selected bit line will sense the current or voltage of the selected bit line to determine the data. Since the unselected bit lines and unselected source lines are pre-charged to the same voltage as the selected bit line, there is no leakage current even if the unselected cells have a negative Vt.

At time T2, the word line WL0 is supplied with 0V. The source line SL0 is pre-charged to Vpre again. The next selected word line WL1 is supplied with the read voltage VR, and the next selected source line SL1 is supplied with 0V. This will read the next cell selected by WL1 and SL1.

Similarly, at time T3, the word line WL1 is supplied with 0V. The source line SL1 is pre-charged to Vpre again. The next selected word line WL2 and source line SL2 are supplied with VR and 0V, respectively, to read the next selected cell.

FIG. 3D shows a table that summarizes the bias conditions of write data ‘1’, write data ‘0’, and read operations. Vb1 is the bit line voltage during write operation. Vw1 and Vw0 are the word line voltages during write ‘1’ and write ‘0’ operations, respectively. Vpre is the pre-charge voltage during read operation. The term “FL” means the indicated line is floating or floating at an indicated value.

The operation conditions shown in FIG. 3D are for an NMOS embodiment. For a PMOS embodiment, the voltages and polarity are adjusted according to the PMOS transistor's characteristics. For example, during the read and write operations, the selected word line is supplied with a low voltage, such as 0V, to turn on the channel. Moreover, during write ‘0’ operation, the bit line 101 is supplied with a positive voltage to cause P-N junction forward bias current to flow from the bit line 101 to the floating body to evacuate the electrons stored in the floating body. These variations and modifications shall be remained within the scope of the invention.

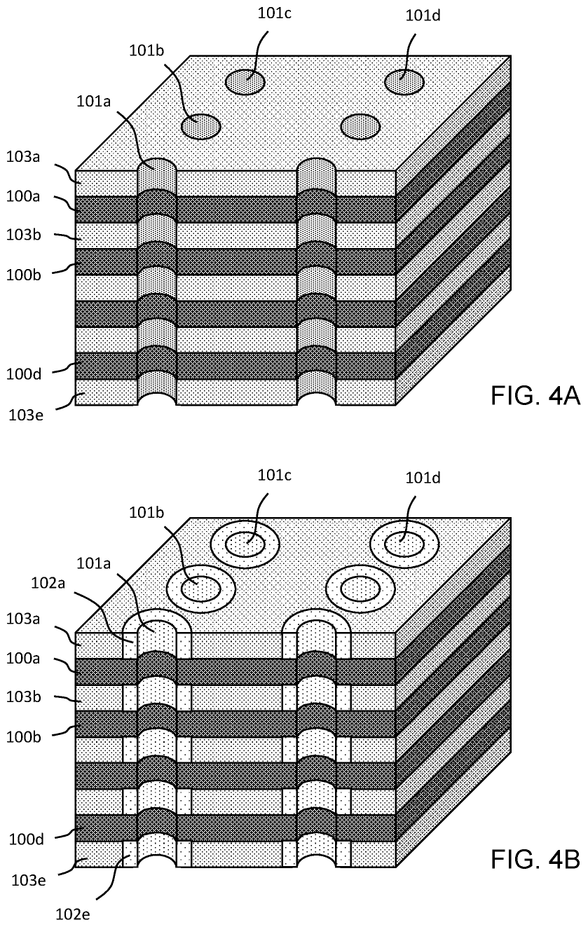

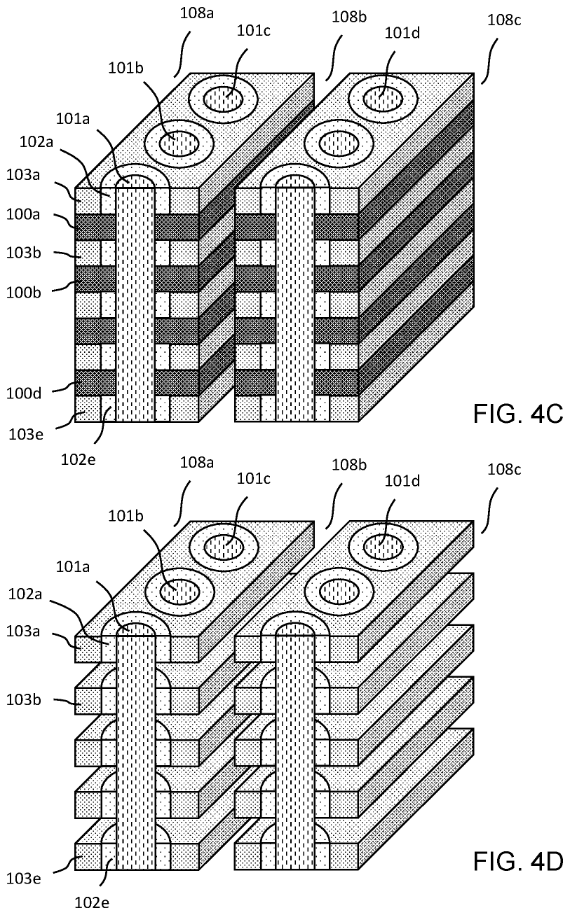

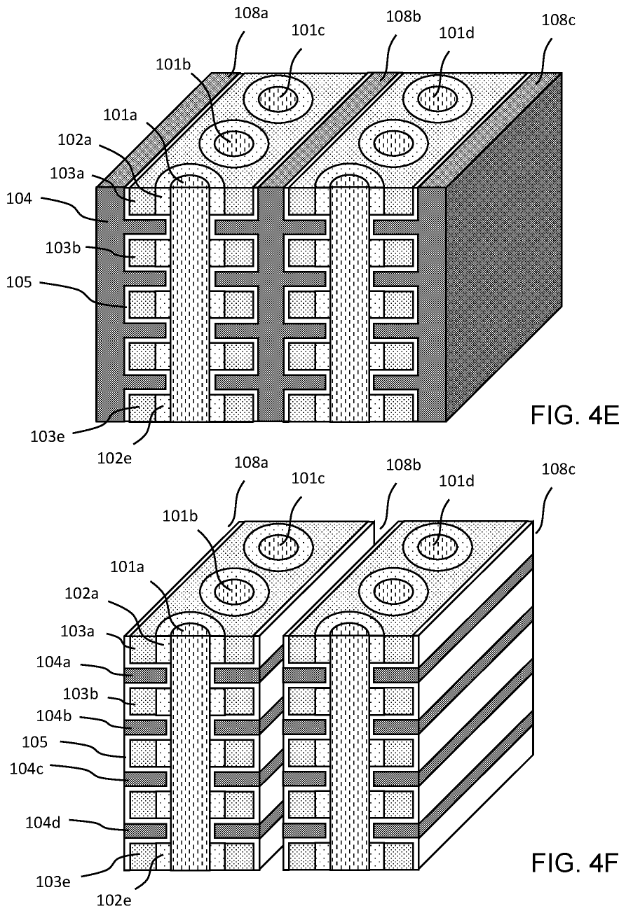

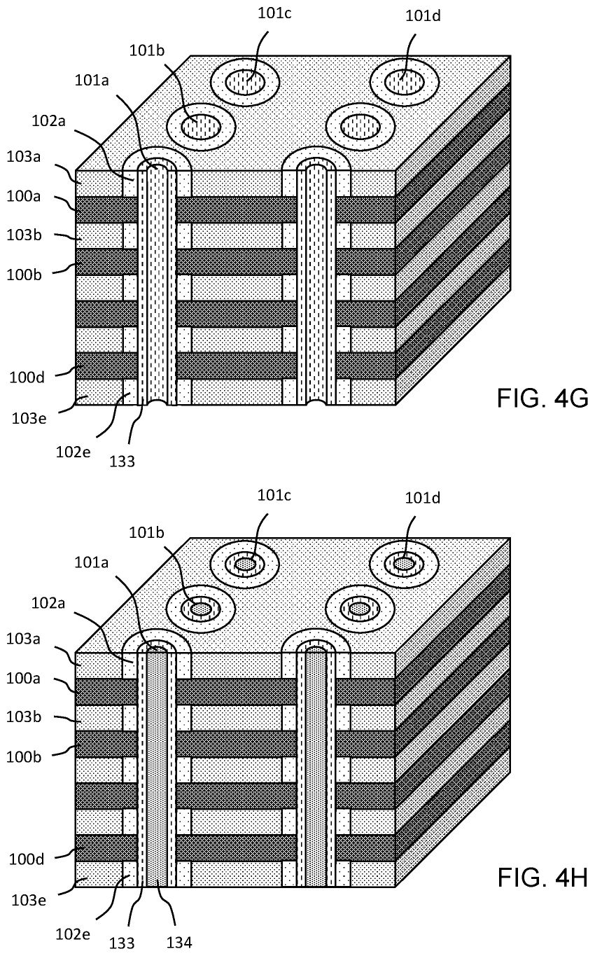

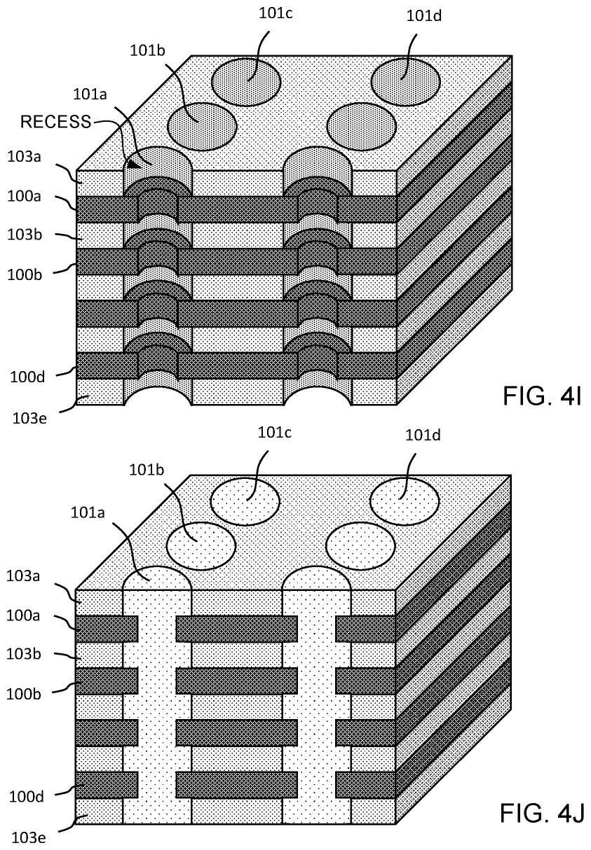

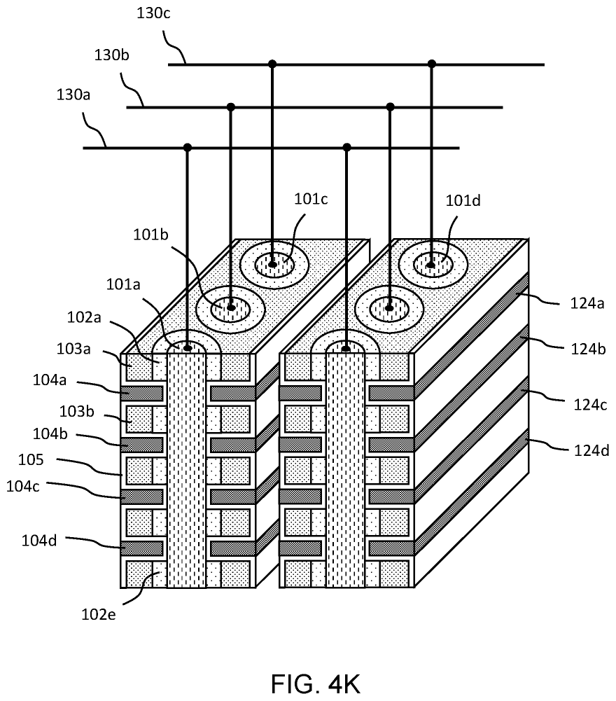

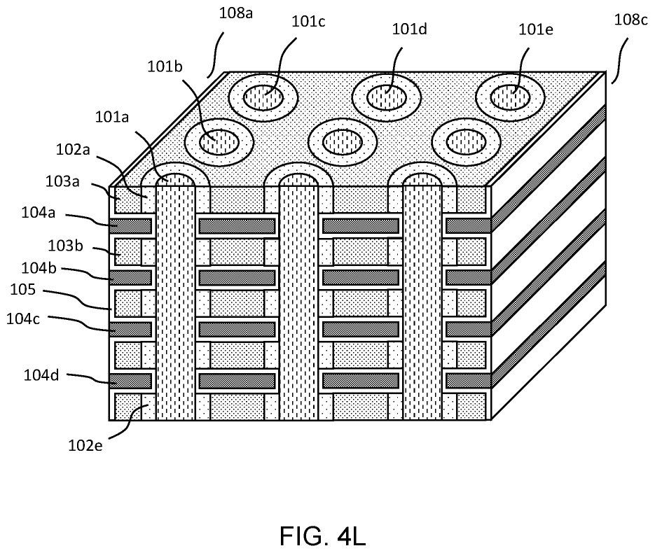

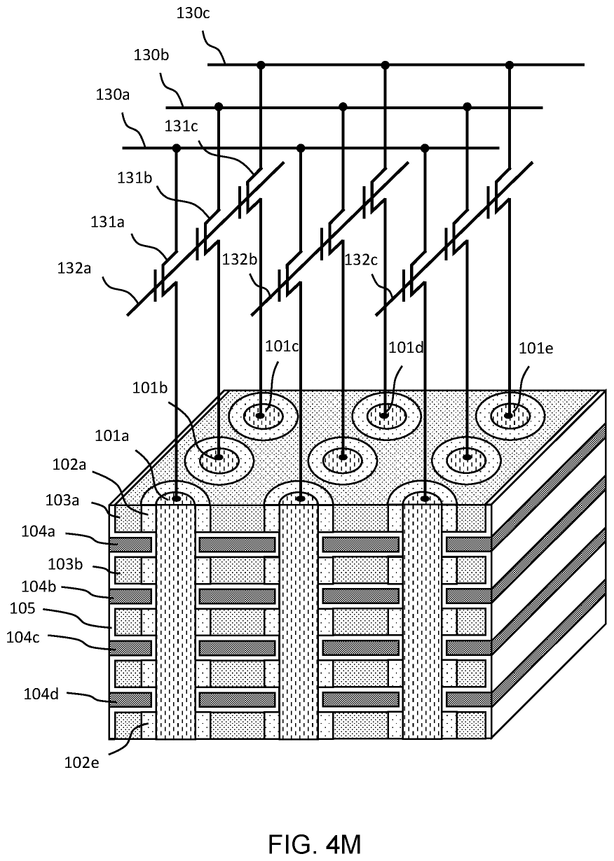

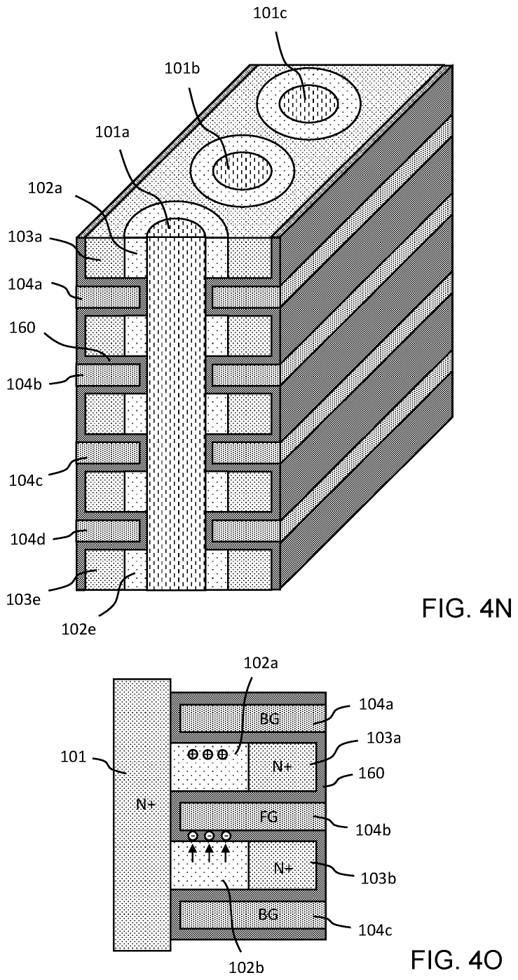

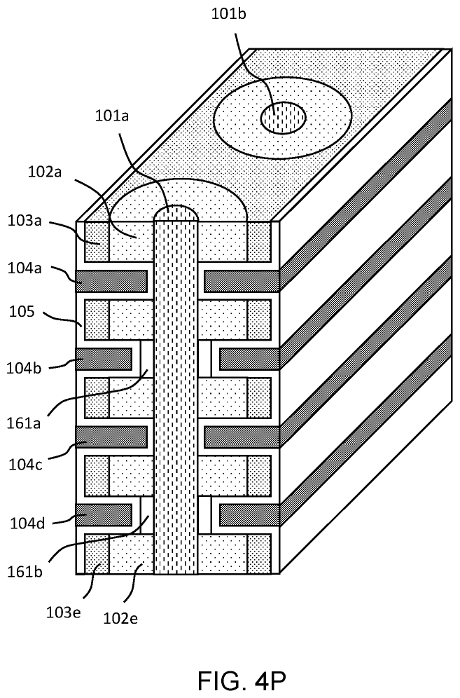

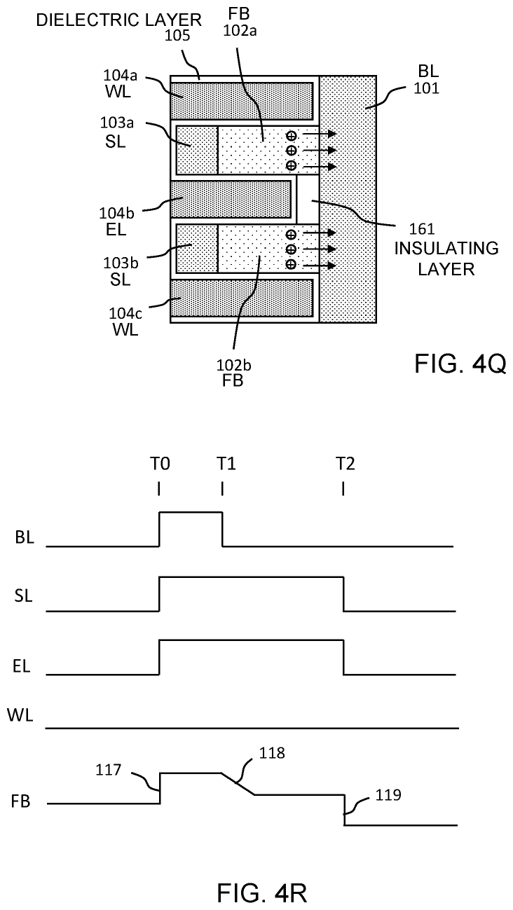

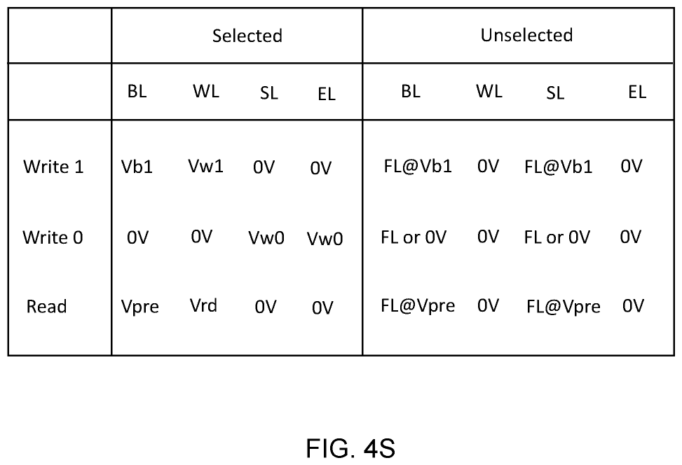

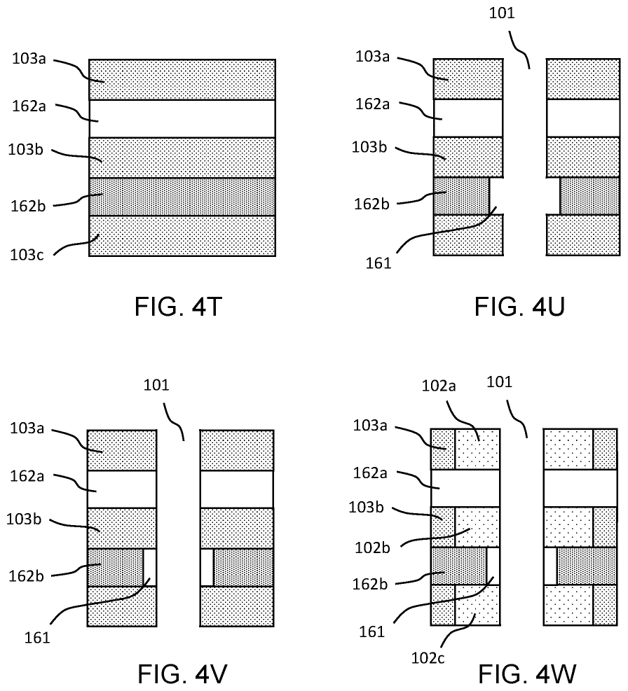

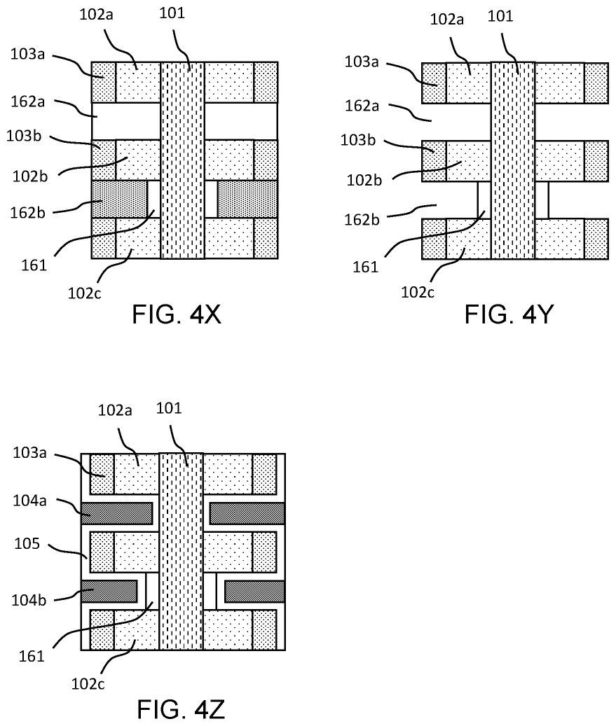

FIGS. 4A-F show simplified process steps for constructing the array structure shown in FIG. 1D.

FIG. 4A shows how multiple sacrificial layers, such as layers 100a to 100d and multiple semiconductor layers, such as silicon or polysilicon layers, forming source lines 103a to 103e, are alternatively deposited to form a stack. The semiconductor source line layers 103a to 103e, have N+ or P+ type of the doping to form NMOS or PMOS transistors, respectively. The sacrificial layers 100a to 100d have different selectivity from the silicon or polysilicon layers for etching solutions. For example, the sacrificial layers 100a to 100d can be oxide or nitride. Then, multiple vertical bit line holes, such as holes for bit lines 101a to 101d are formed by using an anisotropic etching process, such as a deep trench process, to etch through the multiple layers.

FIG. 4B shows how the body of the transistors, such as floating bodies 102a to 102e are formed by using a diffusion process to diffuse the opposite type of impurity of the semiconductor source line layers 103a to 103e through the vertical bit line holes, such as holes 101a to 101d. For example, if the semiconductor source line layers 103a to 103e have N+ type of doping, the body of the transistors, such as floating bodies 102a to 102e are diffused with P− type of doping, such as boron. If the semiconductor source line layers 103a to 103e have P+ type of doping, the body of the transistors, such as floating bodies 102a to 102e are diffused with N− type of doping, such as phosphorus. This forms donut-shape transistor floating bodies 102a to 102e, etc. as shown.

FIG. 4C shows how the vertical bit line holes, such as holes for bit lines 101a to 101d are filled with semiconductor material, such as silicon or polysilicon to form vertical bit lines. The semiconductor layer may have the opposite type of doping as the floating bodies 102a to 102e. For example, if the floating bodies 102a to 102e has P− or N− type of doping, the vertical bit lines 101a to 101d have N+ or P+ type of doping, respectively. Then, vertical slits, such as slits 108a to 108c are formed by using deep trench process to etch through the multiple sacrificial layers 100a to 100d and silicon or polysilicon layers for source lines 103a to 103e. The vertical slits 108a to 108b cut the stack into multiple stacks.

FIG. 4D shows how the sacrificial layers 100a to 100d are selectively removed by using an isotropic etch process, such as wet etch or plasma etch through the slits 108a to 108c.

FIG. 4E shows how a thin-gate dielectric layer 105 is deposited on the surface of the semiconductor source line layers 103a to 103b and the sidewall of the bit lines 101a to 101d through the slits 108a to 108c by using thin-film deposition to form the gate dielectric layer of the transistors. The gate dielectric layer 105 may be oxide or high-K material, such HfOx. After that, a material of the front gate and back gate 104, such as metal or silicon or polysilicon is deposited through the vertical slits 108a to 108c to fill the slits 108a to 108c and the space between the semiconductor source line layers 103a to 103e.

FIG. 4F shows how an anisotropic etch process is performed to vertically etch the gate material in the slits 108a to 108c and form the individual word lines, such as word lines 104a to 104d. As a result, the array structure shown in FIG. 1D is realized. It should be noted that simplified process steps shown in FIGS. 4A-F are used to demonstrate the fundamental process steps according to the invention. Extra steps and minor variations may be applied, and these variations shall remain in the scope of the invention.

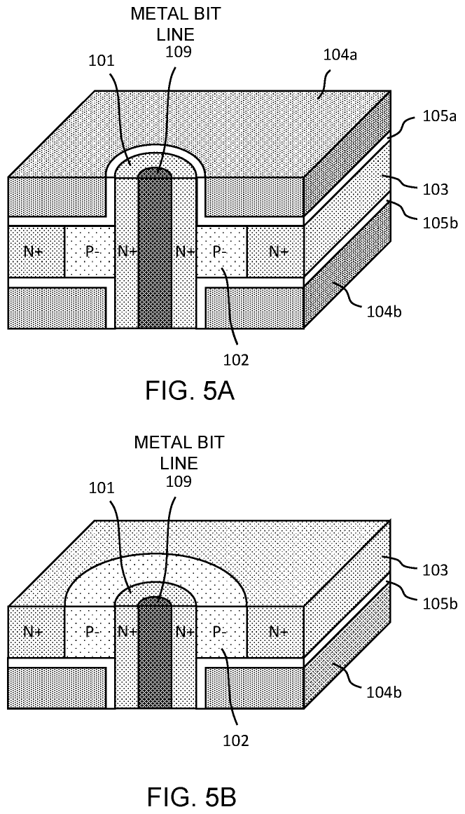

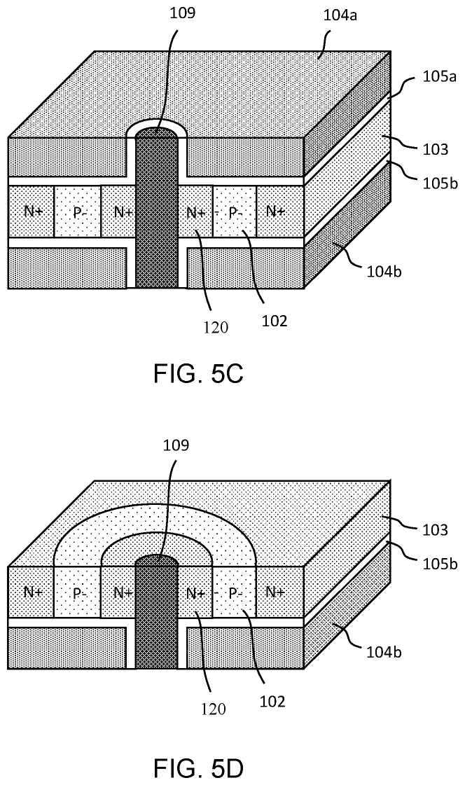

FIGS. 4G-H show additional embodiments of array structures according to the invention to form another embodiment of a cell structure shown in FIG. 5A-B. As illustrated in FIG. 4G, after the process step shown in FIG. 4B are performed, a thin-film deposition or epitaxial thin-film growth process is performed to form a semiconductor layer 133, such as silicon or polysilicon layer, on the sidewall of the vertical holes for the bit lines 101a to 101d. The semiconductor layer 133 is doped with the same type of dopant as the semiconductor source line layers 103a to 103e by using an in-situ doping process or diffusion process through the vertical holes for the bit lines 101a to 101d.

FIG. 4H shows how the vertical holes for the bit lines 101a to 101d are filled with a metal core 134 by using a metal deposition process. This can reduce the resistance of the vertical bit lines to increase the speeds of read and write operations.

FIGS. 4I-J show another embodiment of process steps to form the floating bodies 102a to 102e. After the process steps shown in FIG. 4A are performed, an isotropic etching process, such as wet etch or chemical etch, is performed through the vertical holes for the bit lines 101a to 101d to selectively etch the semiconductor source line layers 103a to 103e to form the recesses as shown.

FIG. 4J shows how the vertical holes for the bit lines 101a to 101e, are filled with a semiconductor material, such as silicon or polysilicon, which is formed by using an epitaxial growth process. In one embodiment, the semiconductor layer in the vertical holes for the bit lines 101a to 101d has the opposite type of impurity of the semiconductor source line layers 103a to 103e. For example, if the semiconductor source line layers 103a to 103e have N+ or P+ type of doping, the semiconductor layer in the vertical holes for the bit lines 101a to 101d have P− or N− type of doping, respectively, which is formed by using an in-situ doping process during the epitaxial growth.

After that, a self-aligned anisotropic etching process, such as dry etch or reactive-ion etch (RIE), is performed using the sacrificial layers 100a to 100d as masks to selectively etch the semiconductor layer in the vertical holes for the bit lines 101a to 101d to form the array structure shown in FIG. 4B. After that, the process steps shown in FIGS. 4C-F are performed to form the array structure shown in FIG. 4F.

FIG. 4K shows an embodiment of the bit line connection of the array structure shown in FIG. 4F. The vertical bit lines, such as 101a to 101d, are connected to horizontal metal bit lines 130a to 130c as shown. Although the embodiment shows the horizontal metal bit lines 130a to 130c located on top of the array, in another embodiment, the metal bit lines 130a to 130c are located in the bottom of the array.

It should be noted that because the vertical bit lines, such as 101c and 101d are connected to the same horizontal metal bit line 130c, the word lines 104a to 104d and word lines 124a to 124d are connected to different decoders' signals to prevent the cells in vertical bit lines to be selected together. This will require many word line decoders and also increase the process challenge to connect so many word lines to the decoders.

FIG. 4L shows another embodiment of the array structure according to the invention to solve the previously mentioned issue with using many word line decoders. In this embodiment, the vertical bit lines, such as 101a to 101e, are all coupled to the same word line layers 104a to 104d. This reduces the number of the word lines need to be connected to the decoders. Therefore, the number of the word line decoders is reduced. The process step of this embodiment is the same as that of the embodiment shown in FIG. 4F, except that the word line processes are performed through the vertical slits 108a and 108c on two sides of the stack.

FIG. 4M shows the bit line connections of the array embodiment shown in FIG. 4L. FIG. 4M illustrates horizontal metal bit lines 130a to 130c. The vertical bit lines, such as 101a to 101c, are connected to the horizontal metal bit lines 130a to 130c through select transistors 131a to 131c. The select transistors, such as 131a to 131c are formed by using any suitable process and technologies, such as vertical transistors, planar transistors, junction-less transistors, and so on. Although the embodiment shows NMOS transistors as an example, the select transistors, such as 131a to 131c, can be formed as PMOS transistors as well. Moreover, although the embodiment shows that the horizontal metal bit lines 130a to 130c and the select transistors, such as 131a to 131c, are located on top of the array, in another embodiment, the bit lines and the select transistors can be located in the bottom of the array as well.

The gates 132a to 132c of the select transistors are connected to different decoders' signals. For example, when the gate 132a is selected, it will turn on the select transistors 131a to 131c to couple the vertical bit lines 101a to 101c to the horizontal metal bit lines 131a to 131c, respectively. The unselected gates 132b and 132c will turn off the associated select transistors. This presents multiple vertical bit lines to be coupled to the same metal bit line.

FIG. 4N shows another embodiment of an array architecture according to the invention. This embodiment is similar to the embodiment shown in FIG. 1D except that the gate dielectric layer 105 is replaced by a charge-trapping layer 160, which traps electric charge such as electrons. When electrons are trapped inside the charge-trapping layer, the threshold voltage of the transistor is increased. This results in lower cell current during read operations. Therefore, the data can be stored in the charge-trapping layer 160 in terms of the number of trapped electrons. Because the trapped electrons remain in the charge-trapping layer after power down, this embodiment can be used as a non-volatile memory, such as 3D NOR flash memory.

In one embodiment, the charge trapping layer 160 is formed as a nitride layer or oxide-nitride layers. Because a nitride layer's electrical barrier is lower than an oxide layer's, this embodiment allows the data to be written in lower gate voltage and shorter time. However, because of the lower electrical barrier, it is easier for the electrons to escape from the charge-trapping layer 160, thus the data retention time is also shorter.

This embodiment is suitable for the application of non-volatile buffer memory. In normal operation, the data is stored in the floating bodies 102a to 102e of the cells, as described in the previous embodiments shown in FIG. 2A to FIG. 3B. When the system becomes idle or during an accidental power loss event, the data stored in the floating bodies 102a to 102e can be quickly written to the charge-trapping layer 160 to preserve the data. Because the electrons stored in the charge-trapping layer 160 may escape after a period of time, a refresh operation with longer duration may still be needed during the system idle. However, since the frequency of the refresh operation is reduced, the power consumption is also reduced. In the case of power loss, a battery or a large capacitor may be utilized to temporarily maintain the power of the system until the data stored in the charge-trapping layer 160 is copied to another non-volatile memory, such as NAND flash memory or hard disk drives.

In another embodiment, the charge-trapping layer 160 comprises a sandwich of oxide-nitride-oxide (ONO) layers. Due to the oxide layer having a higher electrical barrier than the nitride layer, the electrons trapped in the nitride layer are more difficult to escape. Therefore, the data retention time for this embodiment is much longer, like years. This embodiment may be used as a permanent non-volatile memory. However, due to the oxide layer's higher electrical barrier, this embodiment requires higher write voltage, such as 10V to 20V.

FIG. 4O shows an embodiment of a non-volatile program operation to write the data stored in the floating bodies 102a and 102b to the charge-trapping layer 160. Assuming the data stored in the floating bodies 102a and 102b is ‘1’ and ‘0’, respectively. During the non-volatile program operation, the front gate 104b is supplied with a program voltage, such as 3-5V for a nitride layer and 10-20V for ONO layers. The bit line 101 and the source lines 103a and 103b are floating. For the floating body 102a, the holes stored in the floating body 102a reduce the electrical field between the front gate 104b and the floating body 102a to below the threshold of the Fowler-Nordheim (F-N) tunneling mechanism. Therefore, F-N tunneling may not happen. For the floating body 102b, due to the fact there are no holes, the electrical field between the front gate 104b and the floating body 102b is sufficient to induce F-N tunneling, and thus electrons may be injected into the charge-trapping layer 160 and trapped inside the layer to increase the threshold voltage of the cell transistor.

FIG. 4P shows another embodiment of a 3D floating body cell array structure according to the invention. This embodiment is similar to the one shown in FIG. 1D except that the insulating layers 161a and 161b, such as oxide or nitride, are formed in the junctions of the vertical bit lines 101a and 101b and the odd word line layers 104b and 104d. This prevents the channels induced by the even word lines 104b and 104d to reach the vertical bit lines 101a and 101b. In this embodiment, the even word lines 104a and 104c are connected to normal word line (WL) signals, and the odd word lines 104b and 104d are connected to ‘erase word lines (EL)’ signals. The erase word line 104b is activated during write ‘0’ operation to ‘erase’ the data stored in the cells. The array structure allows the cells to perform special write ‘0’ operation shown in FIGS. 4Q-R. For a detailed description of the array structure, please refer to FIG. 1D.

FIG. 4Q shows a write ‘0’ condition of the array structure embodiment shown in FIG. 4P. FIG. 4Q shows the vertical bit line (BL) 101 and floating bodies (FB) 102a and 102b. Also shown are source lines (SL) 103a and 103b, word lines (WL) 104a and 104c, erase word line (EL) 104b, gate dielectric layer 105 and insulating layer 161.

FIG. 4R shows an embodiment of write ‘0’ waveforms. At time T0, the bit line (BL), source line (SL), and erase line (SL) are supplied with a positive voltage. This will couple up the voltage of the floating bodies 102a and 102b as shown at indicator 117. The applied voltage is high enough to couple the floating bodies to a voltage higher than the threshold voltage of the P/N junction, such as 0.5V to 0.7V.

At time T1, the bit line (BL) is supplied with 0V. This will cause forward bias current to flow from the floating bodies 102a and 102b to the bit line 101, and evacuate the holes stored in the floating bodies 102a and 102b to lower their potential, as shown at indicator 118. Due to the insulating layer 161, the channel induced by the erase word line 104b will not reach the bit line 101. This prevents the channel voltage from being discharged by the bit line voltage to reduce the voltage coupling of the floating bodies. The word lines 104a and 104c are supplied with 0V to turn off the channels induced by the word lines to prevent leakage current from the source lines to the bit line.

At time T2, the erase word line 104b and source lines 103a and 103b are supplied with 0V. This will couple down the floating bodies 102a and 102b, as shown at indicator 119, to be lower than its initial voltage. Thus, the threshold voltage of the floating body cells are increased, which represents the state of data ‘0’.

FIG. 4S shows bias conditions of write data ‘1’, write data ‘0’, and read operations for the array embodiment shown in FIG. 4P. The conditions are similar to the ones shown in FIG. 3D except for the write ‘0’ condition. During the write ‘0’ condition, the selected erase word line (EL) and source line (SL) are supplied with a positive voltage Vw0, which shall be high enough to couple up the floating body of the cell to be higher than the threshold voltage of the P/N junction. During read and write ‘1’ operations, the erase word line (EL) is supplied with 0V or any other suitable voltage. Because the channel induced by the erase word line (EL) does not reach the bit line, it will not cause current leakage even when the channel is turned on.

FIGS. 4T-Z show an embodiment of process steps to form the cell array structure shown in FIG. 4P.

FIG. 4T shows how multiple semiconductor source line layers 103a to 103c, such as silicon, and insulating layers 162a and 162b, are alternately deposited to form a stack. The even insulating layers, such as 162a, and odd insulting layers, such as 162b, are different material. For example, in one embodiment, the even insulating layer 162a comprises an oxide layer and the odd insulating layer 162b comprises a nitride layer.

FIG. 4U shows how multiple vertical holes, such as hole 101, is formed by using an anisotropic etching process, such as deep trench or dry etch to etch through the multiple semiconductor source line layers 103a to 103c and the insulating layers 162a and 162b to form the vertical bit line pattern. After that, recessed area for the insulating layer 161 is formed in the odd insulting layers, such as layer 162b by using an isotropic etching process, such as wet etch or chemical etch through the hole for the bit line 101.

FIG. 4V shows how the hole for the bit line 101 is filled with an insulating layer which is different from the insulating layer 162b. For example, if the insulting layer 162b is nitride, the insulator used in filling the hole for the bit line 101 may be oxide. After that, the insulator in the hole for the bit line 101 is etched using an anisotropic etching process, such as dry etch, to remove the insulator in the hole for the bit line 101 except for the residual in the recessed area for the insulating layer 161.

FIG. 4W shows how the floating bodies 102a to 102c are formed by using a diffusion process to diffuse the semiconductor source line layers 103a to 103c with the opposite type of impurity through the hole for the bit line 101. For example, if the semiconductor source line layers 103a to 103c have N+ type or P+ type of doping, the floating bodies 102a to 102c have P− type or N− type of doping, respectively. This step forms ‘donut’ shapes for the floating bodies 102a to 102c.

FIG. 4X shows how the hole for the bit line 101 is filled with semiconductor to form a vertical bit line. The semiconductor may be doped with the opposite type of impurity of the floating bodies 102a to 102c by using an in-situ doping process.

FIG. 4Y shows how even insulting layers, such as 162a, are selectively etched by using an isotropic etching process, such as wet etch or chemical etch. After that, the odd insulating layers, such as 162b, are selectively etched by using an isotropic etching process, such as wet etch or chemical etch. Because the insulating layers 161 and 162b are different materials, the insulating layer 161 will not be etched.

FIG. 4Z shows how a gate dielectric layer 105 is formed on the surface of the array structure by using a thin-film deposition process. After that, the spaces previously occupied by the insulating layers 162a and 162b, as shown in FIG. 4Y, are filled with a control gate material, such as metal or polysilicon, to form the word line 104a and erase word line 104b.

FIG. 5A shows another embodiment of a cell structure according to the invention. This embodiment is similar to the one shown in FIG. 1A except that a metal core is formed in the center of the bit line 101 to form a metal bit line 109 to reduce the bit line resistance.

FIG. 5B shows the cell structure of FIG. 5A with the front gate 104a and gate dielectric layer 105a removed to show the inner structure. The cell structure shown in FIGS. 5A-B is formed by using a similar process to that shown in FIGS. 4A-D except that in FIG. 4D, the silicon or polysilicon layer for bit line 101a is deposited on the surface of the sidewall of the vertical bit line hole instead of filling the bit line hole. Then, the bit line hole is filled with metal to form a metal bit line 109.

FIG. 5C shows another embodiment of a cell structure according to the invention. FIG. 5D shows the cell structure of FIG. 5C with the front gate 104a and the gate dielectric layer 105a removed.

The embodiment shown in FIG. 5C is similar to the embodiment shown in FIG. except that an N+ silicon or polysilicon 120 is formed as a donut shape island for each cell and connected to the metal bit line 109 that is formed by filling the vertical bit line hole with metal. For comparison, the N+ silicon or polysilicon layer for bit line 101 shown in FIG. 5A is a continuous layer formed on the sidewall of the metal bit line 109. Similarly, the cell structure shown in FIGS. 5C-D is formed by a similar process to that shown in FIGS. 4A-D except that in FIG. 4B, after the P− floating body 102 is formed, the N+ region 120 is formed by using an implantation or diffusion through the bit line hole. Then, the bit line hole is filled with the metal to form the metal bit line 109.

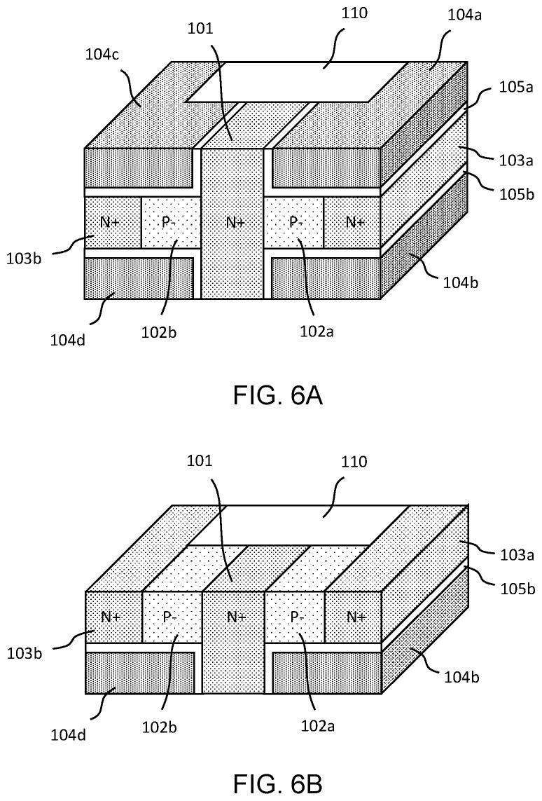

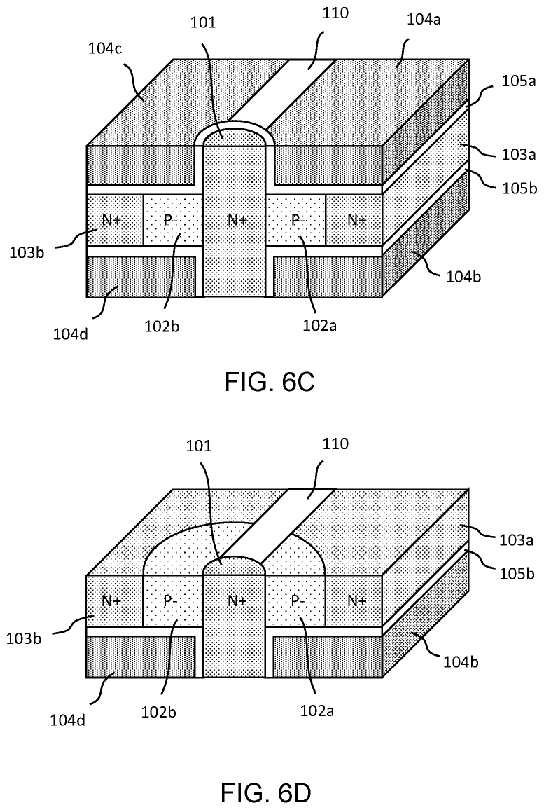

FIG. 6A shows another embodiment of a cell structure according to the invention. FIG. 6B shows the cell structure shown in FIG. 6A with the front gate 104a and gate dielectric layer 105a removed. This embodiment is similar to the embodiment shown in FIG. 1A except that the cell is divided into two cells by an insulating layer 110, such as an oxide. The insulating layer 110 divides the floating body into 102a and 102b, and divides the front gate into 104a and 104c, and divides the back gate into 104b and 104d. In this way, the bit line 101 is connected to two cells, thus the memory array capacity is doubled. Similar to the embodiment shown in FIG. 1A, this cell structure may be formed by using NMOS or PMOS transistors. Besides, the floating bodies 102a and 102b and bit line 101 may be any shape, such as circular.

FIGS. 6C-D show another embodiment of a cell structure according to the invention. This embodiment is similar to the embodiment shown in FIGS. 6A-B except that the floating bodies 102a and 102b and bit line 101 are circular.

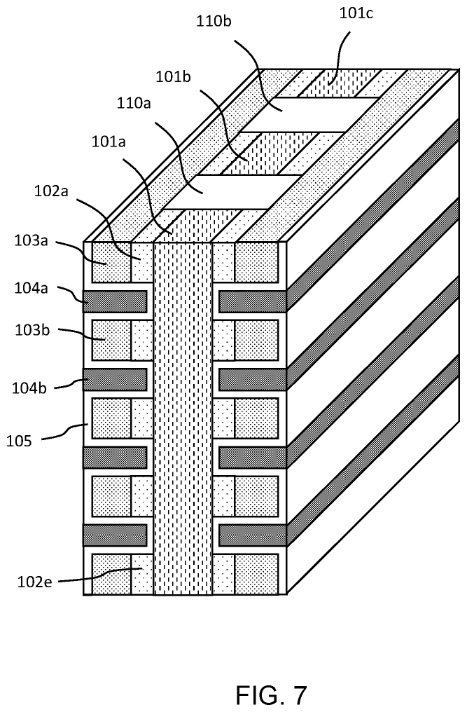

FIG. 7 shows an embodiment of an array structure based on the cell structure shown in FIG. 6A. The array structure of FIG. 7 includes bit lines 101a to 101c, floating bodies 102a to 102e, source lines 103a and 103b, word lines 104a and 104b, gate dielectric layer 105, and insulating layers 110a and 110b that comprise an oxide.

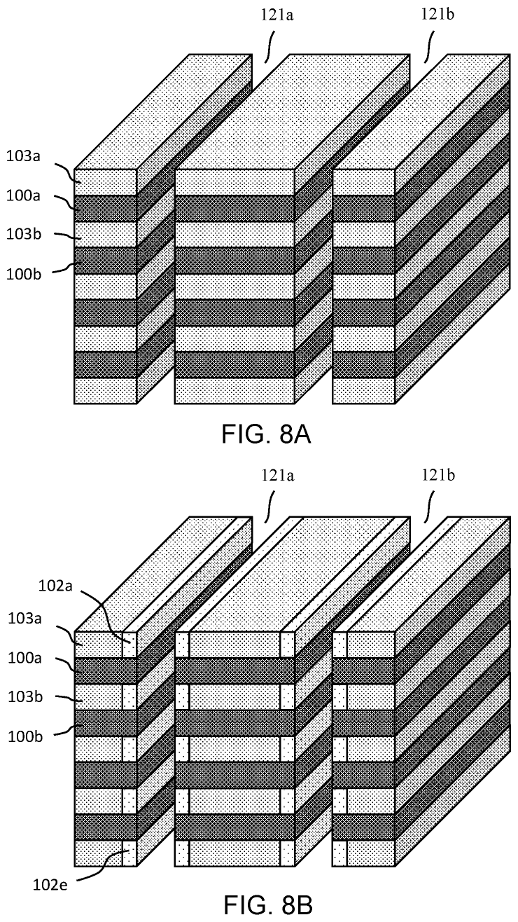

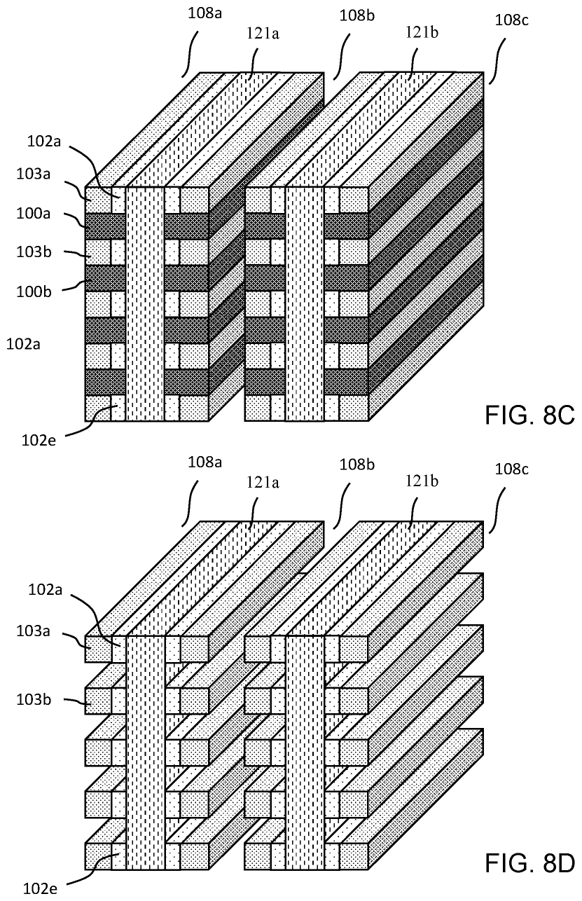

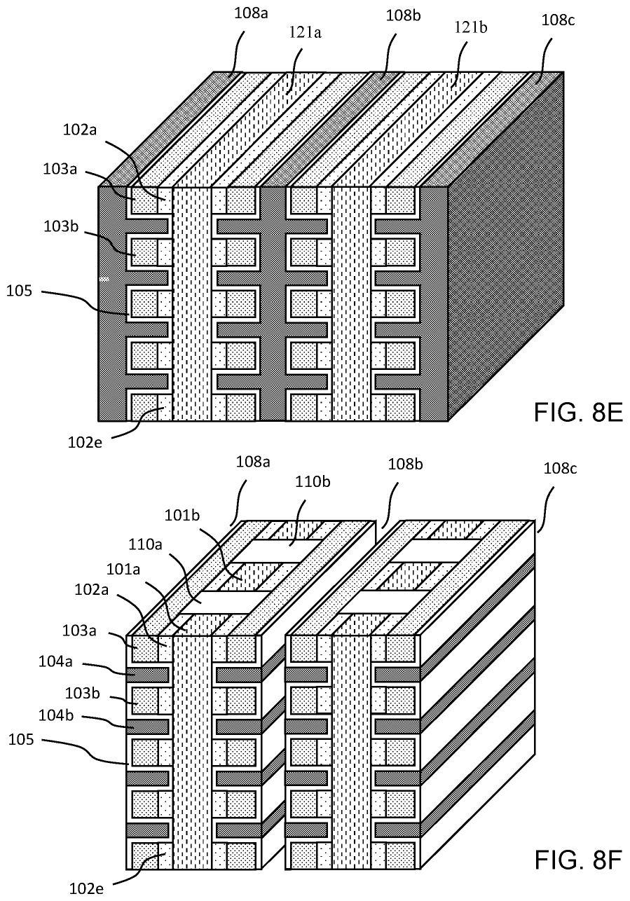

FIGS. 8A-F show simplified process steps for forming the array structure shown in FIG. 7.

FIG. 8A shows how multiple sacrificial layers, such as layers 100a and 100b, and multiple N+ silicon or polysilicon layers, such as layers for bit lines 101a and 101b, are alternatively deposited to form a stack. Then, multiple vertical slits, such as slits 121a and 121b are formed by using a deep trench process to etch through the multiple layers.

FIG. 8B shows how a P− floating body, such as P− floating bodies 102a to 102e are formed by using implantation or diffusion through the slits, such as slits 121a and 121b. This process forms P− silicon or polysilicon strips.

FIG. 8C shows how the slits, such as slits 121a and 121b are filled with N+ silicon or polysilicon. Then, vertical slits, such as vertical slits 108a to 108c are formed by a deep trench process to etch through the stack.

FIG. 8D shows how the sacrificial layers, such as layers 100a and 100b are removed by using an isotropic etch process, such as wet etch or plasma etch, through the slits 108a to 108c.

FIG. 8E shows how a thin dielectric layer 105 is deposited on the surface of the sidewall through the slits 108a to 108c. Then, the material for the front gate and back gate, such as metal or silicon or polysilicon is deposited to fill the slits 108a to 108c and the space between the silicon or polysilicon layers for source lines 103a and 103b, etc.

FIG. 8F shows how vertical bit lines, such as bit lines 101a and 101b are formed by using a deep trench process to etch holes for the bit lines 110a and 110b, etc. and filling the holes with an insulator, such as an oxide. After that, an anisotropic etch process is performed to vertically etch the gate material in the slits 108a to 108c to form the individual word lines, such as word lines 104a and 104b, etc. As a result, the array structure shown in FIG. 7 is realized.

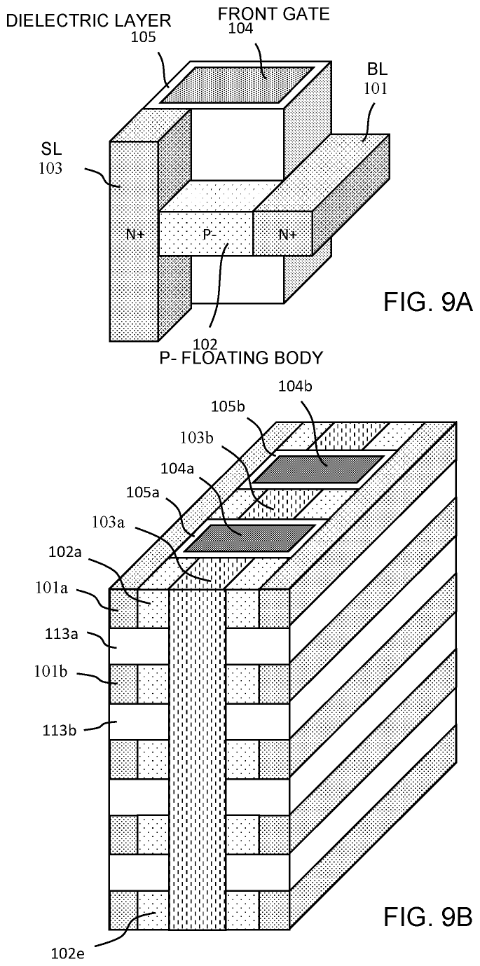

FIG. 9A shows another embodiment of a cell structure according to the invention. The cell structure in FIG. 9A comprises N+ silicon or polysilicon that forms a bit line 101, a P− floating body 102 for charge storage, N+ silicon or polysilicon that forms a source line 103, a front gate 104, and a gate dielectric layer 105. The back gate is not shown to make it easier to illustrate. The front gate 104 of the cells on multiple layers are connected to form a word line (WL). In this embodiment, because the word line 104 runs in a vertical direction, the horizontal N+ silicon or polysilicon line becomes the bit line 101, and the vertical N+ silicon or polysilicon line becomes the source line 103.

It should be noted that when talking about single cell (transistor) structure, the front gate structure is referred to as a gate. If the cell has dual gates, one gate is called the “front gate” and the other gate is called the “back gate.” In an array level structure, the gates of multiple cells are connected to form a word line, so the gate structures are also referred to as word lines.

FIG. 9B shows an embodiment of an array structure based on the cell structure shown in FIG. 9A. The structure of FIG. 9B comprises bit lines 101a and 101b, floating bodies 102a to 102e, source lines 103a and 103b, word lines 104a and 104b, gate dielectric layers 105a and 105b, and insulating layers 113a and 113b, such as oxide layers.

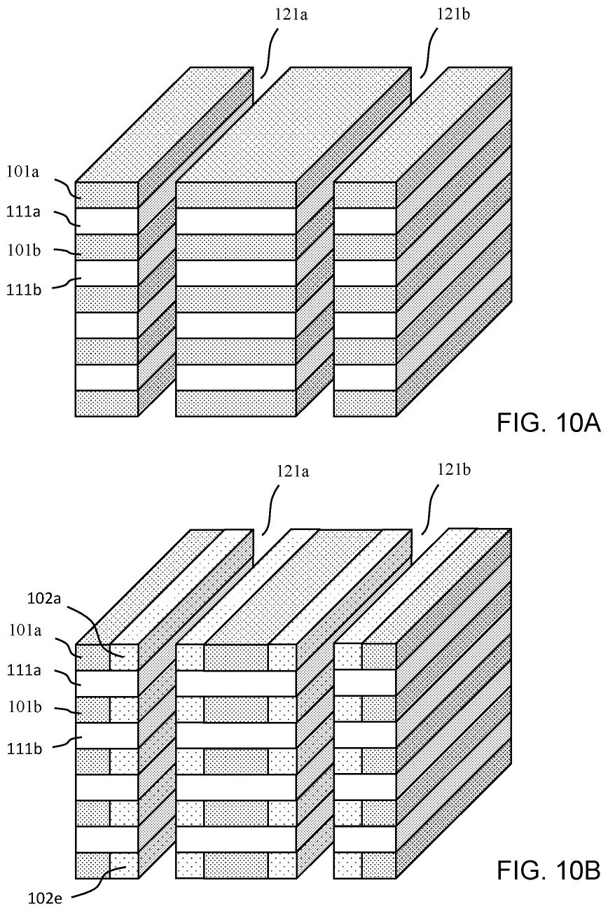

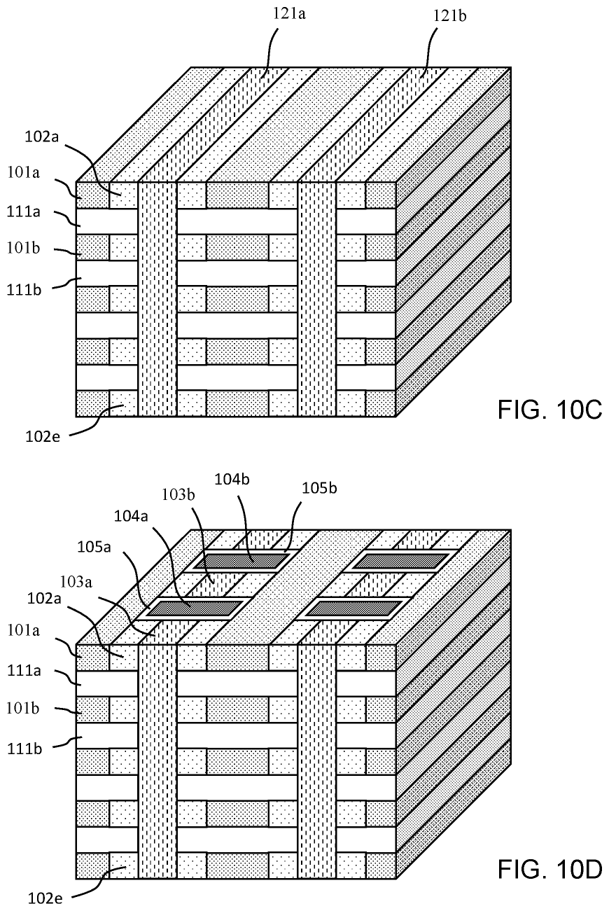

FIGS. 10A-D show simplified process steps for constructing the cell structure shown in FIG. 9A.

FIG. 10A shows how multiple N+ silicon or polysilicon layers, such as layers for bit lines 101a and 101b, and multiple insulating layers, such as layers 111a and 111b are alternatively deposited to form a stack. Then, multiple vertical slits, such as slits 121a and 121b are formed by using a deep trench process to etch through the multiple layers.

FIG. 10B shows how P-bodies, such as P− floating bodies 102a to 102e are formed by using implantation or diffusion through the slits 121a and 121b. This forms P− silicon or polysilicon strips.

FIG. 10C shows how the slits 121a and 121b are filled with N+ silicon or polysilicon.

FIG. 10D shows how multiple holes are formed by a deep trench process and thin gate dielectric layers, such as layers 105a and 105b, are formed on the sidewall of the holes. Then, the holes are filled with the gate material, such as metal or silicon or polysilicon to form vertical word lines, such as word lines 104a and 104b. As a result, the array structure shown in FIG. 9B is realized.

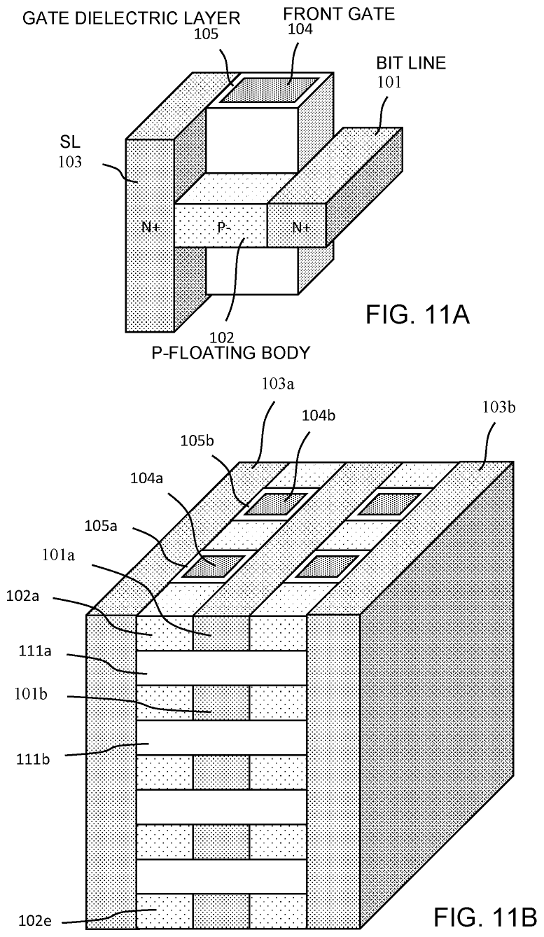

FIG. 11A shows another embodiment of a cell structure according to the invention. The cell structure shown in FIG. 11A comprises a bit line 101 formed from N+ silicon or polysilicon, a P− floating body 102 for charge storage, a source line 103 formed from N+ silicon or polysilicon, a front gate 104, and a gate dielectric layer 105. The back gate is not shown to make it easier to illustrate. The front gate 104 of the cells on multiple layers are connected to form a word line (WL). In this embodiment, because the word line 104 runs in a vertical direction, the horizontal N+ silicon or polysilicon line becomes the bit line 101. The vertical N+ silicon or polysilicon line becomes the source line 103.

FIG. 11B shows an embodiment of an array structure based on the cell structure shown in FIG. 11A. The array structure shown in FIG. 11B comprises bit lines 101a to 101b, floating bodies 102a to 102e, source lines 103a and 103b, word lines 104a and 104b, gate dielectric layers 105a and 105b, and insulating layers 111a and 111b that are formed from a material such as an oxide.

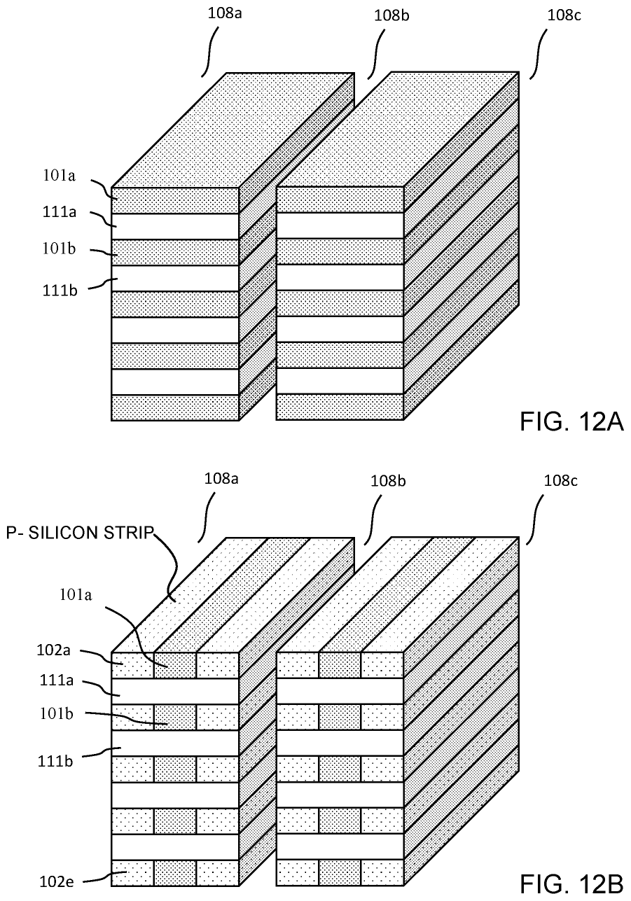

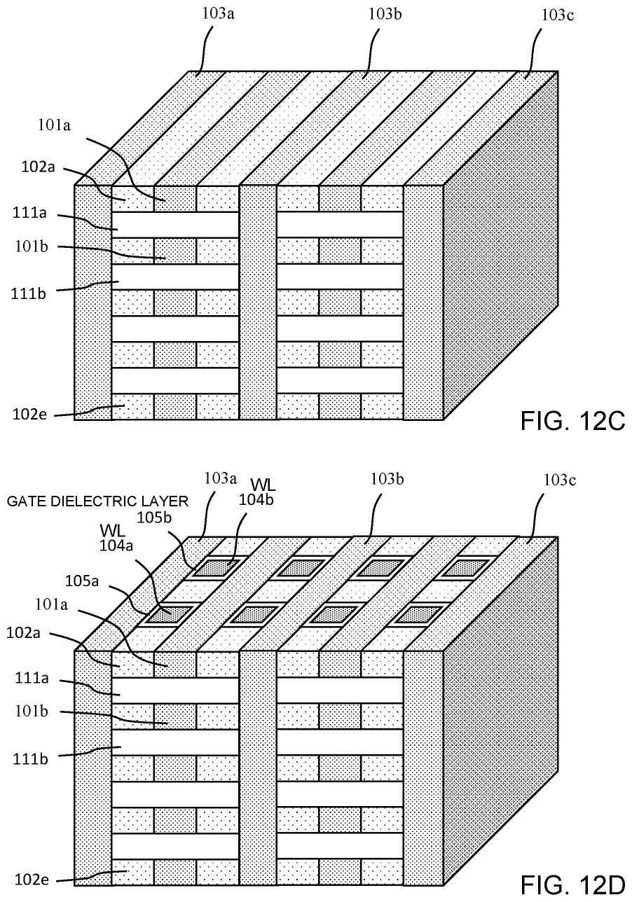

FIGS. 12A-D shows simplified process steps for constructing the cell structure shown in FIG. 11A.

FIG. 12A shows how multiple N+ silicon or polysilicon layers, such as layers for bit lines 101a and 101b, and multiple insulating layers, such as layers 111a and 111b are alternatively deposited to form a stack. Then, multiple vertical slits, such as vertical slits 108a to 108c are formed by using a deep trench process to etch through the multiple layers.

FIG. 12B shows how P− floating bodies, such as P− floating bodies 102a to 102e are formed by using implantation or diffusion through the vertical slits 108a to 108c. This forms P− silicon or polysilicon strips.

FIG. 12C shows how the slits 108a to 108c are filled with N+ silicon or polysilicon to form the source lines 103a to 103c.

FIG. 12D shows how multiple holes are formed by a deep trench process and thin gate dielectric layers 105a and 105b are formed on the sidewall of the holes. Then, the holes are filled with the gate material, such as metal or silicon or polysilicon, to form vertical word lines, such as word lines 104a and 104b. As a result, the array structure shown in FIG. 11B is realized.

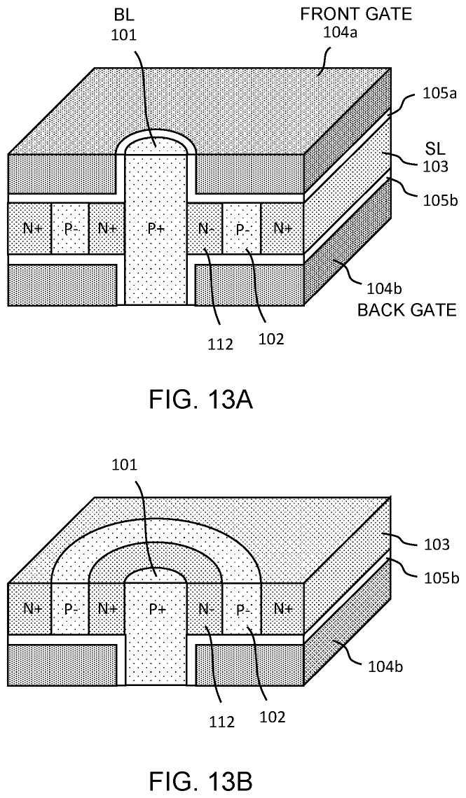

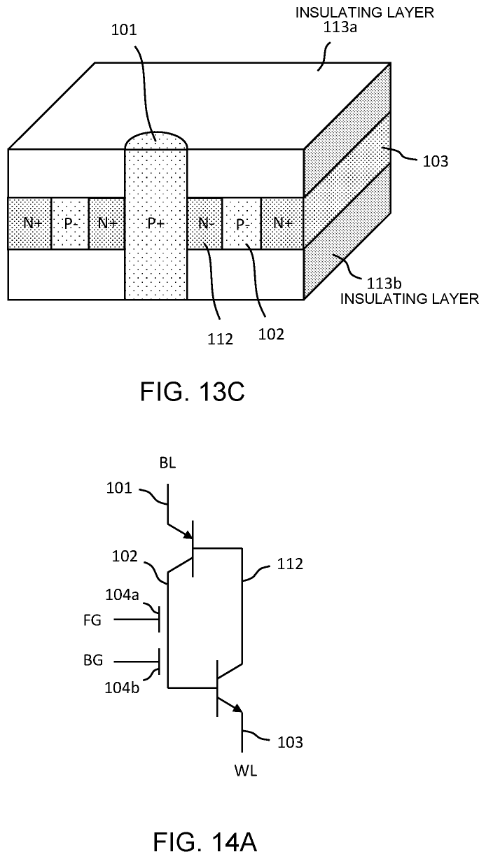

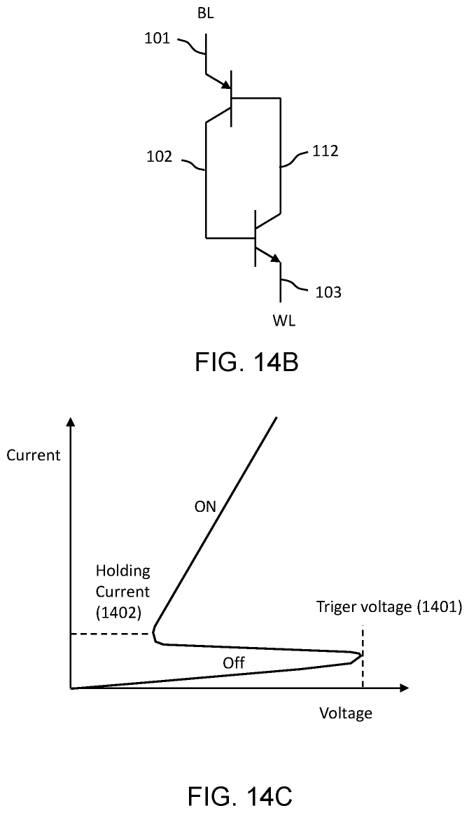

FIG. 13A shows another embodiment of a DRAM-replacement technology according to the invention. This technology uses a 3D thyristor cell and includes P+ silicon or polysilicon for bit line 101, N− silicon or polysilicon 112, P− silicon or polysilicon 102, and N+ silicon or polysilicon for source line 103. The P+ silicon for bit line 101, P− silicon 112, and P− silicon 102 form a PNP bipolar transistor. The N− silicon 112, P− silicon 102, and N+ silicon for source line 103 form an NPN bipolar transistor. The P+ silicon or polysilicon for bit line 101 and N+ silicon or polysilicon for source line 103 are connected to a bit line (BL) and a source line (SL), respectively. Also included are a front gate (FG) 104a and back gate (BG) 104b, respectively, and gate dielectric layers 105a and 105b. The two bipolar transistors form a gate-assisted thyristor cell, as shown in the circuit diagram of FIG. 14A.

FIG. 13B shows the cell structure of FIG. 13A with the front gate 104a and the gate dielectric layer 105a removed. The P− floating body 102 comprises a donut shape as shown.

FIG. 13C shows another embodiment of a 3D thyristor cell structure according to the invention. This embodiment is similar to the embodiment shown in FIG. 13A except that the front gate 104a and back gate 104b are replaced by insulating layers 113a and 113b. This forms a non-gate-assisted thyristor cell as shown in the circuit diagram shown in FIG. 14B.

It should be noted that although the embodiments shown in FIGS. 13A-C show that the shape for the bit line 101 and body 102 is circular, it is obvious that they may have any other shapes, such as square, rectangle, triangle, hexagon, etc. Also, in another embodiment, the materials of 101, 112, 102, and 103 can be reversed to be N+, P−, N−, and P+, respectively. Moreover, similar to FIGS. 5A-D, the cell may have a metal core in the center of bit line 101 to reduce bit line resistance. These variations shall remain in the scope of the invention.

FIG. 14C shows a current to voltage (I-V) curve of the thyristor cell shown in FIG. 13A. When a voltage difference from the BL to WL exceeds a ‘trigger voltage’ 1401, the two bipolar transistors are turned on and cause latch-up to occur. This causes the thyristor cell to conduct current from the BL to the WL, thus it becomes an ‘on-cell’. When the voltage difference from the BL to WL is lowered or reversed to reduce the current to below a ‘holding current’ 1402, the transistors are turned off, thus the cell becomes an ‘off-cell’. By using this process, the thyristor cell functions as a memory cell to store data. Because the cell can be switched between on-cell and off-cell in very short time, such as in the nanosecond range, the cell may be used for high-speed memory, such as for replacement of DRAM or SRAM.

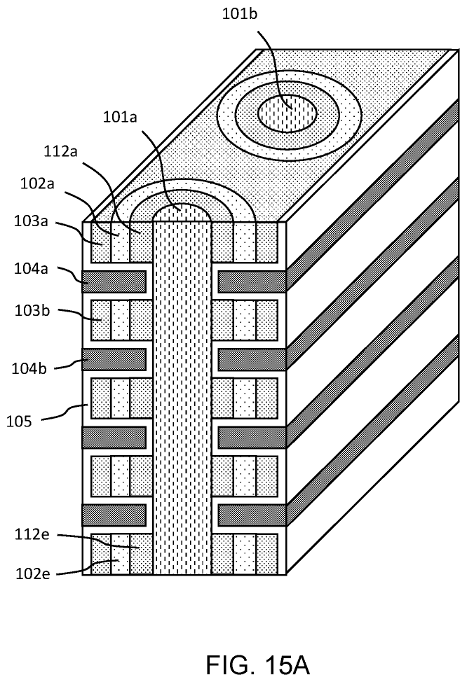

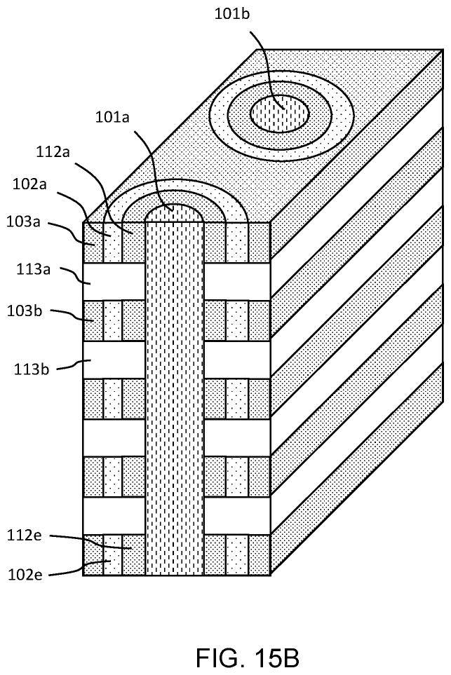

FIG. 15A shows an embodiment of a 3D array structure based on the cell structure shown in FIG. 13A. The 3D array structure shown in FIG. 15A includes P+ silicon or polysilicon bit lines 101a to 101c, N− silicon or polysilicon 112a to 112e, P− silicon or polysilicon 102a to 102e, and N+ silicon or polysilicon word lines 103a and 103b. Also included are front 104a and back 104b gates, and gate dielectric layer 105.

FIG. 15B shows an embodiment of a 3D array structure based on the cell structure shown in FIG. 13C. This embodiment is similar to the embodiment shown in FIG. 15A except that the word line layers 104a and 104b, etc. are replaced with insulating layers 113a and 113b, etc. The 3D array structures shown in FIGS. 15A-B are formed by using similar process steps as shown in FIGS. 4A-F.

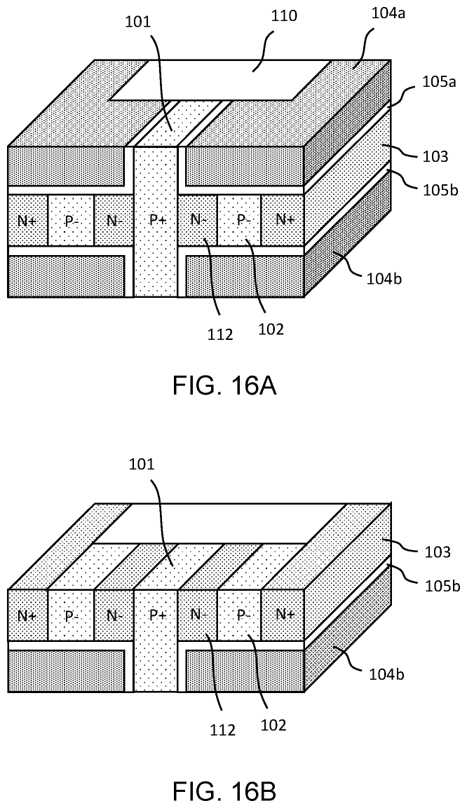

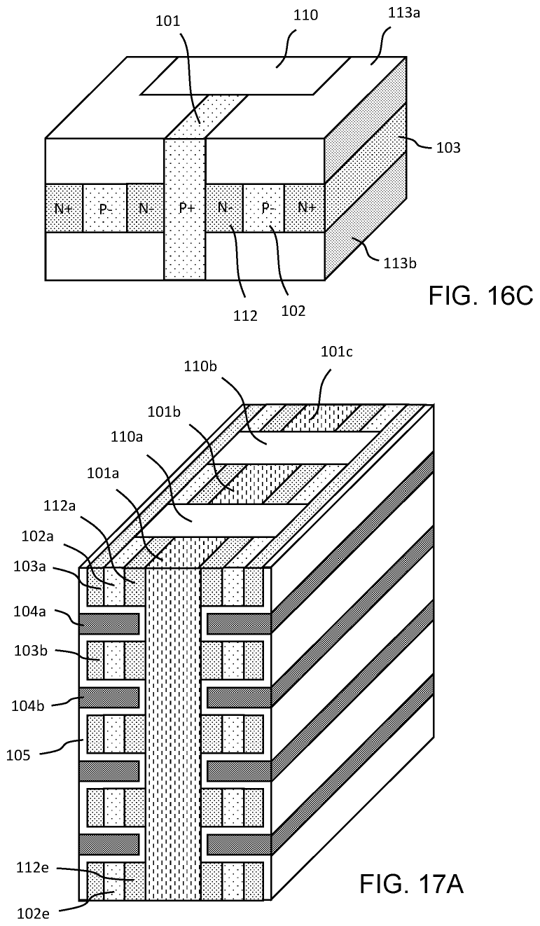

FIG. 16A shows another embodiment of a thyristor cell structure according to the invention. FIG. 16B shows the cell structure shown in FIG. 16A with the front gate 104a and gate dielectric layer 105a removed.

The embodiment shown in FIG. 16A is similar to the embodiment shown in FIG. 13A except that the cell is divided into two cells by an insulating layer 110, such as an oxide material. In this configuration, the memory array capacity is doubled. Similar to FIG. 6C and FIG. 6D, the shapes of the material 101, 112, and 102 can be circular or any other suitable shapes.

FIG. 16C shows another embodiment of a thyristor cell structure according to the invention. This embodiment is similar to the embodiment shown in FIG. 16A except that the front gate 104a and back gate 104b are replaced by insulating layers 113a and 113b. This forms a non-gate-assisted thyristor cell as shown in FIG. 14B.

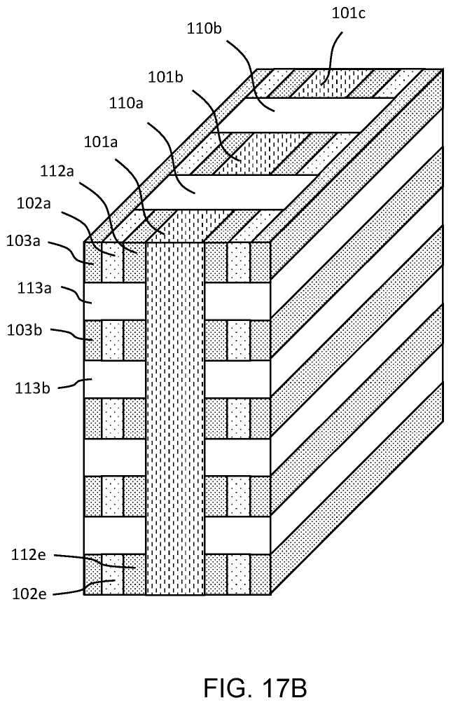

FIG. 17A shows an embodiment of a 3D array structure based on the cell structure shown in FIG. 16A. The embodiment shown in FIG. 17A comprises P+ silicon or polysilicon bit lines 101a to 101c, etc., N− silicon or polysilicon 112a to 112e, etc., P− silicon or polysilicon floating bodies 102a to 102e, etc. N+ silicon or polysilicon source lines 103a and 103b, etc. Also included are front 104a and back 104b gates, gate dielectric layer 105, and insulating layers 110a and 110b.

FIG. 17B shows an embodiment of a 3D array structure based on the cell structure shown in FIG. 16C. This embodiment is similar to the embodiment shown in FIG. 17A except that the word line layers 104a and 104b, etc. are replaced with insulating layers 113a and 113b, etc. The 3D array structures shown in FIG. 17A and FIG. 17B are formed by using similar process steps to those shown and described with reference to FIGS. 8A-F.

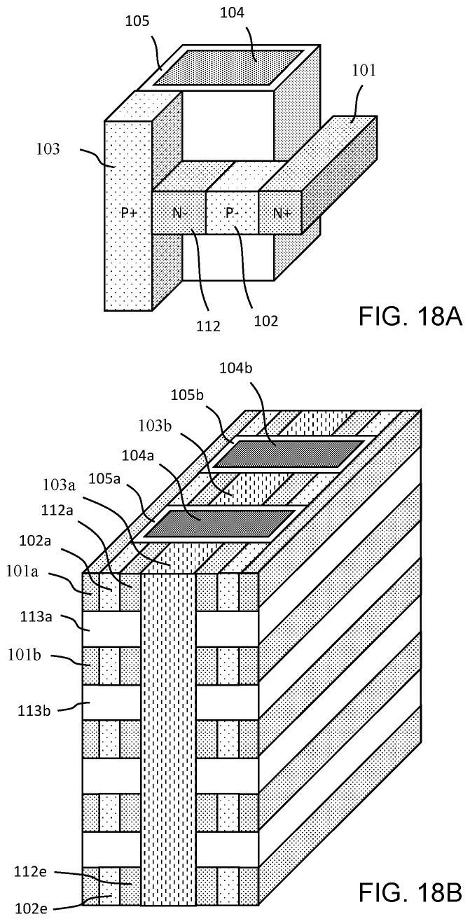

FIG. 18A shows another embodiment of a thyristor cell structure according to the invention. The cell structure shown in FIG. 18A comprises P+ silicon or polysilicon for bit line 101, N− silicon or polysilicon 112, P− silicon or polysilicon 102, and N+ silicon or polysilicon for source line 103. The materials 101 and 103 are connected to a bit line and a source line, respectively. Also shown is a front gate 104 and a gate dielectric layer 105. A back gate is not shown to make it easier to illustrate. In this embodiment, the front gate 104 runs in vertical direction.

FIG. 18B shows an embodiment of a 3D array structure based on the cell structure shown in FIG. 16C. The array structure shown in FIG. 18A comprises P+ silicon or polysilicon bit lines 101a and 101b, etc., N− silicon or polysilicon 112a to 112e, etc., P− silicon or polysilicon 102a to 102e, etc. N+ silicon or polysilicon source lines 103a and 103b, etc., front gate 104a and back gate 104b, gate dielectric layers 105a and 105b, etc., and insulating layers 113a and 113b. This embodiment is formed by using similar process steps as shown and described with respect to FIGS. 10A-D.

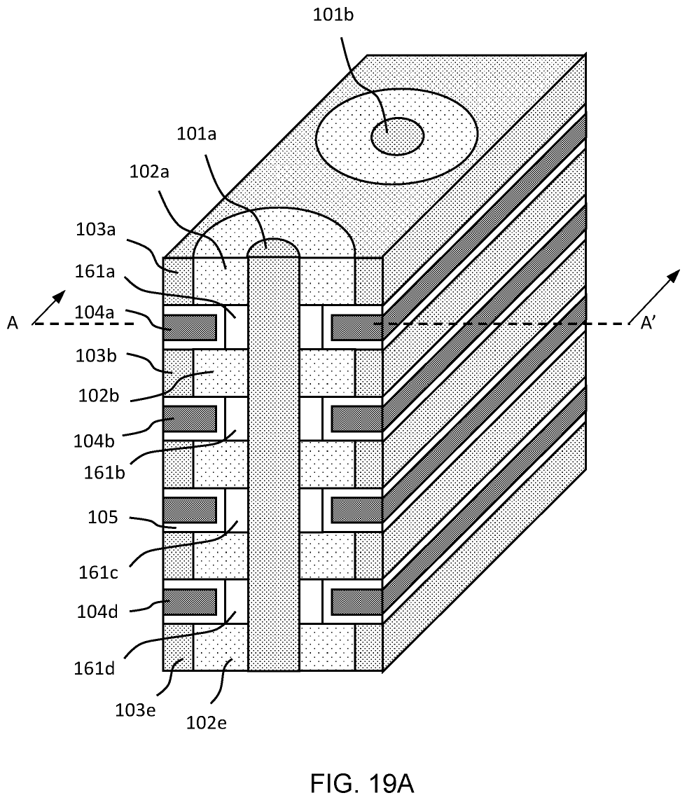

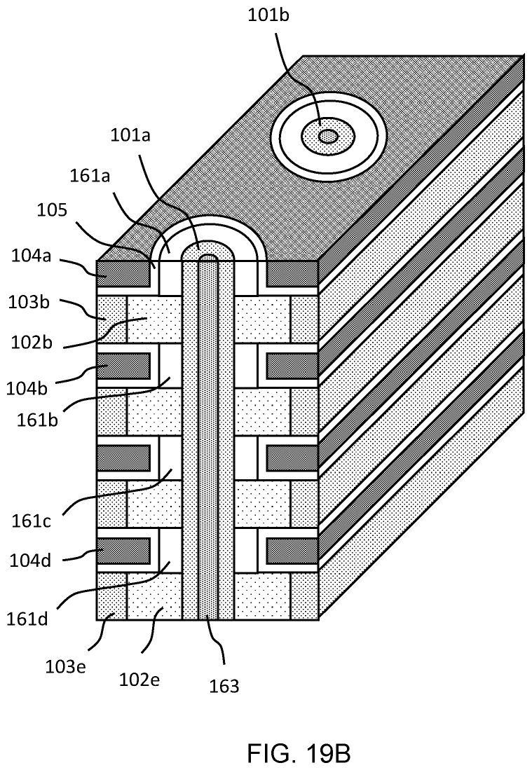

FIG. 19A shows another embodiment of a 3D array structure according to the invention that uses ‘tunnel field-effect transistor (TFET)’ technology. FIG. 19A comprises vertical bit lines 101a and 101b, floating bodies 102a to 102e, and source lines 103a to 103e. In an embodiment, the floating bodies 102a to 102e are formed from an intrinsic semiconductor material, such as silicon.

In an embodiment, the vertical bit lines 101a and 101b and source lines 103a to 103e are formed from P-type or N-type of heavily doped semiconductor material, such as silicon. The vertical bit lines 101a to 101b and the source lines 103a to 103e are material having the opposite type of doping.

In one embodiment, word lines 104a to 104d are formed from conductor material, such as metal or polysilicon. A gate dielectric layer 105 is formed from material, such as gate oxide or high-K material, such as HfO2. Also shown are insulating layers 161a to 161d that are formed from material, such as an oxide or a nitride.

FIG. 19B shows a cross-section of the array structure shown in FIG. 19A that is taken at cross-section indicator A-A′ to reveal the structure of the insulating layer 161a. The structure of the insulating layers 161a to 161d are formed by using an isotropic etching process, such as wet etch, to selectively form recesses through vertical bit line holes, and then forming the insulating layer inside the recesses, as in the process step shown in FIG. 4B.

In another embodiment, a conductor core 163, such as metal or polysilicon, is formed in the center of the vertical bit lines 101a and 101b to reduce the resistance of the vertical bit lines, as shown in FIG. 19B. The conductor core 163 is formed by using a thin-film deposition or a thin-film epitaxial growth process to form a layer of semiconductor for bit line 101a, such as silicon on the sidewall of the vertical hole, and then filling the center of the hole with the conductor core 163.

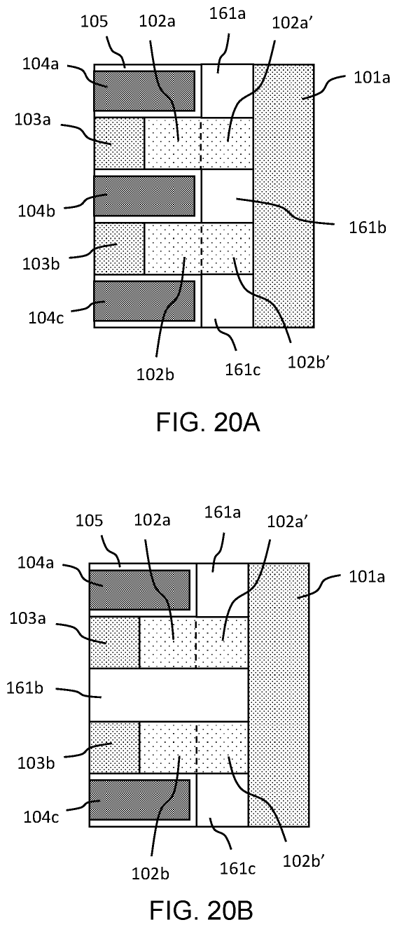

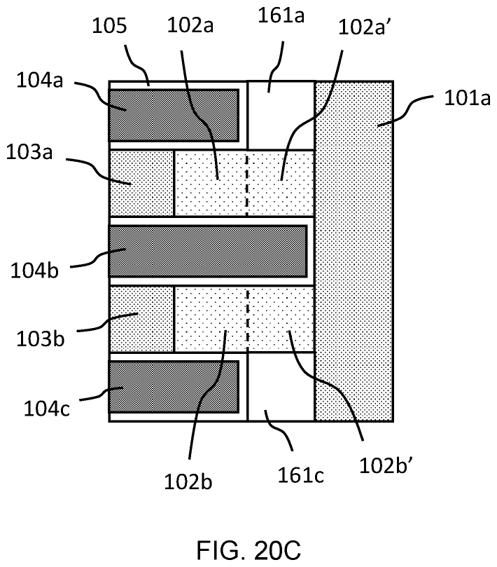

FIG. 20A shows a detailed front view of the 3D array structure shown in FIG. 19A. This view includes vertical bit line 101a, floating bodies 102a, 102a′, 102b, and 102b′, source lines 103a and 103b, word lines 104a to 104c, gate dielectric layer 105, and insulating layers 161a to 161c. It should be noted that the word lines 104a to 104c only partially cover the floating bodies, such as floating bodies 102a and 102b. An electric charge, such as electron holes, can be stored in the portion of the floating bodies 102a and 102b under the word lines 104a to 104c. The number of the stored electron holes can alter the threshold voltage of the cell transistors to represent the data 1 or 0. The portion of the floating bodies 102a′ and 102b′ not being covered by the word lines 104a to 104c form potential wells to isolate the stored electron holes from the bit line 101a.

It should be noticed that the above cell can be operated using dual-gate bias conditions. The even word lines, such as 104a and 104c, are supplied with the front-gate bias condition, and the odd word lines, such as 104b, are supplied with the back-gate bias condition.

In one embodiment, the bit line 101a and the source lines 103a and 103b have N− type and P-type of doping, respectively. During read operations, the bit line 101a is supplied with a positive voltage and the source lines 103a and 103b are supplied with a low voltage, such as 0V. This causes the cells to operate in a reverse bias condition between source and drain.

In another embodiment, the bit line 101a and the source lines 103a and 103b have N-type and P-type of doping, respectively. During read and write operations, the bit line 101a are supplied with low voltage, such as 0V, and the source lines 103a and 103b are supplied with a positive voltage. This causes the cells to operate in a forward bias condition between the source and drain. The word lines 104a and 104b provide controllable injection barriers.

In another embodiment, the bit line 101a and the source lines 103a and 103b have P-type and N-type of doping, respectively. During read operations, the bit line 101a is supplied with a positive voltage and the source lines 103a and 103b are supplied with a low voltage, such as 0V. This causes the cells to operate in a forward bias condition between the source and drain. The word lines 104a and 104b provide controllable injection barriers.

FIG. 20B shows another embodiment of the detailed front view of the 3D array structure according to the invention. This embodiment is similar to the one shown in FIG. 20A except that the word line 104b is replaced with an insulating layer 161b. This forms a single-gate cell structure.

FIG. 20C shows another embodiment of the vertical cross section view of the 3D array structure according to the invention. This embodiment is similar to the one shown in FIG. 20A except that the insulating layer 161b shown in FIG. 20A is removed and the odd word lines, such as 104b cover the entire floating bodies 102a and 102a′.

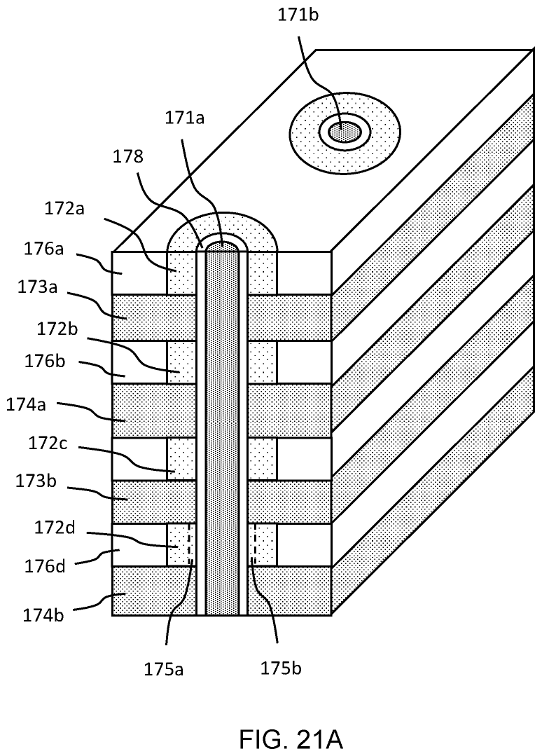

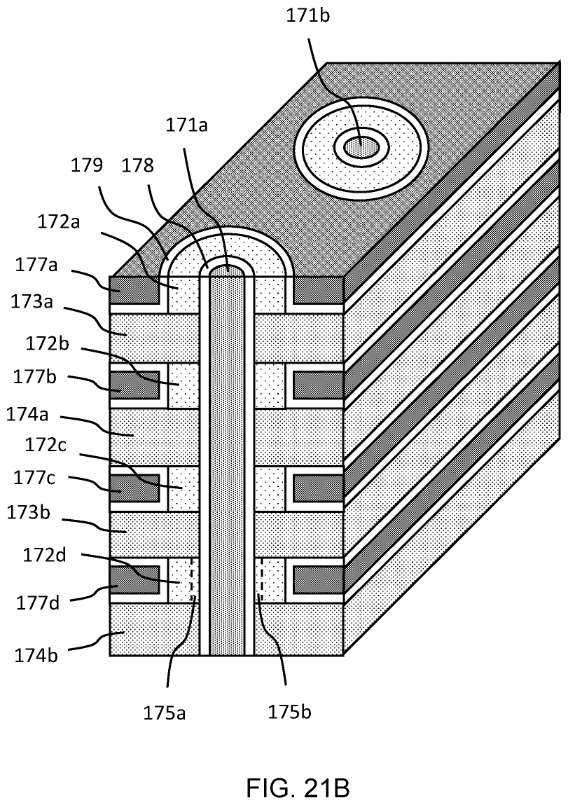

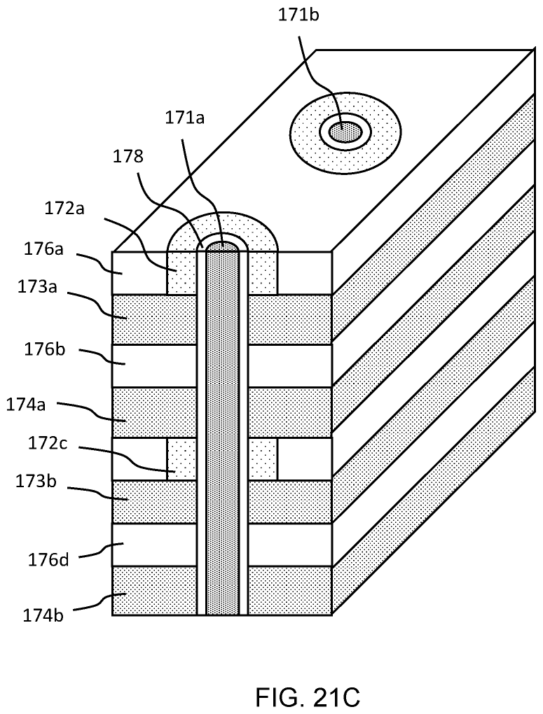

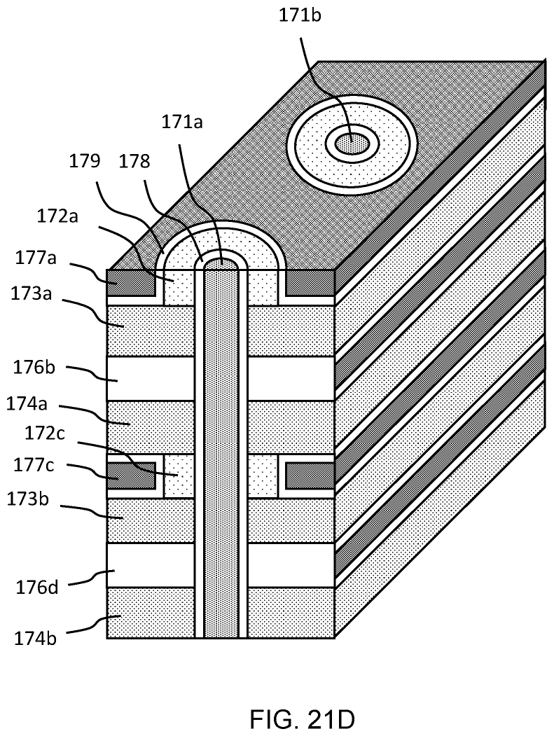

FIG. 21A shows another embodiment of the 3D array structure according to the invention. This embodiment includes vertical word lines 171a and 171b formed of conductor material, such as metal or polysilicon. This embodiment also includes gate dielectric layer 178 made from material, such as gate oxide or high-K material, such as HfO2.

Also shown in FIG. 21A are floating bodies 172a to 172d that are formed by using an isotropic etching process, such as wet etch to selectively form recesses in the insulating layers 176a to 176d through vertical bit line holes, and then forming the silicon layer inside the recesses, as in the process step shown in FIG. 4B.

Also shown in FIG. 21A are bit line layers 173a to 173b and source line layers 174a and 174b. The bit line layers 173a and 173b and the source lines layers 174a and 174b are formed of heavily doped semiconductor, such as silicon. The bit line layers 173a and 173b and the source line layers 174a and 174b have the same type of doping. The floating bodies 172a to 172d are formed of lightly doped semiconductor layers, such as silicon with the opposite type of doping as the bit lines 173a and 173b and the source lines 174a and 174b.

During read operations, the vertical word line 171a is supplied with a read voltage to turn on the vertical channels, such as channels 175a and 175b between the bit lines 173b and the source line 174b to conduct current. Electric charge, such as electron holes, are be stored in the floating bodies 172a to 172d to alter the threshold voltage of the cell transistor to represent data 1 or 0.

FIG. 21B shows another embodiment of the 3D array structure according to the invention. This embodiment is similar to the one shown in FIG. 21A except that the insulating layers 176a to 176d are replaced with conductor layers 177a to 177d, comprising material, such as metal or polysilicon. Also shown is a gate dielectric layer 179 comprising material, such as gate oxide or high-K material, such as HfO2. This forms a dual-gate cell structure which include front gates 171a and 171b and back gates 177a to 177b. During read and write operations, the front gates and back gates are supplied with different bias conditions.

FIG. 21C shows another embodiment of a 3D array structure according to the invention. This embodiment is similar to the embodiment shown in FIG. 21A except that only the even layers of floating bodies 172a and 172c are formed. The odd layers of floating bodies 172b and 172d shown in FIG. 21A are eliminated. For comparison, the structure shown in FIG. 21A shares the bit lines and source lines with adjacent cells. The structure shown in FIG. 21C dedicates one bit line and one source line for each cell.

FIG. 21D shows another embodiment of a 3D array structure according to the invention. This embodiment is similar to the embodiment shown in FIG. 21B except that only the even layers of floating bodies 172a and 172c are formed. The odd layers of floating bodies 172b and 172d shown in FIG. 21A are eliminated. For comparison, the structure shown in FIG. 21B shares the bit lines and source lines with adjacent cells. The structure shown in FIG. 21D dedicates one bit line and one source line for each cell.

FIG. 22A shows another embodiment of a 3D cell structure according to the invention. FIG. 22B shows the cell shown in FIG. 22A separated into three portions (or sections) to show the cell's inner structure. In one embodiment, multiple layers of the cell structure shown in FIG. 22A are stacked to form a high-density cell array.

The materials 181 and 183 are heavily doped semiconductor layers, such as P+ or N+ silicon. The material 181 forms a vertical bit line. The material 183 forms a horizontal source line. The material 182 is a lightly doped semiconductor, such as P− or N− silicon material. The semiconductor layer 182 has the opposite type of doping of the materials 181 and 183. As shown in FIG. 22B, the material 182 forms the floating body of the cell. This forms a floating-body memory cell.

In another embodiment, the material 182 comprises an intrinsic semiconductor, such as silicon. The materials 181 and 183 are heavily doped semiconductor material, such as P+ or N+ silicon material. The materials 181 and 183 have the opposite type of doping. This forms a tunnel field effect transistor (TFET) type of memory cell.

The cell comprises two gates 184 and 186. The gate 184 is connected to a word line. The gate 186 is connected to a read voltage. Gate dielectric layers 185a and 185b comprise gate oxide or high-K material, such as HfO2. Also shown are channel regions 188a and 188b. In one embodiment, the channel length of the gate 186 is longer than that of the gate 184. This reduces the coupling effect of the word line.

Also shown is an insulating layer 187 comprising an oxide to prevent the short of the materials 181 and 183. In one embodiment, a conductor core 189 comprising material, such as a metal, is formed in the center of the vertical bit line 181 to reduce the bit line resistance. The conductor layer 189 can be eliminated without affecting the function of the cell.

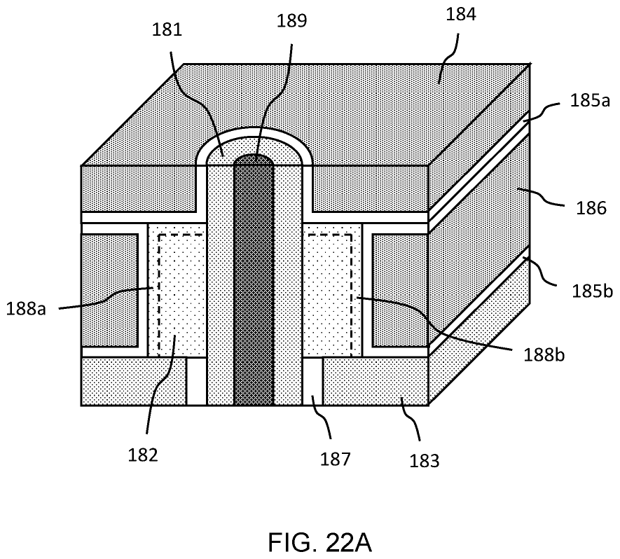

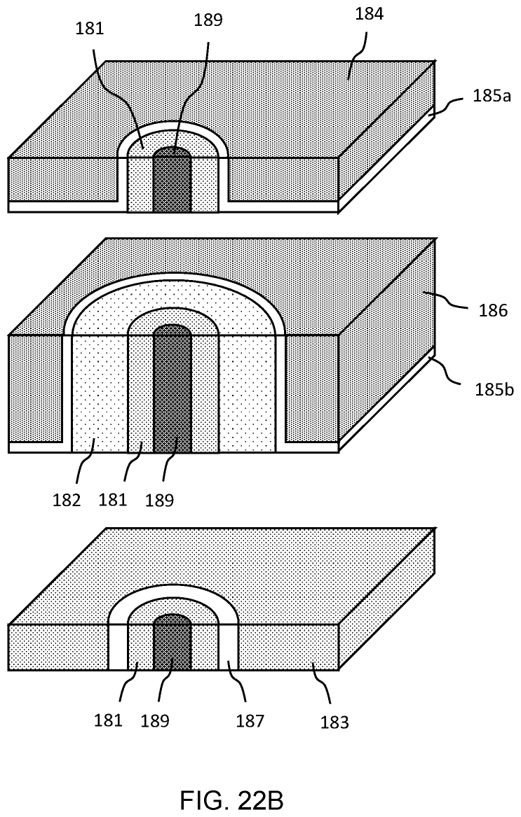

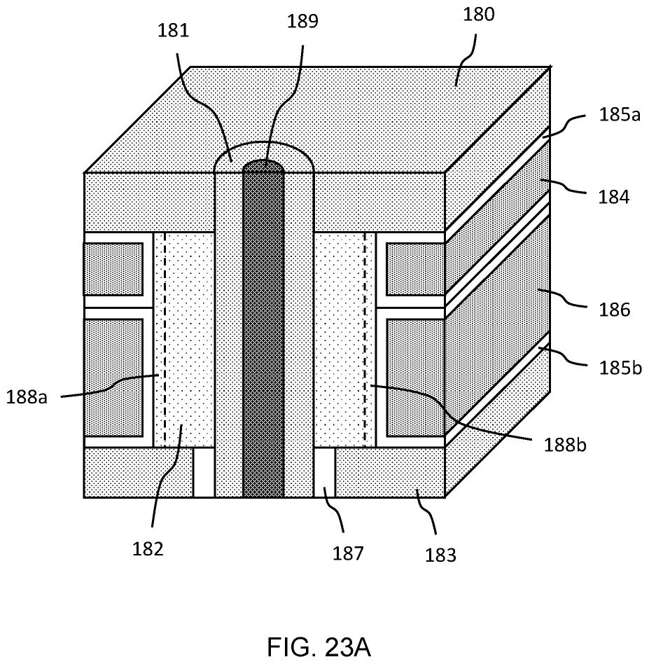

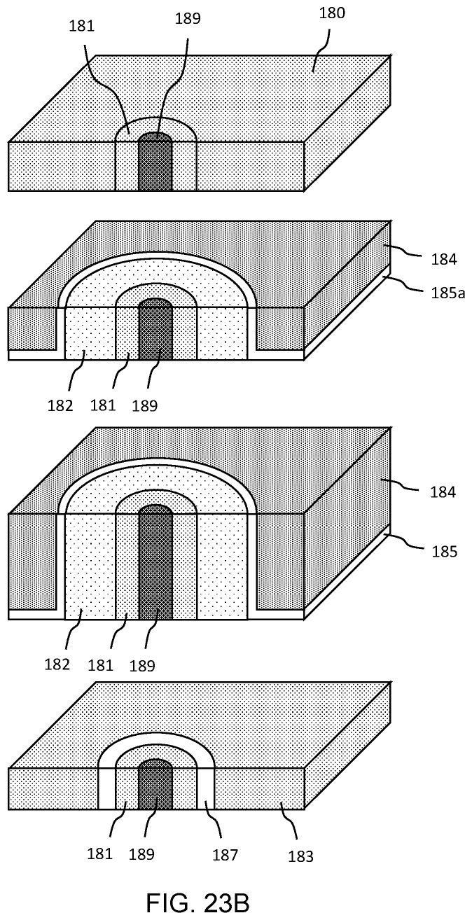

FIG. 23A shows another embodiment of a 3D cell structure according to the invention. FIG. 23B shows the cell shown in FIG. 23A separated into four portions (or sections) to show the cell's inner structure. Multiple layers of the cell structure shown in FIG. 23A are stacked to form a high-density cell array.

The embodiment shown in FIG. 23A is similar to the embodiment shown in FIG. 22A except that an additional layer 180 is added. The layers 180, 181 and 183 are heavily doped semiconductor layers comprising material, such as P+ or N+ silicon. Layer 181 forms a vertical bit line. Layer 183 forms a horizontal source line. The layers 180 and 181 have the same type of doping so that layer 180 becomes an extension of the vertical bit line 181.

The layer 182 is a lightly doped semiconductor, such as P− or N− silicon. The semiconductor layer 182 has the opposite type of doping of the layers 181 and 183. As shown in FIG. 23B, the material 182 forms the floating body of the cell. This results in a floating-body memory cell.

In another embodiment, the material 182 is an intrinsic semiconductor, such as silicon. The material 181 and 183 are heavily doped semiconductors, such as P+ or N+ silicon. The material 181 and 183 have the opposite type of doping. This forms a tunnel field effect transistor (TFET) type of memory cell.

The cell comprises two gates 184 and 186. The gate 184 is connected to a word line. The gate 186 is connected to a read voltage. Gate dielectric layers 185a and 185b comprise material, such as gate oxide or high-K material, such as HfO2. Also shown are channel regions 188a and 188b. In one embodiment, the channel length of the gate 186 is longer than that of the gate 184. This reduces the coupling effect of the word line.

Also shown in an insulating layer 187 comprising material, such as oxide to prevent the short of layers 181 and 183. In one embodiment, a conductor core 189 comprising material, such as metal, is formed in the center of the vertical bit line 181 to reduce the bit line resistance. In one embodiment, the conductor layer 189 can be eliminated without affecting the function of the cell.

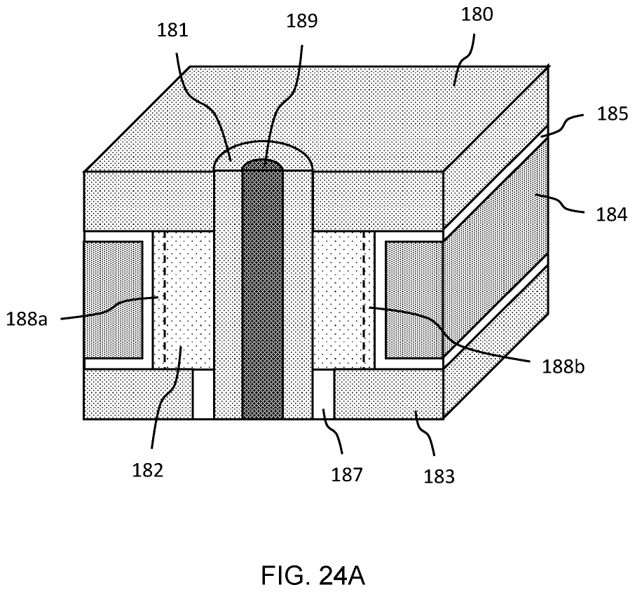

FIG. 24A shows another embodiment of the 3D cell structure according to the invention. FIG. 24B shows the di-section view of the structure shown in FIG. 24A. Multiple layers of the cell structure shown in FIG. 24A are stacked to form a high-density cell array.

The embodiment shown in FIG. 24A is similar to the embodiment shown in FIG. 23A except that the second gate 186 is removed. The materials 180, 181 and 183 are heavily doped semiconductor layers, such as P+ or N+ silicon. The material 181 forms a vertical bit line. The material 183 forms a horizontal source line. The material 180 and 181 have the same type of doping so that the material 180 becomes an extension of the vertical bit line 181.

The material 182 is a lightly doped semiconductor, such as P− or N− silicon. The semiconductor layer 182 has the opposite type of doping of materials 181 and 183. As shown in FIG. 24B, the material 182 forms a floating body of the cell. This results in a floating-body memory cell.

In another embodiment, the material 182 comprises an intrinsic semiconductor, such as silicon. The material 181 and 183 are heavily doped semiconductors, such as P+ or N+ silicon. The materials 181 and 183 have the opposite type of doping. This forms a tunnel field effect transistor (TFET) type of memory cell.

The cell comprises only one gate 184. The gate 184 is connected to a word line. A gate dielectric layer 185 comprises material, such as gate oxide or high-K material, such as HfO2. Also shown are channel regions 188a and 188b.

An insulating layer 187 comprises material, such as oxide to prevent the short of the materials 181 and 183. In one embodiment, a conductor core 189 comprising material, such as metal, is formed in the center of the vertical bit line 181 to reduce the bit line resistance. In one embodiment, the conductor layer 189 is eliminated without affecting the function of the cell.

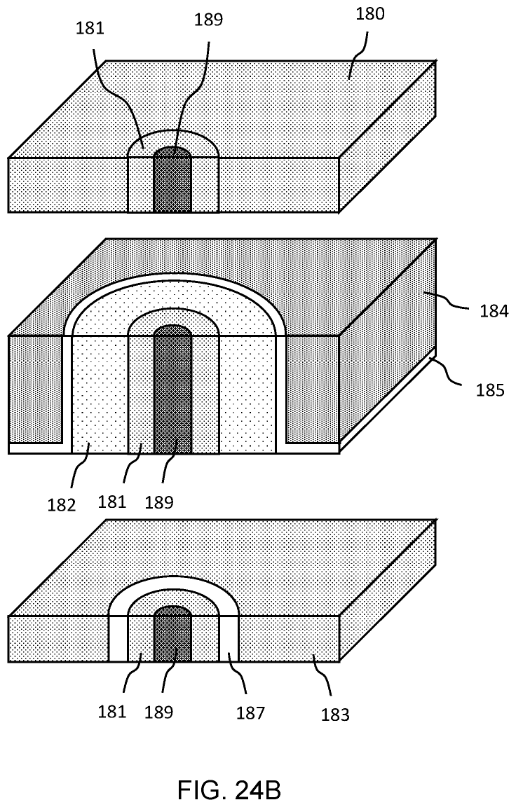

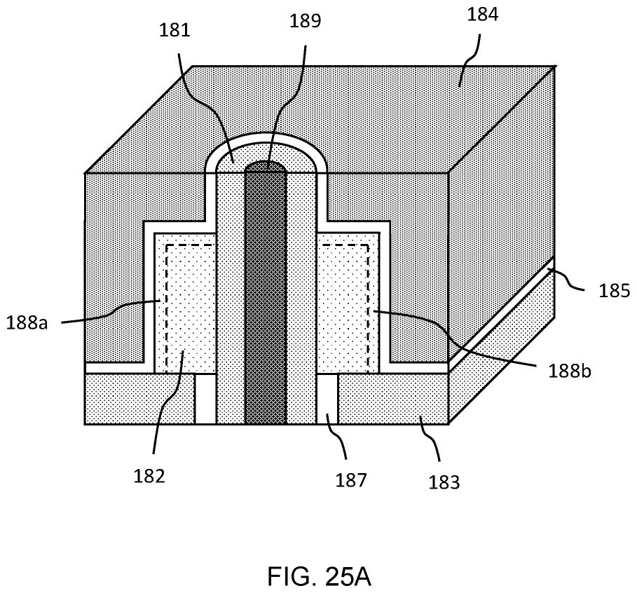

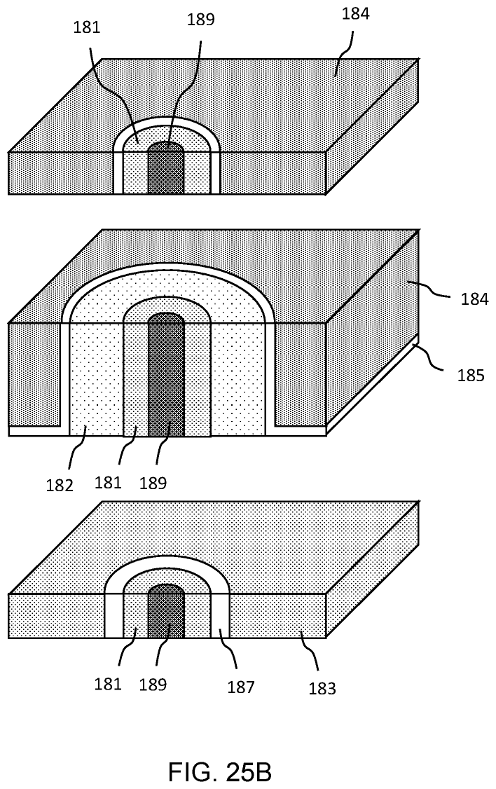

FIG. 25A shows another embodiment of 3D cell structure according to the invention. FIG. 25B shows a di-section view of the structure shown in FIG. 25A. Multiple layers of the cell structure shown in FIG. 25A are stacked to form a high-density cell array.

This embodiment is similar to the embodiment shown in FIG. 24A except that the semiconductor layer extension 180 is removed. The materials 181 and 183 are heavily doped semiconductor layers, comprising P+ or N+ silicon. The material 181 forms a vertical bit line and the material 183 forms a horizontal source line.

The material 182 is a lightly doped semiconductor, comprising material such as P− or N− silicon. The semiconductor layer 182 has the opposite type of doping as the materials 181 and 183. As shown in FIG. 25B, the material 182 forms a floating body of the cell. This results in a floating-body memory cell.

In another embodiment, the material 182 is an intrinsic semiconductor material, such as silicon. The materials 181 and 183 are heavily doped semiconductor materials, such as P+ or N+ silicon. The materials 181 and 183 have the opposite type of doping. This forms a tunnel field effect transistor (TFET) type of memory cell.

The cell comprises only one gate 184. The gate 184 is connected to a word line. Also shown is a gate dielectric layer 185 comprising material, such as gate oxide or high-K material, such as HfO2. Channel regions 188a and 188b are also shown.

An insulating layer 187 comprises material, such as oxide to prevent the short of material 181 and 183. In one embodiment, a conductor core 189 comprising material, such as metal, is formed in the center of the vertical bit line 181 to reduce the bit line resistance. In one embodiment, the conductor layer 189 is eliminated without affecting the function of the cell.

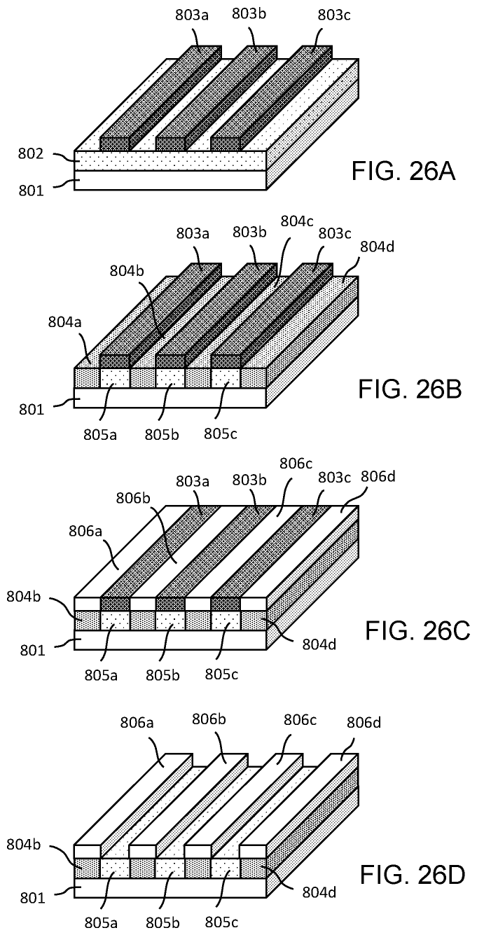

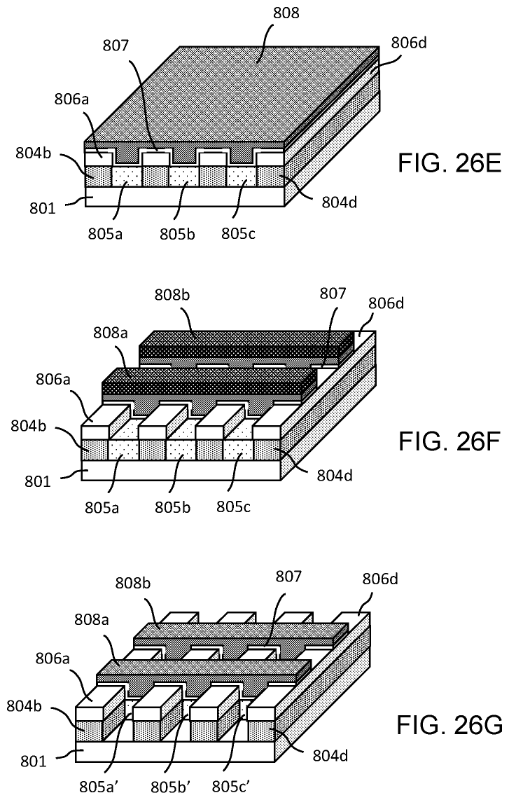

FIGS. 26A-G shows simplified key process steps of another embodiment of a floating body cell “AND” array according to the invention.

FIG. 26A comprises an insulating layer 801, such as oxide, and a P− or N− silicon or polysilicon layer 802. A sacrificial material layer is deposited on top of the silicon or polysilicon layer 802 and pattern-etched to form the pattern features 803a to 803c.

FIG. 26B shows how regions 804a to 804d are implanted or diffused with the opposite type of doping of the silicon or polysilicon layer 802 by using the sacrificial layer features 803a to 803c as masks. This forms N+ or P+ silicon or polysilicon strips 804a to 804d. The even and odd strips are bit lines and source lines, respectively. It should be noted that the junction of the doping shall reach the insulating layer 801, thus it forms isolated P− or N− silicon or polysilicon strips 805a to 805c.

FIG. 26C shows how an insulating layer, such as oxide, is deposited and etched back to form individual strips 806a to 806d. In another embodiment, the insulator strips are formed by using a chemical mechanical planarization (CMP) process to remove the top portion of the insulating layer.

FIG. 26D shows how the sacrificial material layer 803a to 803c are selectively etched.

FIG. 26E shows how a thin gate dielectric layer 807 comprising material, such as oxide, and a gate material layer 808 comprising material, such as metal or polysilicon, are deposited.

FIG. 26F shows how the gate material layer 808 and the gate dielectric layer 807 are pattern-etched to form the word lines. In one embodiment, the materials 808a and 808b are hard masks or photoresists.

FIG. 26G shows how the P− or N− silicon or polysilicon layers 805a to 805c are self-align etched by using the hard masks 808a and 808b. This forms P− or N− silicon or polysilicon floating bodies 805a′ to 805c′.

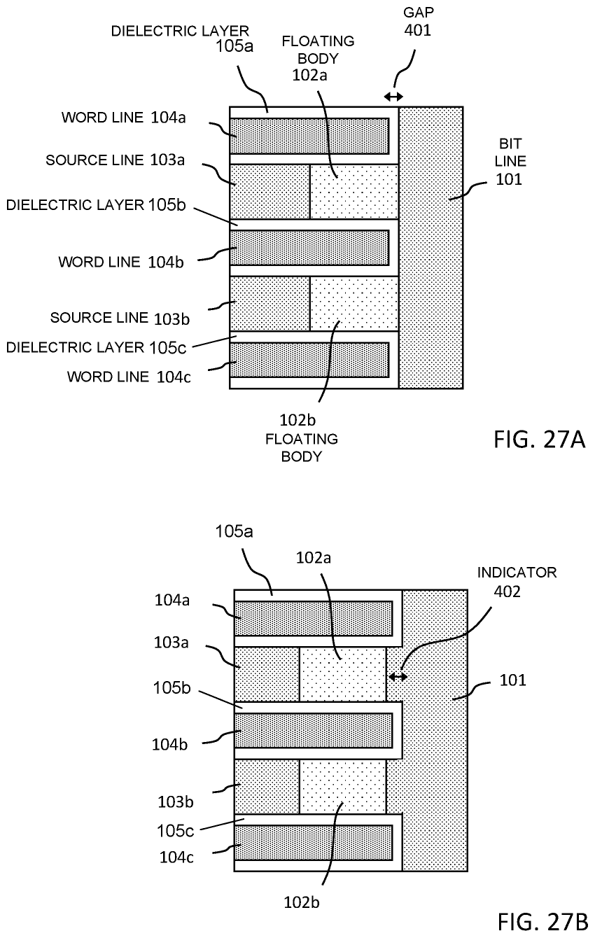

FIG. 27A shows an embodiment of a floating body cell structure constructed according to the invention. The cell structure comprises word lines 104a-c, floating bodies 102a-b, bit line 101, source lines 103a-b, and gate dielectric layers 105a-c. In this embodiment, the cell structure has a gap 401 between the drain junction (bit line 101) and the gate (word line 104a) due to the thickness of the gate dielectric layers 105a-c. This gap increases the intrinsic threshold voltage (Vt) and the band-to-band tunneling (BTBT) voltage of the cell.

FIG. 27B shows an embodiment of a floating body cell structure that provides a lower intrinsic threshold voltage or lower band-to-band voltage. In this embodiment, the drain junction of the bit line 101 is extended under the word line 104a as shown at indicator 402. In one embodiment, this structure is formed by using an isotropic doping process, such as plasma doping or gas-phase doping, or by applying a proper high temperature for a period of time to drive in the diffusion depth in the area of indicator 402 from the bit line 101.

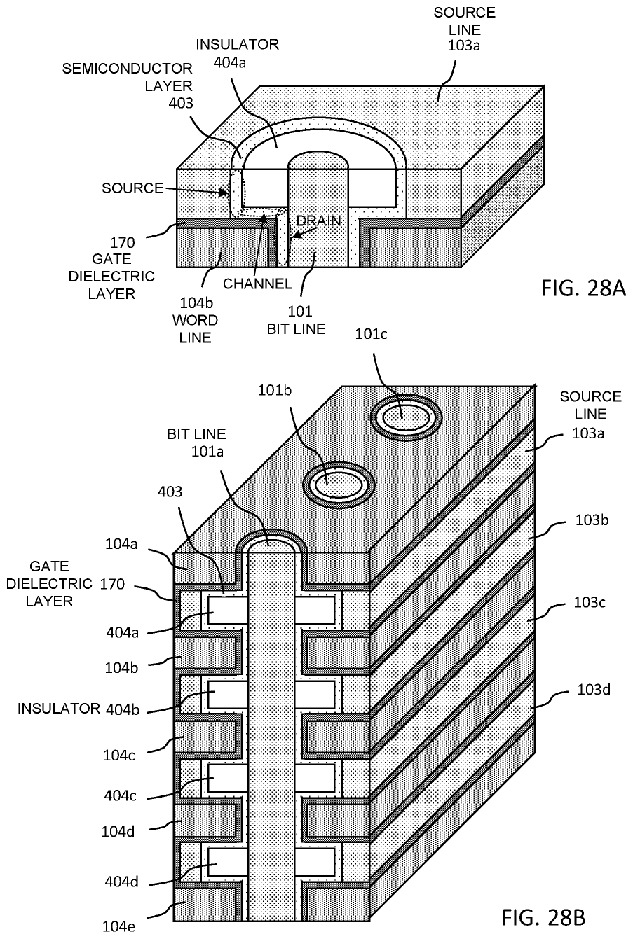

FIG. 28A shows another embodiment of a 3D cell structure using a “thin-film transistor (TFT)” structure according to the invention. In this embodiment, a vertical bit line 101 is formed of conductor material, such as metal or polysilicon. A word line layer 104b is formed of conductor material, such as metal or polysilicon. In one embodiment, a gate dielectric layer 170 comprises a multiple-layer structure. In one embodiment, the gate dielectric layer 170 is a charge-trapping layer, such as nitride-oxide-nitride (ONO) or oxide-nitride (ON) layers to form flash memory cells. In another embodiment, the gate dielectric layer (170) comprises at least one ferroelectric film, such as lead zirconate titanate (PZT) or hafnium oxide (HfO2), for example, to form ferroelectric random-access memory (FRAM) cells.

The cell structure shown in FIG. 28A also comprises a semiconductor layer 403, such as a silicon layer to form the channel of the cell transistor. Also provided is an insulator 404a, such as an oxide. In one embodiment, the bit line 101 and source line 103a are formed of silicon or polysilicon. The channel layer 403 has the same type of doping as the bit line 101 and source line 103a to form junction-less transistors. For example, the “drain”, “source” and “channel” regions shown in FIG. 28A form a junction-less transistor. In another embodiment, the channel layer 403 has the opposite type of doping as the bit line 101 and source line 103a to form a traditional transistor.

FIG. 28B shows an embodiment of the 3D array structure using the cell structure shown in FIG. 28A. The 3D array comprises vertical bit lines 101a-c, source lines 103a-d, word lines 104a-e, gate dielectric layer 170 that comprises material such as ONO, ON, or ferroelectric layers, depending on the type of the memory technologies, and a semiconductor channel layer 403. Also shown are insulators 404a-d that are formed of insulating material, such as an oxide.

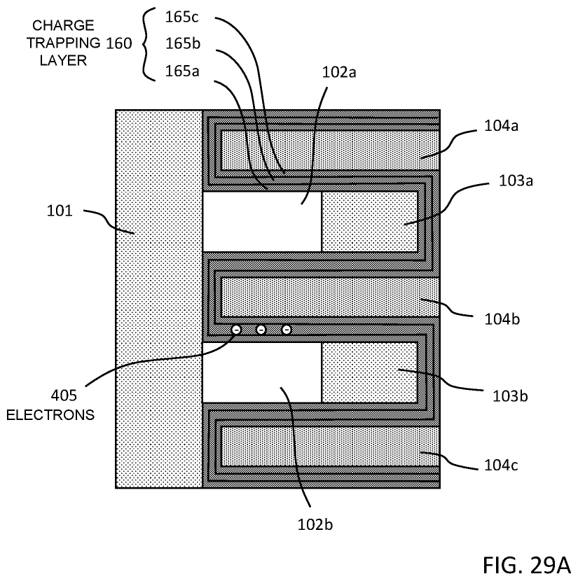

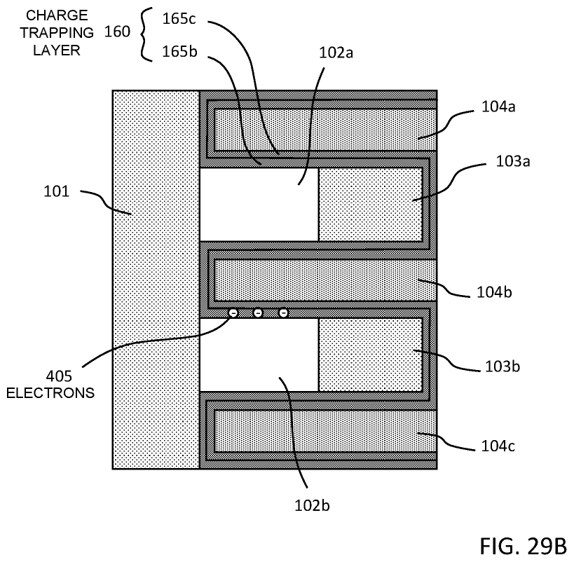

FIG. 29A shows another embodiment of a 3D cell structure based on the array embodiment shown in FIGS. 4N-O. This cell structure is similar to the one shown in FIGS. 1A-B except that the gate dielectric layer 105 is replaced with a charge-trapping layer 160. FIG. 29A shows a detailed embodiment of the structure of the charge trapping layer 160.

In one embodiment, the charge-trapping layer 160 comprises a sandwich structure of oxide-nitride-oxide (ONO) layers. Thus, the charge-trapping layer 160 comprises at least three layers 165a to 165c. The layer 165a is a tunnel oxide layer, which is thin enough to allow electrons to tunnel through when a high electric field is applied. The layer 165b is a nitride layer that may trap electrons (as shown by indicator 405) for data storage. The layer 165c is a blocking oxide, which is thick enough to prevent electrons from tunneling through to the word lines 104a-c. In another embodiment, the layer 165c is a tunnel oxide layer and the layer 165a is a blocking oxide layer. In this embodiment, during programming, the electrons or holes are injected from the selected word line, such as word line 104b to the nitride layer 165b.

The three ONO layers 165a-c are used as an example for the charge-trapping layer 160, however, any number of additional nitride and oxide layers can be added in-between the layers 165a-c. For example, in another embodiment, the charge-trapping layer 160 comprises oxide-nitride-oxide-nitride-oxide (ONONO) layers. These variations of the charge-trapping layer are in the scope of the invention.

Previous embodiments, shown in FIG. 4N-O, use only a nitride layer for the charge trapping layer 160. However, when using ONO layers as shown in FIG. 29A, due to the oxide layer 165a having a higher electrical barrier than a nitride layer, it is more difficult for the electrons trapped in the nitride layer 165b to escape. Therefore, the data retention time for the embodiment using ONO layers is much longer, on the order of years. This embodiment may be used as a permanent non-volatile memory. However, due to the oxide layer 165a having a higher electrical barrier, this embodiment may require a higher write voltage, such as 10V to 20V.

The embodiment shown in FIG. 29A can be programmed by using conventional channel hot-electron (CHE) injection, Fowler-Nordheim (FN) tunneling, hot-hole injection, or any other suitable program mechanisms. Thus, this embodiment may be suitable for implementing 3D NOR flash memory products.

In another embodiment, the cell structure shown in FIG. 29A is used in a dual-mode application for both volatile and non-volatile data storages. For volatile data storage, the input data is stored in the floating bodies 102a-b. This provides increase program speed. After that, the data is programmed in the charge-trapping layer 160 for non-volatile data storage.

FIG. 29B shows another embodiment of a cell structure constructed according to the invention. This embodiment is similar to the embodiment shown in FIG. 29A except that the tunnel oxide layer 165a is eliminated. As a result, the charge-trapping layer 160 comprises a nitride layer 165b and a blocking oxide layer 165c. This configuration reduces the tunneling barrier (that is present in FIG. 29A) so that electrons or holes can be injected into the nitride layer 165b with a lower program voltage, such as 3-5V and shorter program time, such as 100 ns. However, due to the lower tunneling barrier, the electrons or holes trapped in the nitride layer 165b may escape after a short time. Therefore, a refresh operation can be used to periodically read the data from the cells and re-program the data back to the nitride layer 165b. This embodiment is suitable for implementing DRAM products.

In another embodiment, the layer 165c is a nitride layer and the layer 165b is a blocking oxide layer. In this embodiment, during programming, the electrons or holes are injected from the selected word line, such as word line 104b to the nitride layer 165c.

In FIG. 29B, a nitride layer 165b and an oxide layer 165c are used as an example of the charge-trapping layer 160, however, any number of additional nitride and oxide layers can be added in-between the layers 165b and 165c. For example, in another embodiment, the charge-trapping layer 160 comprises nitride-oxide-nitride-oxide (NONO) layers. These variations of the charge-trapping layer 160 are within the scope of the invention.

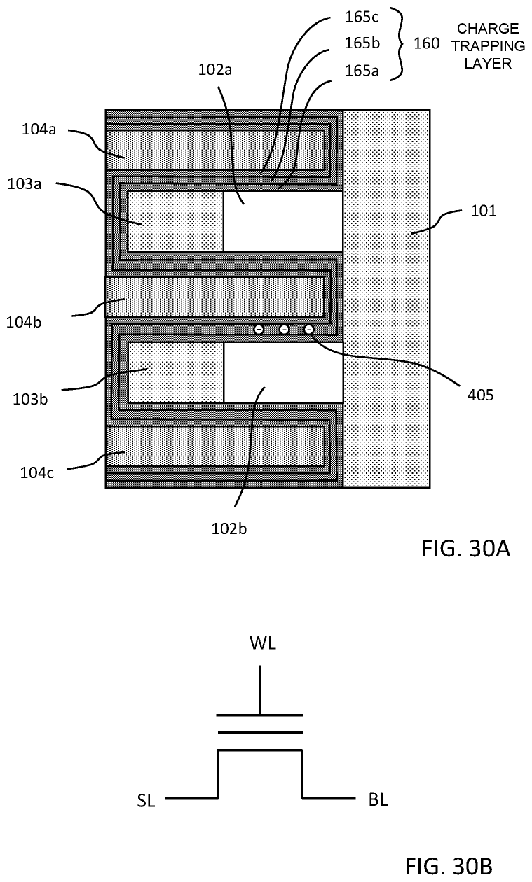

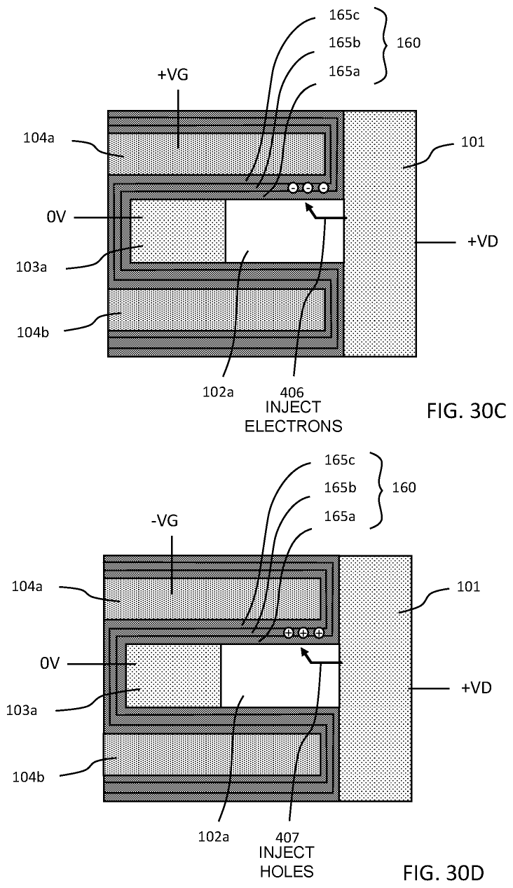

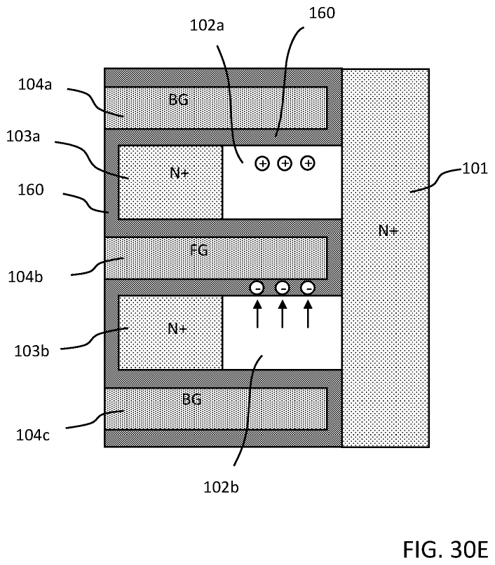

FIG. 30A shows an embodiment of a cell structure in which the charge-trapping layer 160 comprises multiple layers 165a-c, such as oxide-nitride-oxide (ONO) layers. In one embodiment, the layer 165a is a tunnel oxide layer that is thin enough to allow electrons to tunnel through when a high electric field is applied. The layer 165b is a nitride layer that traps electrons, as shown at indicator 405 for data storage. The layer 165c is a blocking oxide that is thick enough to prevent electrons tunneling through to the word lines 104a-c. In another embodiment, the layer 165c is a tunnel oxide layer and the layer 165a is a blocking oxide layer. In this embodiment, during programming, the electrons or holes are injected from the selected word line, such as word line 104b to the nitride layer 165b.

It should be noted that although ONO layers 165a-c are used as an example for the charge-trapping layer 160, any number of additional nitride and oxide layers may be added in-between the layers 165a to 165c. For example, in another embodiment, the charge-trapping layer 160 comprises oxide-nitride-oxide-nitride-oxide (ONONO) layers. These variations of the charge-trapping layer 160 are within the scope of the invention.

The embodiment shown in FIG. 30A is programmed by using conventional channel hot-electron (CHE) injection, Fowler-Nordheim (FN) tunneling, hot-hole injection, or any other suitable program mechanisms. The conventional program conditions for these mechanisms can be applied to this embodiment.

FIG. 30B shows an equivalent circuit of the NOR flash memory cell shown in FIG. 30A.

FIGS. 30C-D show embodiments of program and erase operations and conditions according to the invention.

FIG. 30C shows an embodiment of programing operations using channel hot electron (CHE) injection for use with the cell structure shown in FIG. 30A. The word line 104a and the bit line 101 are supplied with positive voltage +VG and +VD, such as 10V and 5V, respectively. The source line 103a is supplied with a low voltage, such as 0V. This will cause current to flow through the channel and cause electrons to be injected into the charge-trapping layer 160, as shown by the arrow 406, due to the high electric field applied to the word line 104a. The electrons are trapped in the nitride layer 165b near the drain side (bit line 101) to increase the threshold voltage of the cell.

FIG. 30D shows an embodiment of erase operations using hot-hole injection (HHI) for use with the cell structure shown in FIG. 30A. The word line 104a and bit line 101 are supplied with a negative voltage −VG, such as −5V and a positive voltage such as +5V, respectively. The source line 103a is supplied with a low voltage such as 0V. This will turn off the channel and cause band-to-band tunneling (BTBT) to occur in the drain side and cause holes to be injected to the charge-trapping layer 160 due to the high electric field applied to the word line 104a, as shown by the arrow 407. The holes neutralize the electrons trapped in the nitride layer 165b near the drain side (bit line 101) to decrease the threshold voltage of the cell.

It should be noted that because the program and erase operations shown in FIGS. both occurred in the drain side (bit line 101), the channel near the source side 103a remains in enhancement mode (Vt>0V). Therefore, the ‘over-erase’ problem of conventional NOR flash memory is eliminated.

In another embodiment, the cell structure shown in FIG. 30A is used in a dual-mode application to provide both volatile and non-volatile data storages. For volatile data storage, the input data is stored in the floating bodies 102a-b. This increases the program speed. After that, the data is programmed into the charge-trapping layer 160 for non-volatile data storage.

FIG. 30E shows an embodiment of non-volatile program operations for use with the cell structure shown in FIG. 30A to write the data stored in the floating bodies 102a-b to the charge-trapping layer 160. Assuming the data stored in the floating bodies 102a and 102b are ‘1’ and ‘0’, respectively. During the non-volatile program operation, the front gate 104b is supplied with a program voltage, such as 3-5V for a nitride layer and 10-20V for ONO layers. The bit line 101 and the source lines 103a-b are floating. For the floating body 102a, the holes stored in the floating body 102a reduce the electrical field between the front gate 104b and the floating body to below the threshold of a Fowler-Nordheim tunneling (F-N) mechanism. Therefore, the F-N tunneling will not happen. For the floating body 102b, due to the fact that there are no holes in the floating body 102b, the electrical field between the front gate 104b and the floating body 102b is sufficient to induce F-N tunneling. Thus, electrons are injected into the charge-trapping layer 160 and trapped inside this layer to increase the threshold voltage of the cell transistor.

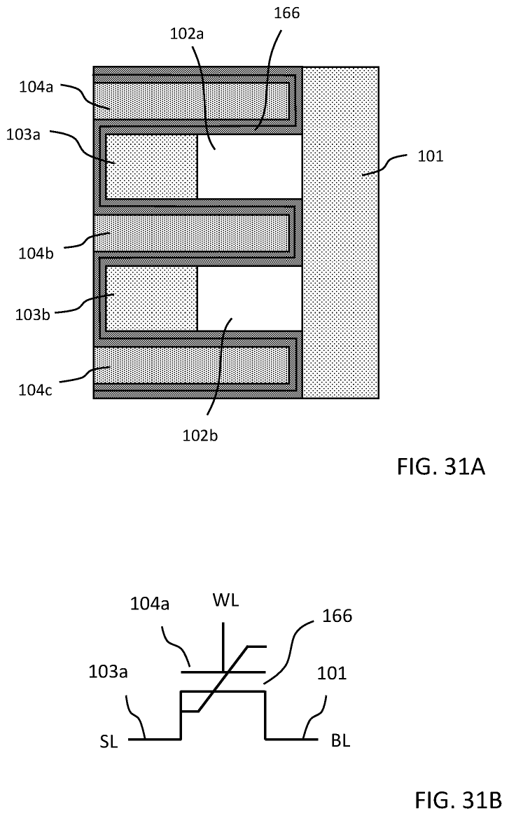

FIG. 31A shows another embodiment of a cell structure for a 3D NOR-type array using ferroelectric field-effect transistors (FeFET) according to the invention. This embodiment is similar to the cell structure shown in FIG. 30A except that the charge-trapping layer 160 is replaced with a ferroelectric layer 166. The ferroelectric layer 166 comprises multiple layers with at least one ferroelectric layer, such as lead zirconate titanate (PZT) or hafnium oxide (HfO2). By applying proper bias conditions, the polarity of the ferroelectric material can be switched to represent the stored data. The conventional read and write conditions for FeFET can be applied to this embodiment.

FIG. 31B shows an equivalent circuit of the cell shown in FIG. 31A.

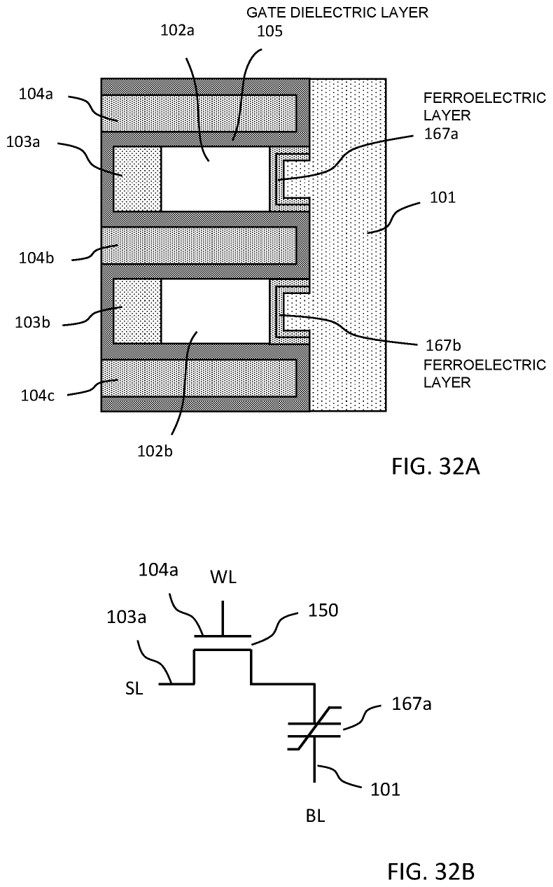

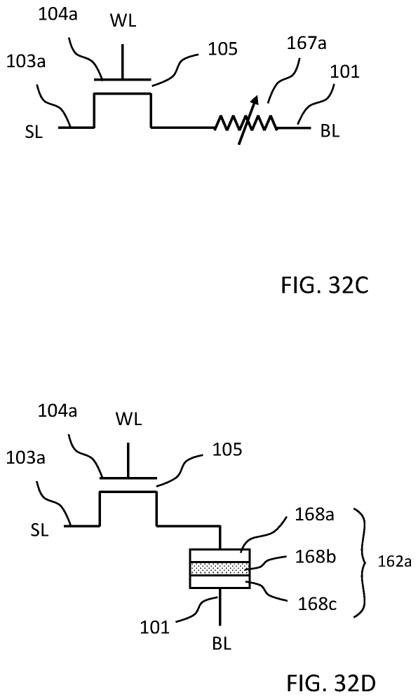

FIG. 32A show another embodiment of a cell structure for a 3D NOR-type array for ferroelectric random-access memory (FRAM) according to the invention. This embodiment is similar to the cell structure shown in FIG. 31A except that the ferroelectric layers 167a and 167b are formed in the junction of the bit line 101 and the floating bodies 102a and 102b, respectively. The cell structure also comprises a gate dielectric layer 105, such as a thin oxide layer or high-K material, such as hafnium oxide (HfO₂) layer. Please refer to the description of FIG. 31A for detailed description of the cell structure. In one embodiment, the ferroelectric layers 167a and 167b comprise multiple layers with at least one ferroelectric layer, such as lead zirconate titanate (PZT) or hafnium oxide (HfO2).

FIG. 32B shows the equivalent circuit of the cell structure shown in FIG. 32A. The ferroelectric layer 167a forms a ferroelectric capacitor. By applying proper bias conditions, the polarity of the ferroelectric material can be switched to represent the stored data. The conventional read and write conditions for FRAM can be applied to this embodiment.

In addition to FRAM, the cell structure shown in FIG. 32A can be applied to other memory technologies, such as resistive random-access memory (RRAM), phase-change memory (PCM), or magnetoresistive random-access memory (MRAM). For different technologies, the material and structure of the layers 167a and 167b may be different.

FIG. 32C shows an equivalent circuit of the cell structure for RRAM and PCM embodiments. For RRAM embodiments, the layer 167a is formed of multiple layers comprising at least one resistive layer, such as hafnium oxide (HfOx), titanium oxide (TiOx), tantalum oxide (TaOx). The conventional read and write conditions for RRAM can be applied to this embodiment. By applying proper bias conditions, the resistance of the resistive layer 167a can be changed to represent the stored data.

For PCM embodiments, the layer 167a is formed of multiple layers comprising at least one phase-change layer, such as chalcogenide glass, Ge2Sb2Te5 (GST) and a heating element, such as titanium nitride (TiN). The conventional read and write conditions for PCM can be applied to this embodiment. By applying proper bias conditions, the phase-change layer 167a can be switched between a crystalline state and an amorphous state to change its resistance to represent the stored data.

FIG. 32D shows an equivalent circuit of the cell structure for the MRAM embodiment. For this embodiment, the layer 167a comprises multiple layers including at least one free layer 168a, one tunnel barrier or insulation layer 168b, and one pinned layer 168C. The pinned layer 168C is also referred to as a fixed or reference layer. The free layer 168a and the pinned layer 168c are formed of ferromagnetic material, such as, for example, iron-nickle (NiFe) or iron-cobalt (CoFe) alloys.

The conventional read and write conditions for spin-transfer torque (STT) MRAM can be applied to this embodiment. By applying the proper bias conditions, the electron spin of the free layer 168a can be switched to represent the stored data.

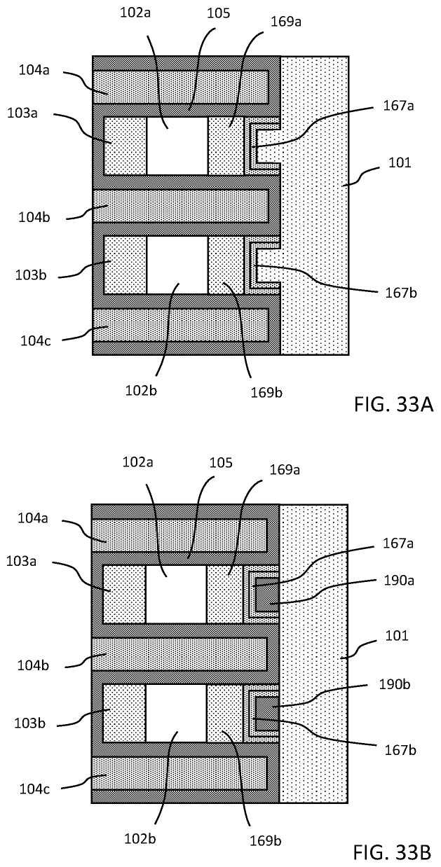

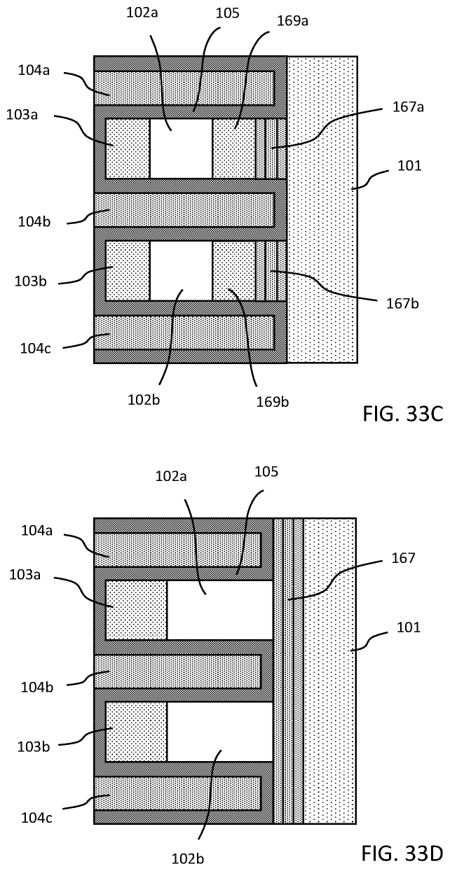

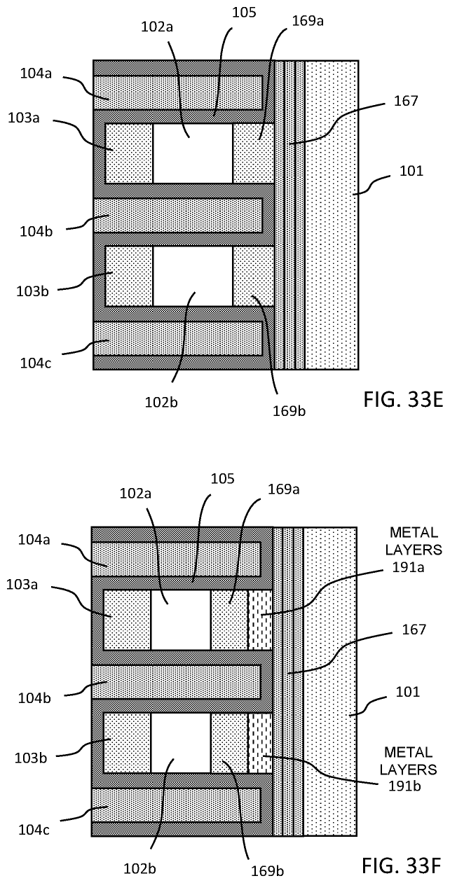

FIGS. 33A-F show another embodiment of the cell structures according to the invention. These embodiments are similar to the cell structure shown in FIG. 32A with some variations in the cell structures. These embodiments can be applied to FRAM, RRAM, PCM, and MRAM technologies. Please refer to FIGS. 31A-32D for a detailed description of the cell structure for each technology.

FIG. 33A shows a cell structure in which diffusion regions 169a and 169b are added in the drain side (bit line 101) of the cells. The diffusion regions 169a and 169b have the same type of heavy doping as the source regions 103a and 103b. In this embodiment, the bit line 101 is formed of metal or polysilicon.

FIG. 33B shows the cell structure of FIG. 33A in which metal islands 190a and 190b are formed in-between the bit line 101 and the layers 167a and 167b, respectively. In this embodiment. The bit line 101 is formed of metal or polysilicon.

FIG. 33C shows the cell structure of FIG. 33B in which the layers 167a and 167b are formed as individual segment for each cell as shown.

FIG. 33D shows the cell structure of FIG. 33C in which the layers 167 are formed as continuous layers on the sidewall of the bit line hole. In this embodiment. The bit line 101 is formed of metal or polysilicon.

FIG. 33E shows a cell structure that is similar to the cell structure shown in FIG. 33D except that the diffusion regions 169a and 169b are formed in the drain side of the cells. In this embodiment. The bit line 101 is formed of metal or polysilicon.

FIG. 33F shows an embodiment that is similar to the cell structure shown in FIG. 33E except that the metal layers 191a and 191b are formed in-between the diffusion regions 169a and 169b and the layer 167.

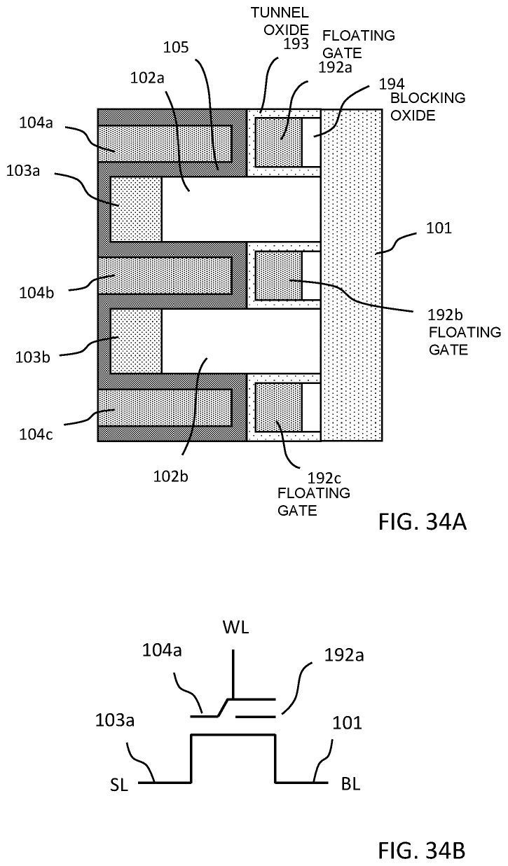

FIG. 34A shows another embodiment of a “floating-gate” cell structure for a 3D NOR-type flash memory according to the invention. This embodiment is similar to the embodiment shown in FIG. 30A except that the floating gates 192a to 192c are formed in the drain side of the cells, and the charge-trapping layer 160 is replaced with a gate dielectric layer 105 such as oxide or high-K material such as hafnium oxide (HfO₂). In this embodiment, the bit line 101 is formed of metal or polysilicon. This embodiment comprises a tunnel oxide layer 193 that is thin enough to allow electrons to be injected into the floating gates 192a-c to increase the threshold voltage of the cells or removed from the floating gates to reduce the threshold voltage of the cells to represent the stored data. The embodiment also comprises a blocking oxide layer 194. This embodiment of the cell may be read, erased, and programmed by using the conventional bias conditions for NOR flash memory.

FIG. 34B shows an equivalent circuit of the cell shown in FIG. 34A.

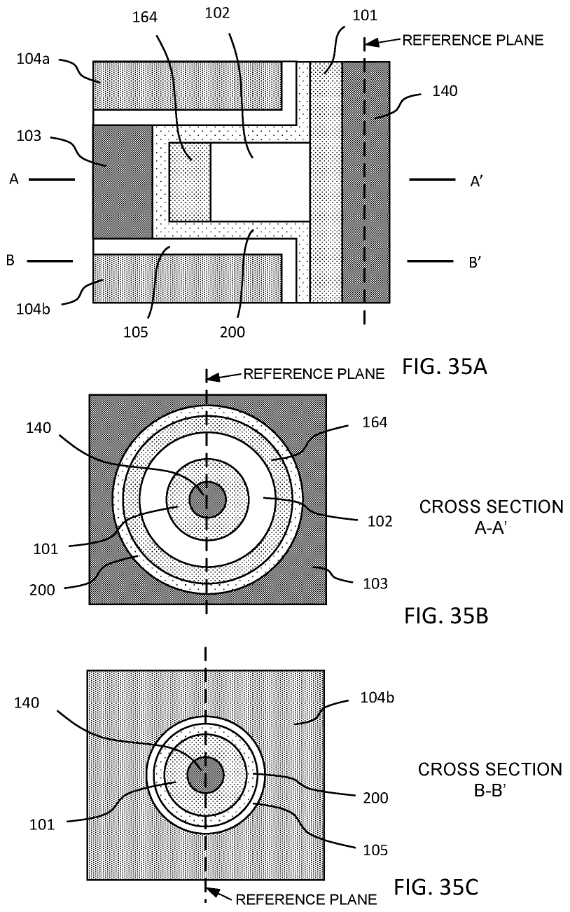

FIG. 35A shows another embodiment of the cell structure according to the invention. FIG. 35B and FIG. 35C shows cross-section views of the cell shown in FIG. 35A taken along line A-A′ and line B-B′, respectively, and aligned by a reference plane. This embodiment is similar to the embodiment shown in FIG. 5A except that a memory layer 200 is added as shown.

The memory layer 200 comprises any suitable material selected for use with different types of memory technologies. For example, in one embodiment of resistive random-access memory (RRAM), the memory layer 200 is an adjustable resistive layer, such as hafnium oxide (HfOx), titanium oxide (TiOx), and tantalum oxide (TaOx).

In another embodiment of a ferroelectric random-access memory (FRAM), the memory layers 200 are a ferroelectric layer, such as lead zirconate titanate (PZT) or hafnium oxide (HfO2). In another embodiment of a phase-change memory (PCM), the memory layer 200 is formed of multiple layers comprising at least one phase-change layer, such as chalcogenide glass, Ge2Sb2Te5 (GST).

In another embodiment of a magnetoresistive random-access memory (MRAM), the memory layer 200 comprises multiple layers including ferromagnetic material, such as iron-nickel (NiFe) or iron-cobalt (CoFe) alloys. The materials of the memory layer 200 described above are exemplary and not limiting. Other suitable materials can be used in the memory layer 200 within the scope of the invention.

In one embodiment, the bit line 101, floating body 102, and source region 164 are formed of semiconductor material, such as silicon or polysilicon. The word lines 104a-b are formed of conductor material, such as metal or polysilicon. A gate dielectric layer 105 comprises material, such as oxide or high-K material, such as HfO2. A metal core 140 is formed in the center of the bit line 101 hole to reduce the resistance of the bit line. The source line 103 is formed of conductor material, such as metal or polysilicon to reduce the resistance of the source line 103.

In one embodiment, the memory layer 200 is formed by using the process steps shown in FIG. 4I. Referring to FIG. 4I, after the layers 103a to 103e are etched by using an isotropic etching process, such as wet etching through the vertical bit line holes 101a to 101d to form recesses, the memory layer 200 is formed on the surface of the sidewall of the recesses through the bit line holes 101a to 101e by using a thin film deposition process.

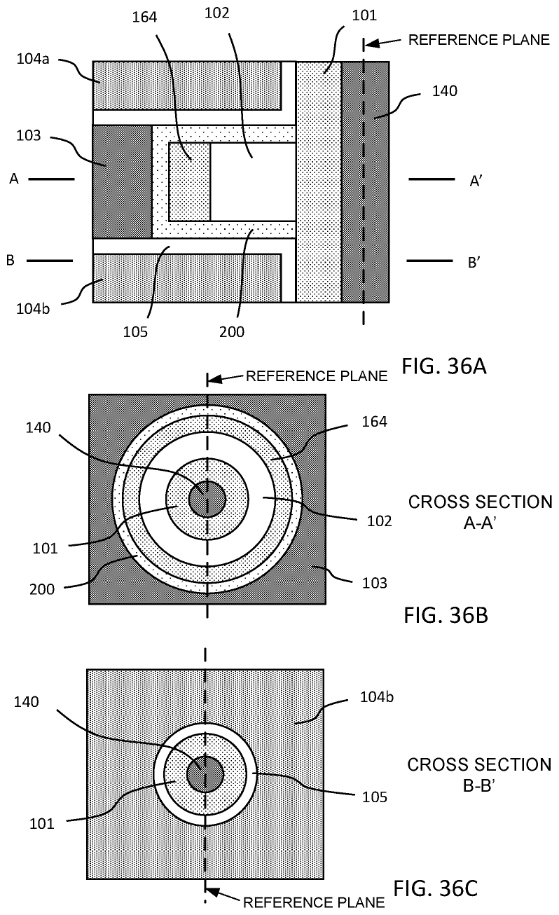

FIG. 36A shows another embodiment of the cell structure constructed according to the invention. FIG. 36B and FIG. 36C shows cross-section views of the cell structure shown in FIG. 36A taken along line A-A′ and line B-B′, respectively, and aligned by a reference plane. This embodiment is similar to the embodiment shown in FIGS. 35A-C except that the memory layer 200 is formed as an individual layer for each cell instead of a continuous layer as shown in FIG. 35A. The structure shown in FIG. 36A is formed by using anisotropic etching process, such as dry etching to remove the memory layer 200 on the surface of the sidewall of the vertical bit hole 101.

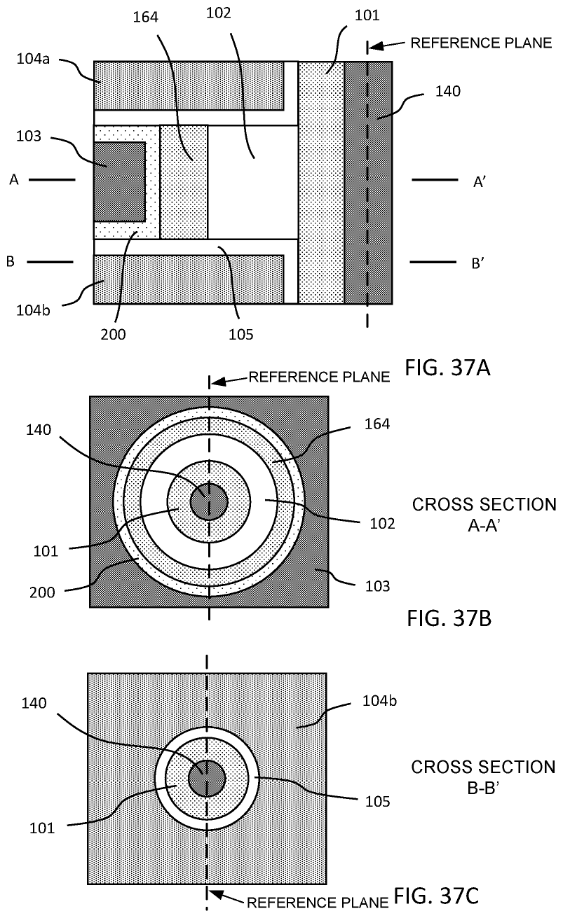

FIG. 37A shows another embodiment of a cell structure constructed according to the invention. FIG. 37B and FIG. 37C shows cross-section views of the cell structure shown in FIG. 37A taken along line A-A′ and line B-B′, respectively, and aligned by a reference plane. This embodiment is similar to the embodiment shown in FIGS. 35A-C except that the memory layer 200 is formed in the source side of the cell. In one embodiment, this structure is formed by using the process steps shown in FIGS. 4I-J.

Referring to FIG. 4I-J, to construct the embodiment of FIG. 37A, the layers 103a to 103e comprise sacrificial layers, such as oxide or nitride layers. After the process step shown in FIG. 4J, the sacrificial layers 103a to 103e are removed by using an isotropic etching process, such as wet etching. Then, the memory layer 200 is formed on the surface of the structure by using a thin-film deposition process. After that, a conductor material, such as metal is deposit to form the source line 103 as shown in FIG. 37A.

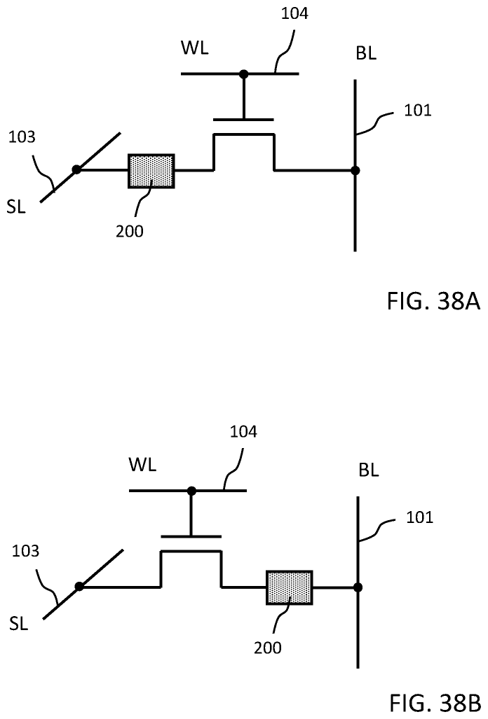

FIG. 38A shows the equivalent circuit of the embodiments of the cell structures shown in FIG. 35A to FIG. 37C. In these embodiments, the memory layer 200 is formed in the source line 103 side of the cell.

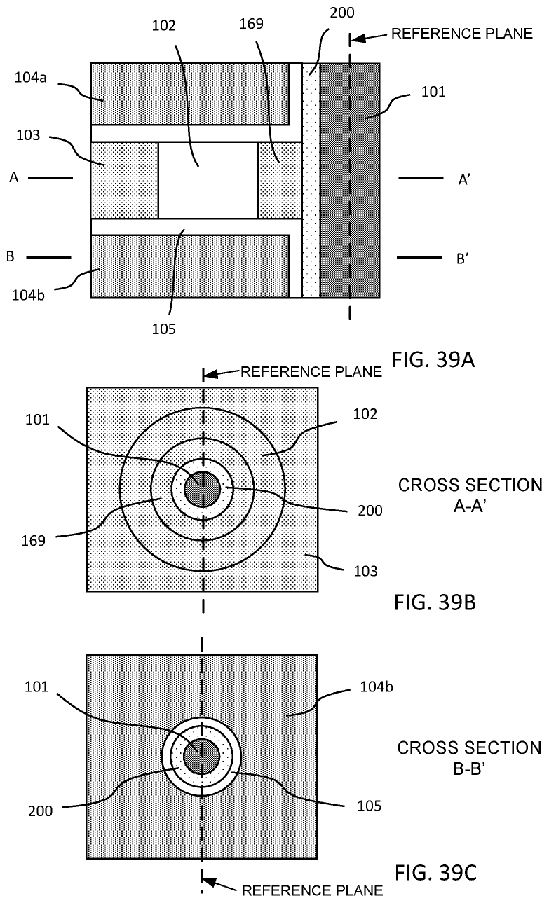

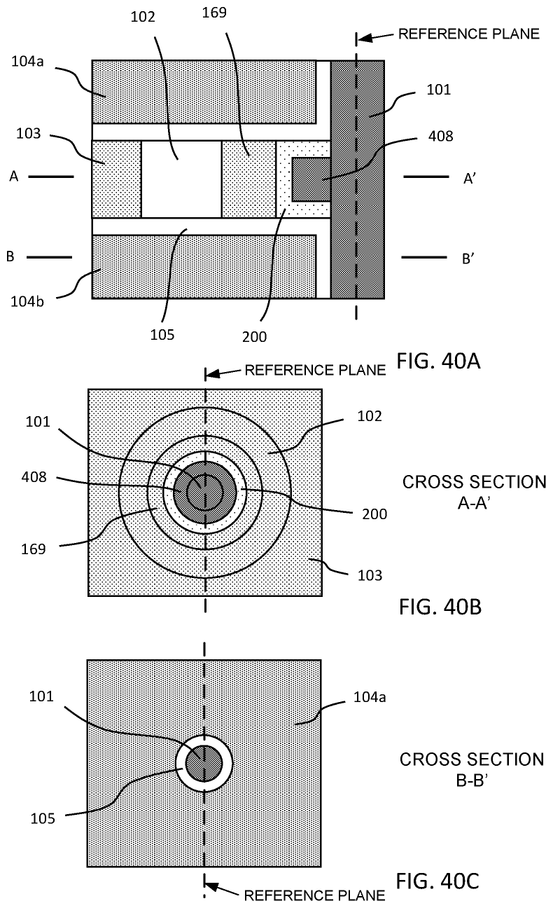

FIG. 38B shows another embodiment of an equivalent circuit of the cell structures shown in FIG. 39C to FIG. 40C according to the invention. In these embodiments, the memory layer 200 is formed in the bit line 101 side of the cell.

FIG. 39A shows another embodiment of a cell structure according to the invention. FIG. 39B and FIG. 39C shows cross-section views of the cell shown in FIG. 39A taken along line A-A′ and line B-B′, respectively, and aligned by a reference plane. This embodiment is similar to the one shown in FIGS. 35A-C except that the memory layer 200 is formed on the side wall of the vertical bit line hole by using a thin-film deposition process, before filling the bit line 101 hole with a conductor material, such as metal or polysilicon. In addition, a drain region 169 is formed of semiconductor material, such as silicon or polysilicon.

FIG. 40A shows another embodiment of a cell structure according to the invention. FIG. 40B and FIG. 40C shows cross-section views of the cell shown in FIG. 40A taken along line A-A′ and line B-B′, respectively, and aligned by a reference plane. This embodiment is similar to the one shown in FIGS. 39A-C except that the memory layer 200 is formed as an individual layer for each cell instead of a continuous layer, as shown in FIG. 39A.

In one embodiment, this structure is formed by using an isotropic etching process, such as wet etching to selectively etch the semiconductor layer of the drain region 169 to form a recess. Then, the memory layer 200 is formed on the surface of the sidewall of the recess by using a thin-film deposition process though the bit line hole, and then applying an anisotropic etching process, such as dry etching, to remove the memory layer 200 on the surface of the sidewall of the bit line hole. The recess is then filled with a conductor 408. The conductor 408 can be the same or different material as the bit line 101.

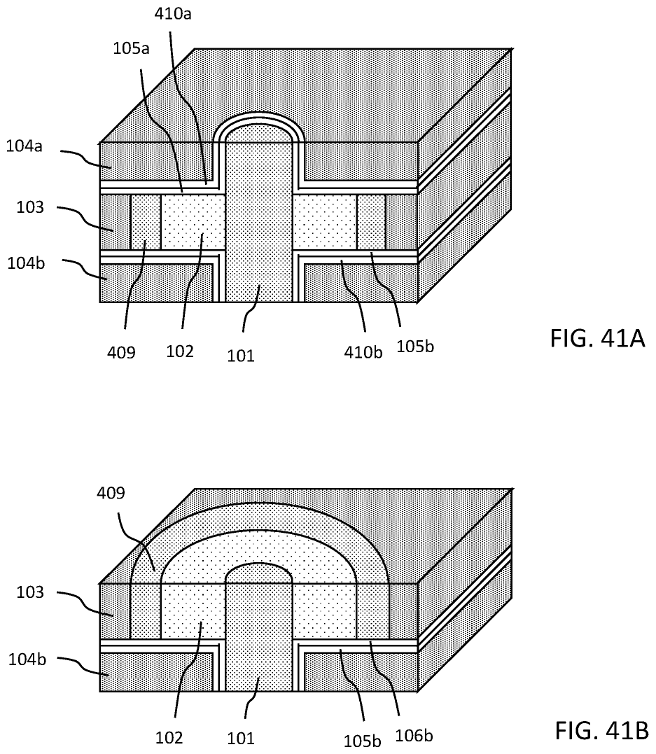

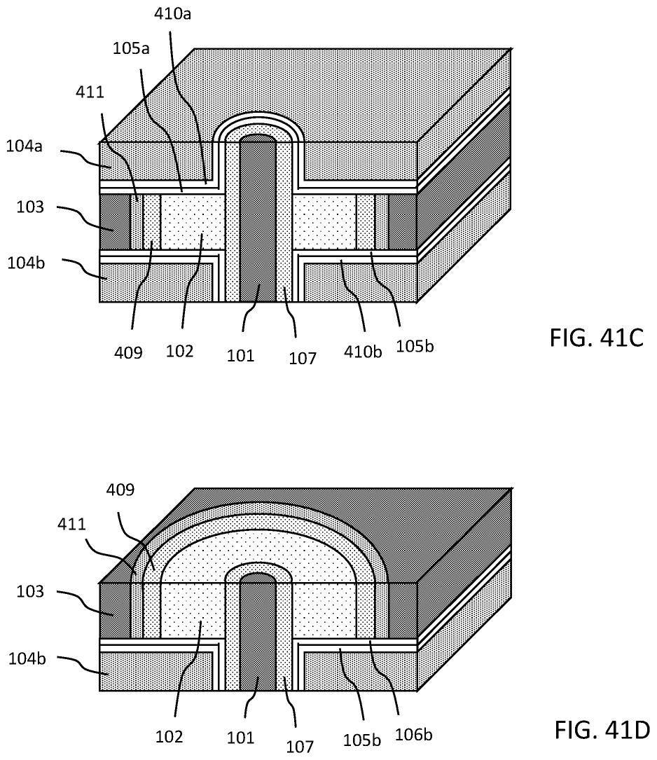

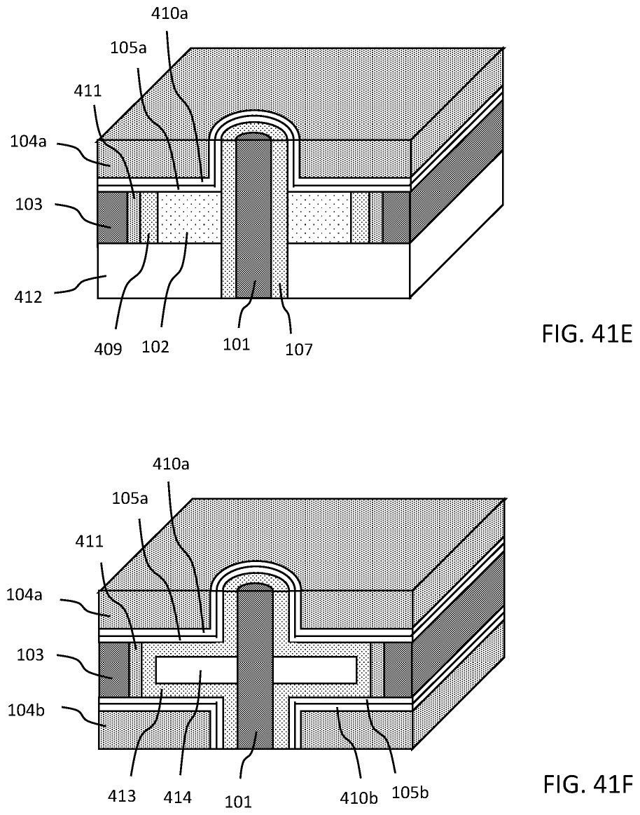

FIG. 41A show another embodiment of a 3D ferroelectric memory cell constructed according to the invention. As illustrated in FIG. 41A, a vertical bit line 101 is formed of semiconductor material, such as silicon or polysilicon. The vertical bit line 101 also forms a drain region of the cell. A semiconductor 102, comprising material such as silicon or polysilicon, forms a floating body of the cell. A semiconductor layer 409, comprising material such as silicon or polysilicon, forms a source region of the cell.

In one embodiment, the bit line 101 and the source region 409 have the same type of heavy doping, such as N+ or P+ doping. The floating body 102 has the opposite type of light doping, such as P− or N− doping, to form an N-channel or P-channel transistor cell, respectively.

In another embodiment, the bit line 101 and the source region 409 have the same type of heavy doping, such as N+ or P+ doping. The floating body 102 has the same type of heavy doping, such as N+ or P+ doping or light doping, such as N− or P− doping to form a junction-less' N-channel or P-channel transistor cell, respectively.

In another embodiment, the bit line 101 and the source region 409 have the opposite type of heavy doping, such as N+ or P+ doping. The floating body 102 is intrinsic or has P− or N− type of light doping. This forms a tunnel field-effect transistor (T-FET) cell.

A source line 103 is formed of a semiconductor layer, such as silicon or polysilicon. In one embodiment, the source line 103 has the opposite type of doping of the source region 409. The source line 103 and the source region 409 form a P-N diode.

In one embodiment, the cell shown in FIG. 41A is formed as a dual-gate transistor that comprises a front gate 104a and a back gate 104b. The front gate 104a and back gate 104b are formed of conductor material, such as metal or polysilicon. In one embodiment, the front gate 104a and back gate 104b are connected to word lines.

The cell shown in FIG. 41A also comprises ferroelectric layers 410a and 410b. The ferroelectric layers 410a and 410b comprise materials that have ferroelectric behavior, such as lead zirconate titanate (PZT), Hafnia-based ferroelectric materials, hafnium oxide (HfO2) in orthorhombic crystal phase, hafnium zirconium oxide (HfZrO), aluminum-doped hafnium oxide (HfO2), germanium-doped hafnium oxide (HfO2), silicon-doped hafnium oxide (HfO2), yttrium-doped hafnium oxide (HfO2), lead zirconium titanium bismuth iron oxide (PZT/BFO), and/or any combination of these materials.

The cell shown in FIG. 41A also comprises dielectric layers 105a and 105b, also called buffer layers. In various embodiments, the cell structure comprises various structures or configurations of the dielectric layers 105a and 105b. In one embodiment, the dielectric layers 105a and 105b are formed of insulator material, such as thin oxide or a high-K material, such as hafnium oxide (HfO2). In another embodiment, the dielectric layers 105a and 105b are eliminated, and thus the ferroelectric layers 410a and 410b directly contact with the floating body 102. In another embodiment, a metal layer, comprising material such as titanium or tungsten, is formed in between the ferroelectric layers 410a and 410b and the dielectric layers 105a and 105b.

The materials and structures of the ferroelectric layers 410a and 410b and dielectric layers 105a and 105b are applicable to all the embodiments of the cell structures herein according to the invention. The materials and structures described above are exemplary only and not limiting. Using any other suitable materials and structures remains within the scope of the invention.

FIG. 41B shows the cell structure of FIG. 41A with the layers 104a, 410a, and 105a removed to show the inner structure of the cell. From this view it can be seen that the floating body 102 and source region 409 are formed as a circular (donut) shape as shown. However, in other embodiments, the floating body 102 and source region 409 can be formed as any other shapes, such as square, rectangle, triangle, hexagon, etc. These variations remain within the scope of the invention.

FIG. 41C shows another embodiment of a cell structure according to the invention. FIG. 41D shows the cell structure with the layers 104a, 410a, and 105a removed to show the inner structure of the cell. The embodiment shown in FIG. 41C is similar to the embodiment shown in FIGS. 41A-B except that the vertical bit line 101 and the source line 103 are formed of conductor material, such as metal. This reduces the resistance of the vertical bit line 101 and source line 103.

The vertical bit line 101 is surrounded by a semiconductor layer 107, such as silicon or polysilicon, to form a drain region of the cell. Another semiconductor layer 409 forms a source region of the cell. The vertical bit line 101 comprises a semiconductor layer, such as silicon or polysilicon. In one embodiment, the semiconductor layer 411 has the opposite type of heavy doping as the source region 409. The semiconductor layer 411 and the source region 409 form a diode. In another embodiment, the semiconductor layer 411 has the same type of light doping of the source region 409. This forms a Schottky diode between the semiconductor layer 411 and the metal source line 103.

In various embodiments, the drain region 107, the floating body 102, and the source region 409 can be formed with various doping combinations. For example, in one embodiment, the drain region 107 and source region 409 have N+ type of heavy doping and the floating body 102 has P− type of light doping. This forms an N-channel transistor. In another embodiment, the drain region 107 and source region 409 have P+ type of heavy doping and the floating body (102) has N− type of light doping. This forms a P-channel transistor.

In another embodiment, the drain region 107 and source region 409 have N+ type of heavy doping and the floating body (102) has N+ or N− type of light doping. This forms a N− channel junction-less transistor. In another embodiment, the drain region 107 and source region 409 have P+ type of heavy doping and the floating body 102 has P+ or P− type of light doping. This forms a P-channel junction-less transistor.

In another embodiment, the drain region 107 has N+ or P+ type of heavy doping and the source region 409 has the opposite type of heavy doping of the drain region 107. The floating body 102 is intrinsic or has P− or N− type of light doping. This forms a tunnel field-effect transistor (T-FET).

FIG. 41E shows another embodiment of a 3D ferroelectric memory cell constructed according to the invention. This embodiment is similar to the embodiment shown in FIG. 41C except that the cell comprises only one control gate 104a. This forms a single-gate cell. Also shown is an insulating layer 412, comprising material such as oxide.

FIG. 41F shows another embodiment of a 3D ferroelectric memory cell constructed according to the invention. This embodiment is similar to the embodiment shown in FIG. 41C except that the cell is formed by using a thin-film transistor. The cell includes a semiconductor layer 413 comprising material, such as silicon or polysilicon. The cell also includes an insulator 414 comprising material, such as oxide or nitride. In one embodiment, the semiconductor layers 413 and 411 have the opposite type of doping to form a P-N diode at the junction of the semiconductor layers 413 and 411. In another embodiment, the semiconductor layers 413 and 411 have the same type of doping. In one embodiment, the semiconductor layer 413 has heavy doping, such as N+ or P+ doping. The semiconductor layer 411 has light doping, such as N− or P− doping. The source line 103 is formed of metal material. This forms a Schottky diode between the semiconductor layer 411 and the source line 103.

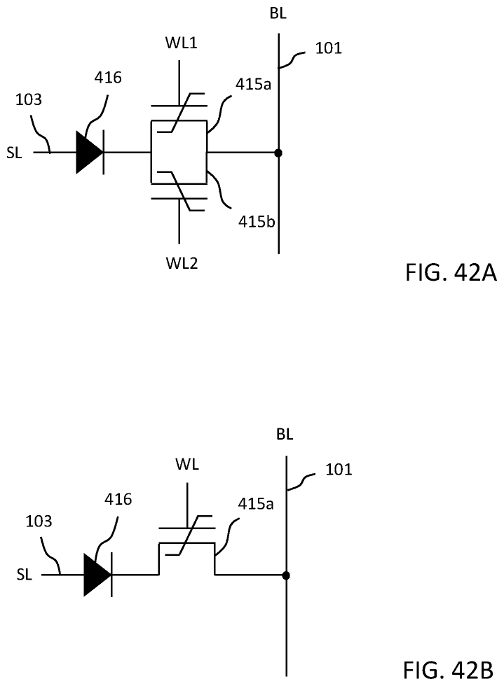

FIG. 42A shows an embodiment of an equivalent circuit of the cell structure shown in FIG. 41C. The cell comprises a dual-gate transistor 415a and 415b. The cell further comprises a diode 416 that is formed of semiconductor layers with the opposite type of doping, such as the layers 409 and 411 shown in FIG. 41C. The cell is connected to the bit line 101 and the source line 103.

FIG. 42B shows another embodiment of an equivalent circuit of the cell structure shown in FIG. 41E. This cell comprises a single-gate transistor 415a. The cell further comprises a diode 416 that is formed of semiconductor layers with the opposite type of doping, such as the layers 409 and 411 shown in FIG. 41E. The cell is connected to the bit line 101 and the source line 103.

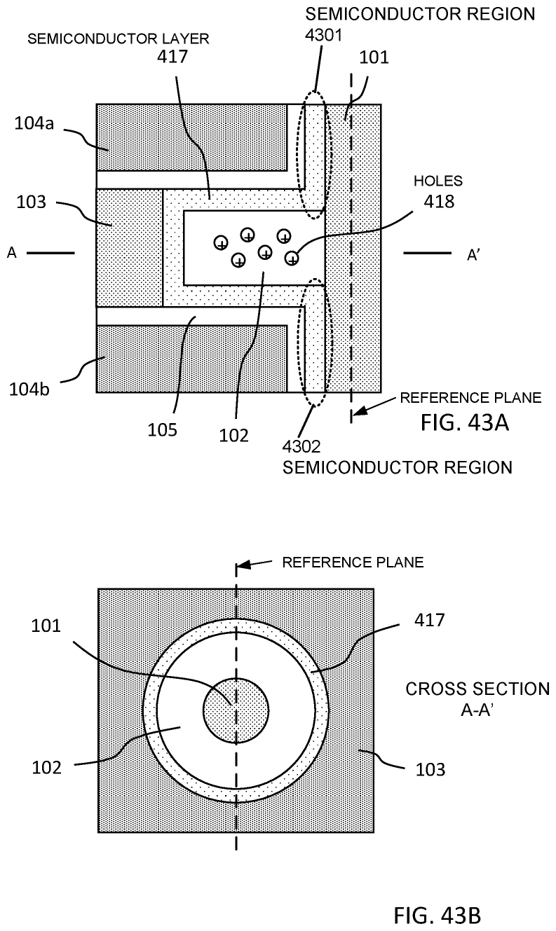

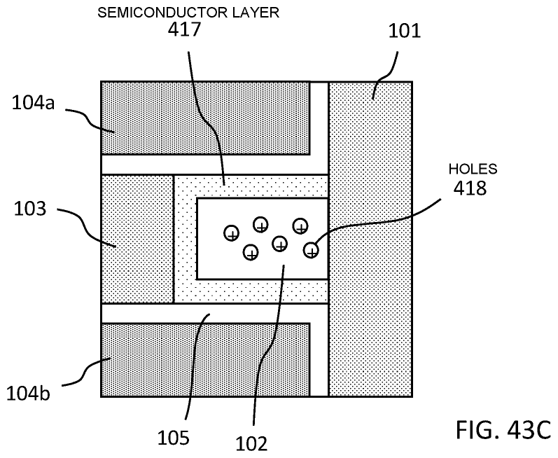

FIG. 43A shows another embodiment of a floating-body cell structure constructed according to the invention. FIG. 43B shows a cross section view of the cell structure shown in FIG. 43A taken along line A-A′ and aligned by a reference plane. This embodiment is similar to the embodiment shown in FIGS. 1A-C except that a semiconductor layer 417 comprising material such as silicon is formed to surround the floating body 102. The semiconductor layer 417 forms the channel of the cell. The semiconductor layer 417 has the opposite type of doping as the floating body 102. As illustrated in FIG. 43A, holes 418 are stored in the floating body 102 to alter the threshold voltage of the cell. Also shown in FIG. 43A are semiconductor regions 4301 and 4302.

FIG. 43C shows another embodiment of a floating-body cell structure constructed according to the invention. This embodiment is similar to the embodiment shown in FIGS. 43A-B except that the semiconductor region 4301/4302 of the semiconductor layer 417 located on the surface of the sidewall of the bit line 101 is removed by using an anisotropic etching process, such as dry etching, before the bit line hole is filled with the bit line material 101.

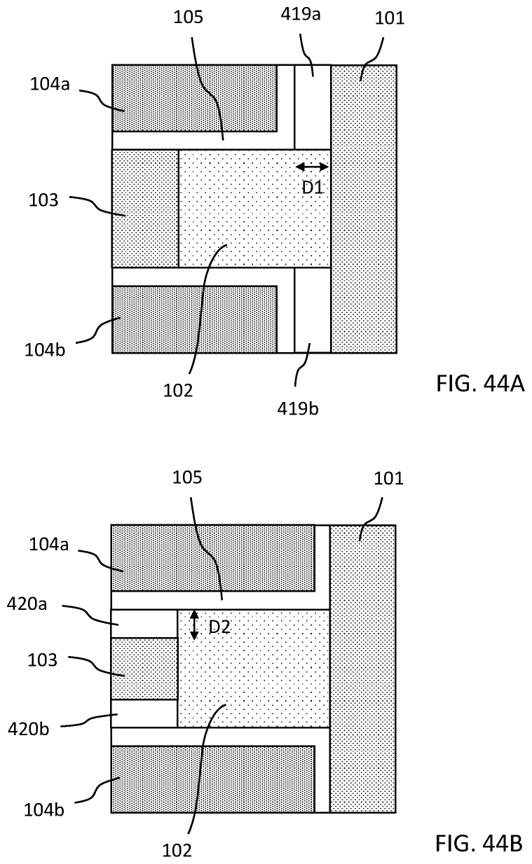

FIG. 44A shows another embodiment of a floating-body cell structure constructed according to the invention. In one embodiment, the bit line 101 and the source line 103 have the same type of heavy doping, such as N+ or P+ doping. The floating body 102 has the opposite type of light doping from the bit line 101 and the source line 103, such as P− or N− doping. This forms a traditional transistor type of cell. In another embodiment, the bit line 101 and the source line 103 have the opposite type of heavy doping. For example, the bit line 101 and the source line 103 have P+ and N+ type of doping, respectively. The floating body 102 is intrinsic or has P− or N− type of light doping. This forms a tunnel field effect transistor (T-FET) type pf cell.

The embodiment shown in FIG. 44A is similar to the embodiment shown in FIGS. 1A-C except that the insulators 419a and 419b, such as oxide or nitride, are formed between the word lines 104a and 104b and the bit line 101. The distance D1 between the word line 104a and the bit line 101 is a design parameter that affects the characteristics of the cell, such as the threshold voltage, write voltage, read voltage, channel current, and data retention time. The insulators 419a and 419b also prevent holes from escaping from the floating body 102 to the bit line 101. The insulators 419a and 419b also reduce the parasitic capacitance between the word lines 104a and 104b and the bit line 101.

FIG. 44B shows another embodiment of a floating-body cell structure constructed according to the invention. This embodiment is similar to the embodiment shown in FIG. 44A except that the insulators 420a and 420b are formed between the word lines 104a and 104b and the source line 103 instead of the bit line 101. The distance D2 between the word line 104a and the source line 103 is a design parameter that affects the characteristics of the cell, such as the threshold voltage, write voltage, read voltage, channel current, and data retention time. The insulators 420a and 420b also prevent holes from escaping from the floating body 102 to the source line 103. The insulators 419a and 419b also reduce the parasitic capacitance between the word lines 104a and 104b and the source line 103.

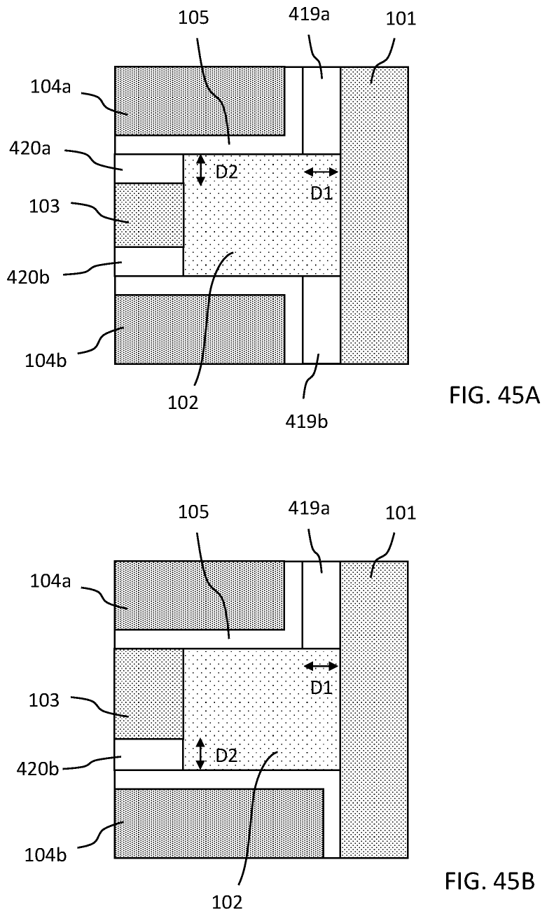

FIG. 45A shows another embodiment of a floating-body cell structure constructed according to the invention. This embodiment is similar to the embodiment shown in FIGS. 44A-B except that the insulators 419a and 419b are formed between the word lines 104a and 104b and the bit line 101, and the insulators 420a and 420b are formed between the word lines 104a and 104b and the source line 103. The distances D1 and D2 are design parameters that affect the characteristics of the cell, as described above with reference to FIGS. 44A-B.

FIG. 45B shows another embodiment of a floating-body cell structure constructed according to the invention. This embodiment is similar to the embodiment shown in FIG. 45A except that only one insulator 419a is formed between the front-gate word line 104a and the bit line 101, and only one insulators 420b is formed between the back-gate word line 104b and the source line 103. The distances D1 and D2 are design parameters that affect the characteristics of the cell, as described above with reference to FIGS. 44A-B.

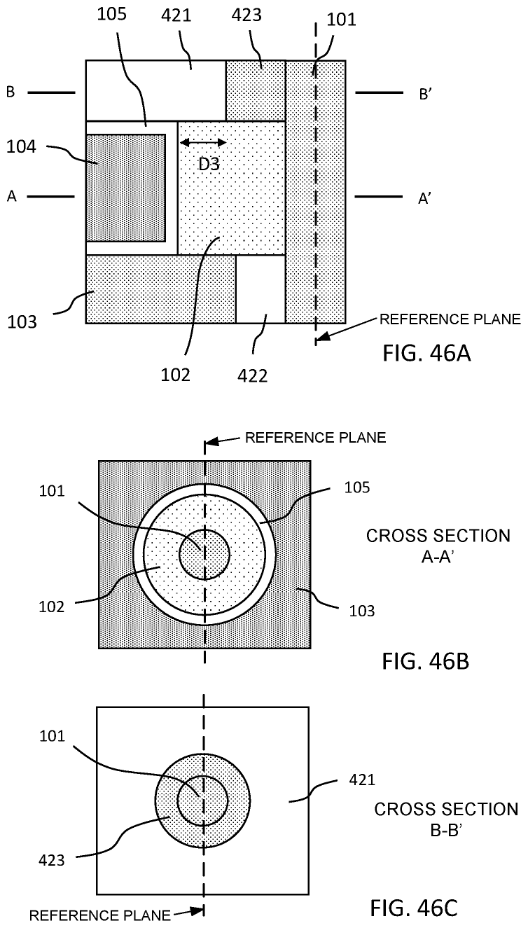

FIG. 46A shows another embodiment of a floating-body cell structure constructed according to the invention using a tunnel field-effect transistor (T-FET). FIGS. 46B-C show cross section views of the cell shown in FIG. 46A taken along line A-A′ and line B-B′, respectively, and aligned by a reference plane. As illustrated in FIG. 46A, the cell comprises a vertical bit line 101, floating body 102, and a source line 103. The cell also comprises a word line 104 formed of conductor material and a gate dielectric layer 105. The cell also comprises insulating layers 421 and 422 that comprise material, such as oxide or nitride, and a semiconductor layer 423 that comprises material such as silicon or polysilicon that is connected to the bit line 101 to form a drain region of the cell. The semiconductor layer 423 and the bit line 101 have the same type of heavy doping. The distance D3 between the semiconductor 423 and the word line 104 is a design parameter that affects the characteristics of the cell, as described above with reference to FIGS. 44A-B.

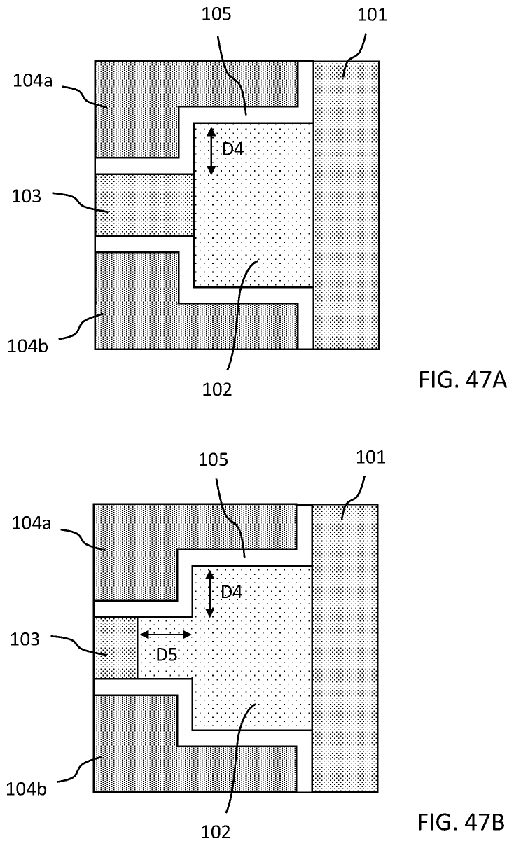

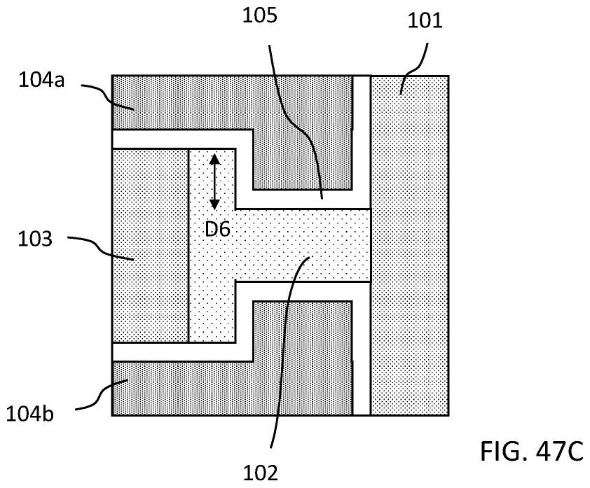

FIG. 47A shows another embodiment of a floating-body cell structure constructed according to the invention using a transistor or tunnel field-effect transistor (T-FET) type of transistor, as described in FIG. 44A. This embodiment is similar to the embodiment shown in FIGS. 1A-C except that it has an L-shape channel. The distance D4 between the corner of the channel and the source line 103 is a design parameter that affects the characteristics of the cell, such as the cell's data retention time.

FIG. 47B shows another embodiment of a floating-body cell structure constructed according to the invention using a transistor or tunnel field-effect transistor (T-FET). This embodiment is similar to the embodiment shown in FIG. 47A except that the source line 103 is pulled back. The distances D4 and D5 between the corner of the channel and the source line 103 are design parameters that affect the characteristics of the cell, such as the cell's data retention time.

FIG. 47C shows another embodiment of a floating-body cell structure constructed according to the invention using a transistor or tunnel field-effect transistor (T-FET). This embodiment is similar to the embodiment shown in FIG. 47B except that the thickness of the source line 103 layer is larger than that of the floating body 102. This structure increases the on-cell current. The distance D6 is a design parameter that affects the characteristics of the cell, such as the cell's data retention time.

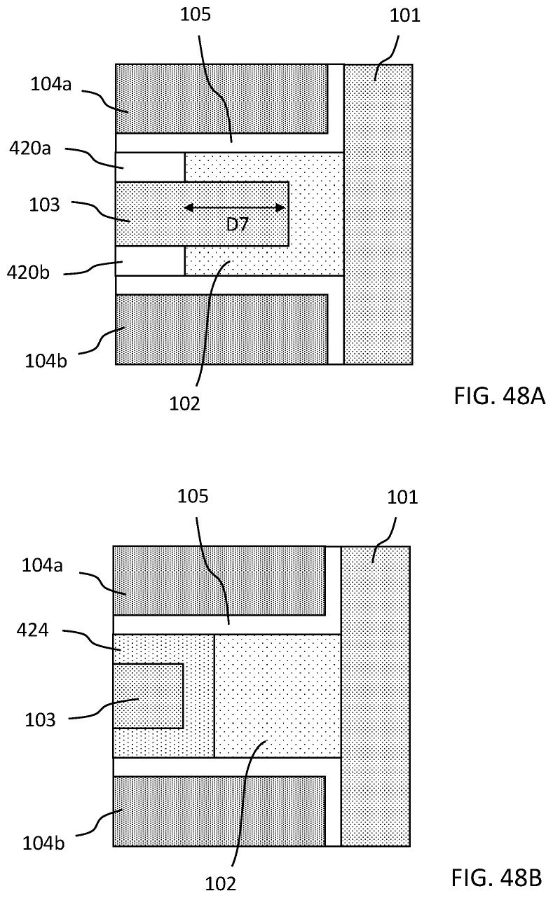

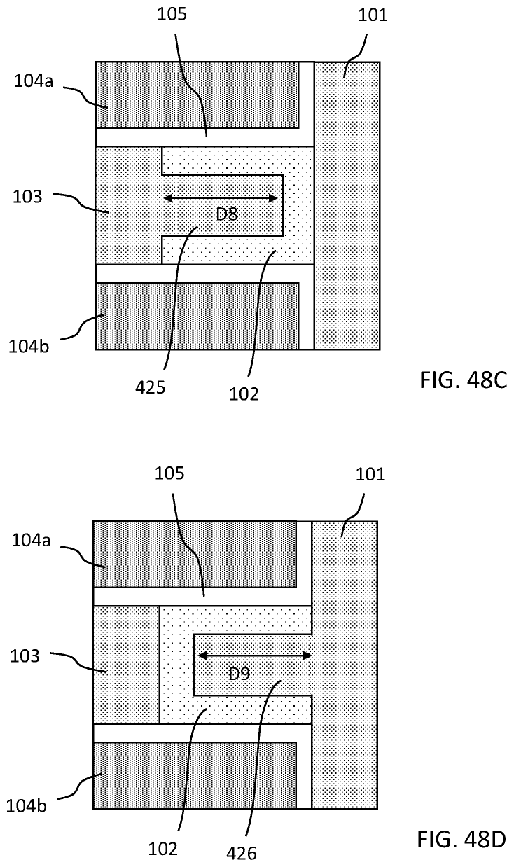

FIG. 48A shows another embodiment of a floating-body cell structure constructed according to the invention using a transistor or tunnel field-effect transistor (T-FET). This embodiment is similar to the embodiment shown in FIG. 45A except that the source line 103 is extended into the floating body 102. This structure increases the on-cell current. The distance D7 is a design parameter that affects the characteristic of the cell.

FIG. 48B shows another embodiment of a floating-body cell structure constructed according to the invention using tunnel field-effect transistor (T-FET). This embodiment is similar to the embodiment shown in FIGS. 1A-C except that a semiconductor pocket 424 is formed to surround the source line 103. The semiconductor pocket 424 is formed by using pocket implantation, diffusion, or thin-film deposition. The semiconductor pocket 424 has the opposite type of doping as the source line 103. For example, in one embodiment, the source line 103 has P+ type of heavy doping. The semiconductor pocket 424 and the bit line 101 have N+ type of doping. The floating body 102 is intrinsic or has N− or P− type of light doping. The semiconductor pocket 424 affects the characteristics of the cell, such as the cell's threshold voltage, channel current, and data retention time.

FIG. 48C shows another embodiment of a floating-body cell structure constructed according to the invention using tunnel field-effect transistor (T-FET). This embodiment is similar to the embodiment shown in FIGS. 1A-C except that the source line 103 is extended into the floating body 102 as shown at indicator 425. This structure increases the on-cell current. The distance D8 is a design parameter that affects the characteristics of the cell.

FIG. 48D shows another embodiment of a floating-body cell structure constructed according to the invention using tunnel field-effect transistor (T-FET). This embodiment is similar to the embodiment shown in FIGS. 1A-C except that the bit line 101 is extended into the floating body 102 as shown in 426. This structure increases the on-cell current. The distance D9 is a design parameter that affects the characteristics of the cell.

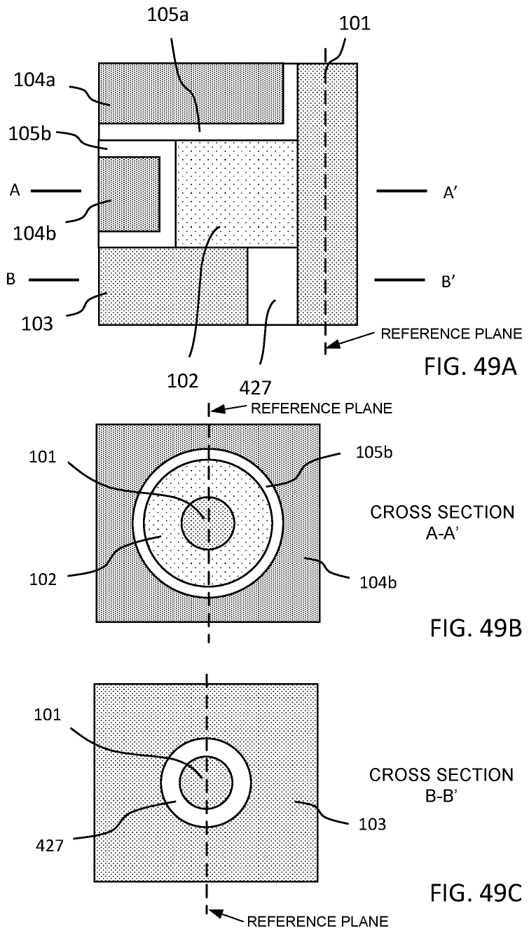

FIG. 49A shows another embodiment of a floating-body cell structure according to the invention using a double-gate, the traditional type of transistor or tunnel field-effect transistor (T-FET). The disclosure provided with respect to FIG. 44A provides a description of the traditional type of transistor and the tunnel field-effect transistor. As illustrated in FIG. 49A, this embodiment has two gates 104a and 104b connected in series. In one embodiment, the gate 104a is the word line and the gate 104b is a control gate that is connected to a fixed bias voltage. In another embodiment, the gate 104a is the control gate and the gate 104b is the word line. The control gate stabilizes the voltage of the floating body 102. This reduces the word line coupling issue of the traditional floating body cell during read operations. Also shown in FIG. 49A are gate dielectric layers 105a and 105b comprising material, such as oxide or high-K material, such as HfO2. In addition, an insulating layer 427 is provided comprising material, such as oxide or nitride.

FIGS. 49B-C show cross-section views of the cell shown in FIG. 49 taken along line A-A′ and line B-B′, respectively, and aligned by a reference plane.

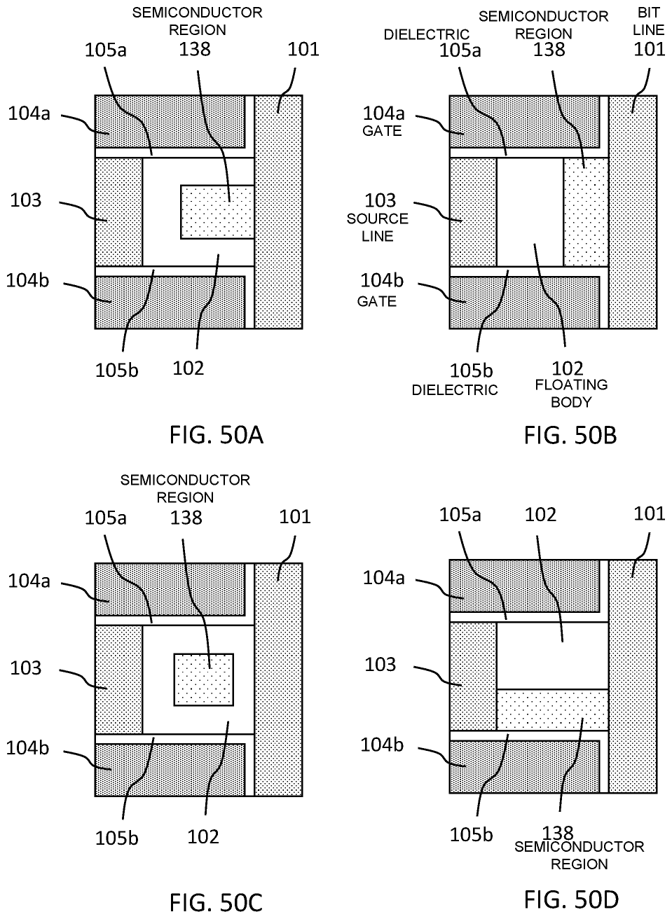

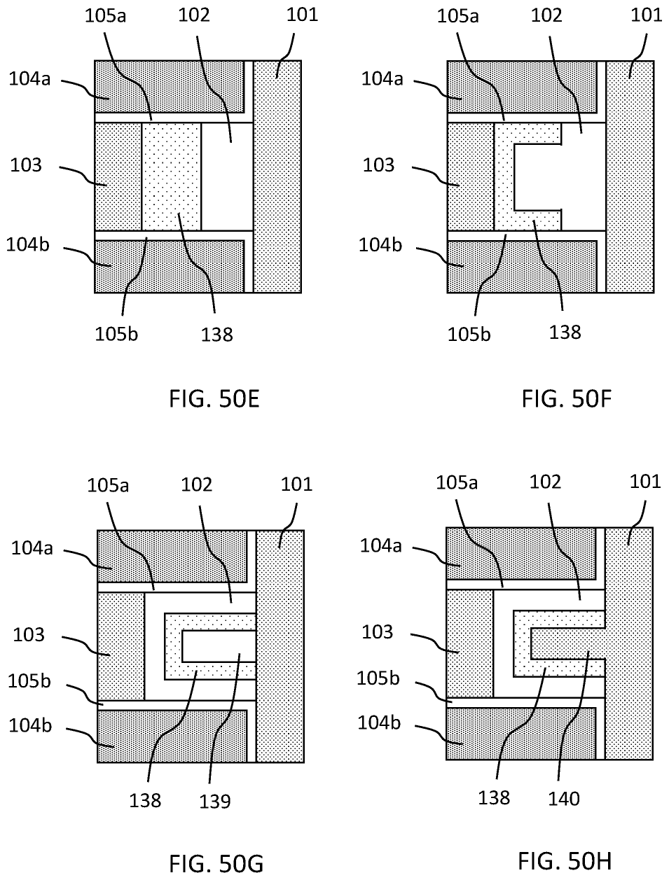

FIGS. 50A-H show additional embodiments of 3D cell structures constructed according to the invention. In these embodiments, one or multiple second semiconductor material regions 138 comprising material such as silicon germanium (SiGe), are formed in the floating body 102 that is formed of a first semiconductor material, such as silicon (Si). This configuration forms a heterostructure junction between the two materials Si and SiGe and forms a quantum well inside the second semiconductor material (SiGe) to store holes. This increases the data retention time of the cell.

In accordance with the invention, the first and second semiconductor materials can be any suitable semiconductor material, such as silicon (Si), polysilicon (Poly-Si), germanium (Ge), silicon germanium (SiGe), gallium nitride (GaN), gallium-arsenide (GaAs), indium silicon (InSi), germanium indium (GeIn), indium gallium arsenide (InGaAs), silicon carbide (SiC), Indium gallium zinc oxide (IGZO), and/o other suitable materials.

In one embodiment, the second semiconductor material region 138 has the same type of doping as the floating body 102. For example, the second semiconductor material region 138 is heavily doped P+ silicon germanium and the floating body 102 is lightly doped P− silicon. The bit line 101 and the source line 103 are heavily doped N+ silicon.

According to the invention, the second semiconductor region 138 is formed as any suitable shape and in any suitable locations within the floating body 102.

FIG. 50A shows how the second semiconductor material region 138 is formed as a pocket located in the bit line 101 side.

FIG. 50B shows how the second semiconductor material region 138 is formed as a layer located in the bit line 101 side.

FIG. 50C shows how the second semiconductor material region 138 is formed as an isolated island inside the floating body 102.

FIG. 50D shows how the second semiconductor material region 138 is formed as a layer located in the back gate 104b side. In this configuration, the back gate 104b is supplied with a negative voltage to increase the retention time of the holes stored in the second semiconductor material region 138.

FIG. 50E shows how the second semiconductor material region 138 is formed as a well located in the source line 103.

FIG. 50F shows how the second semiconductor material region 138 is formed as a layer located in the source line 103.

FIG. 50G shows how the second semiconductor material region 138 is formed in a horseshoe shape as shown. In one embodiment, the material 139 is the same type of material as the floating body 102.

FIG. 50H shows how the second semiconductor material region 138 is formed as the horseshoe shape shown. In one embodiment, the material 140 is the same type of material as the bit line 101.

It should be noted that the materials, shapes, and locations of the second semiconductor material region 138 shown in FIGS. 50A-H are exemplary and not limiting and that variations on the material, shapes, and locations of the second semiconductor material region 138 are within the scope of the invention.

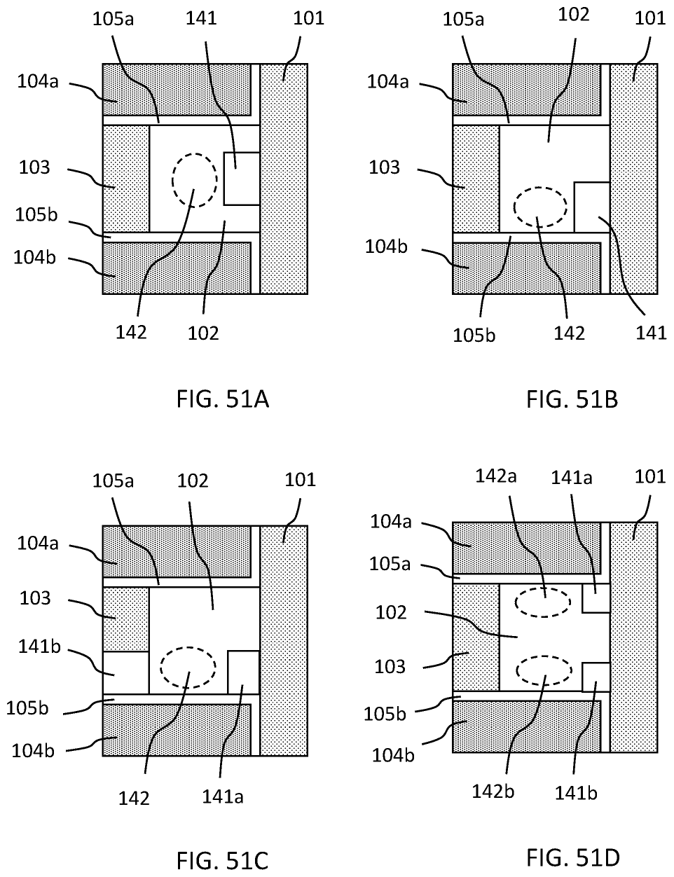

FIGS. 51A-D show additional embodiments of 3D cell structures constructed according to the invention. In these embodiments, one or more insulators 141, comprising material such as oxide or nitride are formed in the floating body 102 to be a physical barrier between the bit line 101 junction and the holes stored in the floating body 102. This reduces the junction leakage to enhance the retention time of the stored holes. According to the invention, the insulator 141 is formed as any suitable shape and in any suitable location within the floating body 102.

FIG. 51A shows how the insulator 141 is formed in the bit line 101 side to form a physical barrier for the holes stored in the region 142.

FIG. 51B shows how the insulator 141 is formed in the junction between the bit line 101 and the back gate 104b. This configuration forms a physical barrier for the holes stored in the region 142. In one embodiment, the back gate 104b is supplied with a negative voltage to increase the retention time of the holes stored in the region 142.

FIG. 51C shows how the insulators 141a and 141b are formed in the bit line 101 junction and the source line 103 junction, respectively, to form physical barriers to reduce the junction leakage of the holes stored in the region 142. In one embodiment, the back gate 104b is supplied with a negative voltage to increase the retention time of the holes stored in the region 142.

FIG. 51D shows how the insulators 141a and 141b are formed in the bit line 101 junctions to form physical barriers for the holes stored in the regions 142a and 142b. In one embodiment, the front gate 104a and back gate 104b are supplied with a negative voltage during a ‘hold’ mode to increase the retention time of the holes stored in the region 142.

It should be noted that the materials, shapes, and locations of the insulator 141 shown in FIGS. 51A-D are exemplary and not limiting and that examples variations on the material, shapes, and locations are within the scope of the invention.

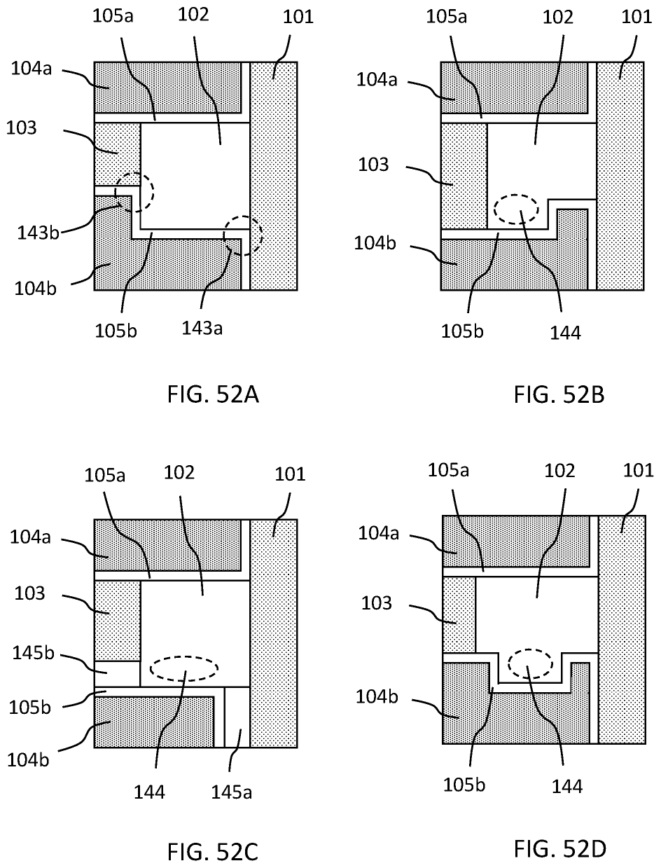

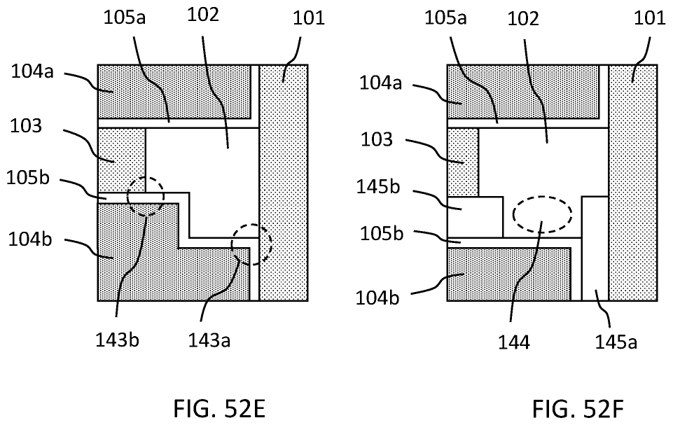

FIGS. 52A-F show additional embodiments of 3D cell structures constructed according to the invention. In these embodiments, the front gate 104a or the back gate 104b is formed or configured in special shapes to reduce the junction leakage of the holes stored in the floating body 102. These configurations increase the retention time of the holes stored in the floating body 102. According to the invention, the front gate 104a and the back gate 104b are formed or configured in a variety of suitable shapes.

FIG. 52A shows how the back gate 104b is formed to have the shape shown to create underlaps 143a and 143b between the back gate 104b and the bit line 101 junction and source line 103 junction, respectively. This configuration reduces the junction leakage of the holes stored in the floating body 102.

FIG. 52B shows how the back gate 104a is formed to have the shape shown to create a pocket for the holes to be stored in the region 144. The shape of the back gate 104b forms a physical barrier to reduce the junction leakage of the bit line 101 junction.

FIG. 52C shows how the insulators 145a and 145b are formed between the back gate 104b and the bit line 101 junction and the source line 103 junction, respectively. This reduces the junction leakage of the holes stored in the region 144. In one embodiment, the back gate 104b is supplied with a negative voltage to increase the retention time of the holes stored in the region 144.

FIG. 52D shows how the back gate 104a is formed to have the shape shown to create a pocket for the holes to be stored in the region 144. The shape of the back gate 104b forms a physical barrier to reduce the junction leakage of the bit line 101 junction and the source line 103 junction.

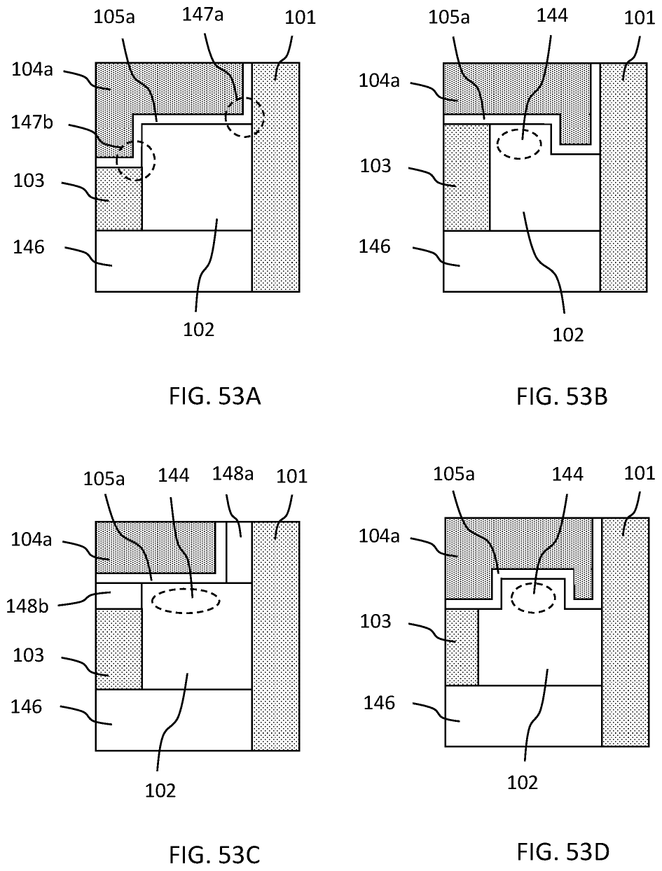

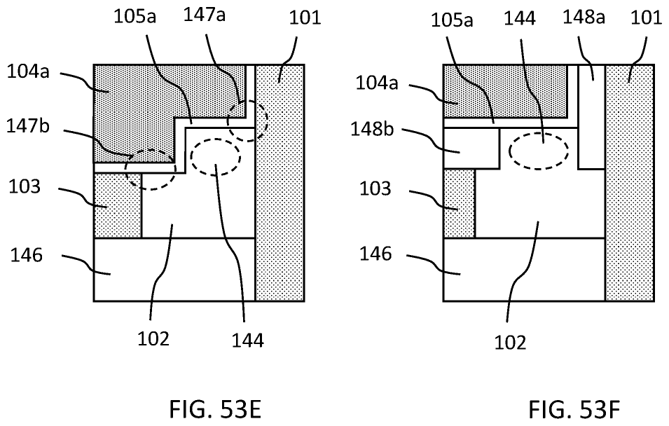

FIGS. 53A-F show additional embodiments of 3D cell structures constructed according to the invention. In these embodiments, the cells are formed as single-gate transistors that only has the front gate 104a. The back gate is eliminated and replaced with an insulating layer 146, comprising material such as oxide or nitride, to isolate the floating body 102 from the adjacent cells. During ‘hold’ mode, the front gate 104a is supplied with a negative voltage to attract holes to enhance the data retention time. In the embodiments shown in FIGS. 53A-F, the front gate 104a is formed in a variety of special shapes to reduce the junction leakage of the holes stored in the floating body 102 to the bit line 101 or source line 103. This configuration increases the data retention time of the holes stored in the floating body 102. In various embodiments, the front gate (104a) can be formed in a variety of suitable shapes.

FIG. 53A shows how the front gate 104a is formed to have the shape shown to create underlaps 147a and 147b between the front gate 104a and the bit line 101 junction and source line 103 junction, respectively. This configuration reduces the junction leakage of the holes stored in the floating body 102 to the bit line 101 and the source line 103.

FIG. 53B shows how the front gate 104a is formed to have the shape shown to create a pocket for the holes to be stored in the region 144. The shape of the front gate 104a forms a physical barrier to reduce the junction leakage of the bit line 101 junction.

FIG. 53C shows how the insulators 148a and 148b are formed between the front gate 104a and the bit line 101 junction and the source line 103 junction, respectively. This configuration reduces the junction leakage of the holes stored in the region 144 to the bit line 101 and the source line 103. In one embodiment, the front gate 104a is supplied with a negative voltage to increase the retention time of the holes stored in the region 144.

FIG. 53D shows how the back gate 104a is formed to have the shape shown to create a pocket for the holes to be stored in the region 144. The shape of the front gate 104a forms a physical barrier to reduce the junction leakage of the holes stored in the region 144 to the bit line 101 and the source line 103.

FIG. 53E shows how the front gate 104a is formed to have the shape shown to create underlaps 147a and 147b between the front gate 104a and the bit line 101 junction and source line 103 junction, respectively. This embodiment is similar to the embodiment shown in FIG. 53A except that the source line 103 is pulled back to enlarge the distance of the underlap 147b. This configuration further reduces the junction leakage of the holes stored in the floating body 102 to the source line 103.

FIG. 53F shows how the insulators 148a and 148b are formed between the front gate 104a and the bit line 101 junction and the source line 103 junction, respectively. This embodiment is similar to the embodiment shown in FIG. 53C except that the insulators 148a and 148b are extended into the floating body 102 to form a pocket region 144 for hole storage. This configuration further reduces the junction leakage of the holes stored in the region 144 to the bit line 101 and the source line 103.

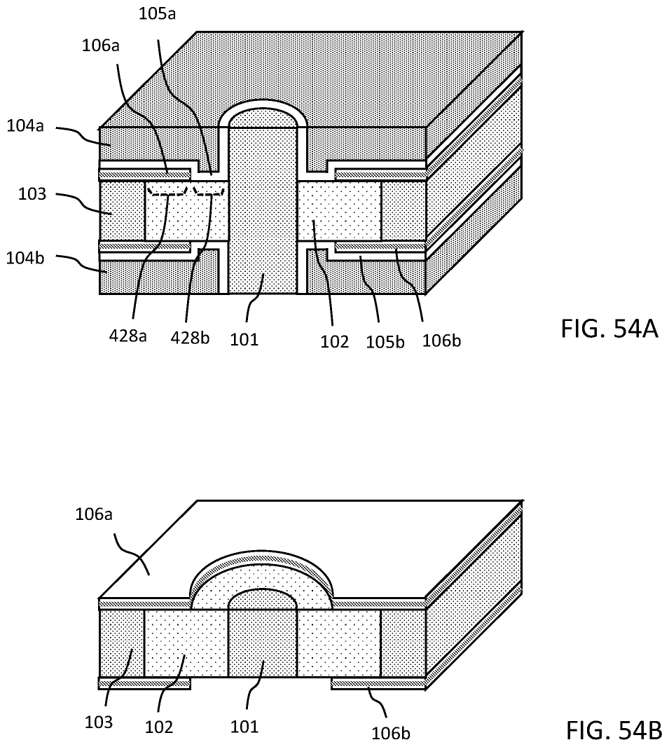

FIG. 54A shows another embodiment of a cell structure constructed according to the invention. This embodiment is similar to the embodiments shown in FIGS. 1A-C except that additional charge-trapping layers 106a and 106b are form under the gate dielectric layers 105a and 105b. The charge-trapping layers 106a and 106b are formed of oxide-nitride-oxide (ONO) layers or any other suitable structures, as described with reference to FIGS. 28A-B. The gate dielectric layers 105a and 105b are formed of thin oxide of high-K material, such as hafnium oxide (HfO2). The charge-trapping layers 106a and 106b only cover a partial length of the channel. The channel of the cell is split into two portions 428a and 428b. The first channel portion 428a is coupled to the charge-trapping layer 106a. The second portion 428b is coupled to the gate dielectric layer 105a. This forms a ‘split-gate’ type of 3D NOR flash memory cell.

In another embodiment, the layer 106a comprises a ferroelectric layer, such as lead zirconate titanate (PZT), or hafnium oxide (HfO2) in orthorhombic crystal phase, or hafnium zirconium oxide (HfZrO2). This configuration forms a ‘split-gate’ type of ferroelectric memory cell.

For NOR flash memory or ferroelectric memory cells, during erase operations, the threshold voltage (Vt) of the charge-trapping layer or ferroelectric layer 106a may become negative, known as an ‘over-erase’ condition, which cause the channel portion 428a to remain always on, which causes leakage problems.

To address the over-erase condition, the gate dielectric layer 105a is configured to cause the second channel portion 428b to behave like an enhancement transistor. Therefore, the over-erase condition is resolved.

FIG. 54B shows the cell structure shown in FIG. 54A with the front gate 104a, the back gate 104b, and the gate dielectric layers 105a and 105b removed to show the structure of the layers 106a and 106b.

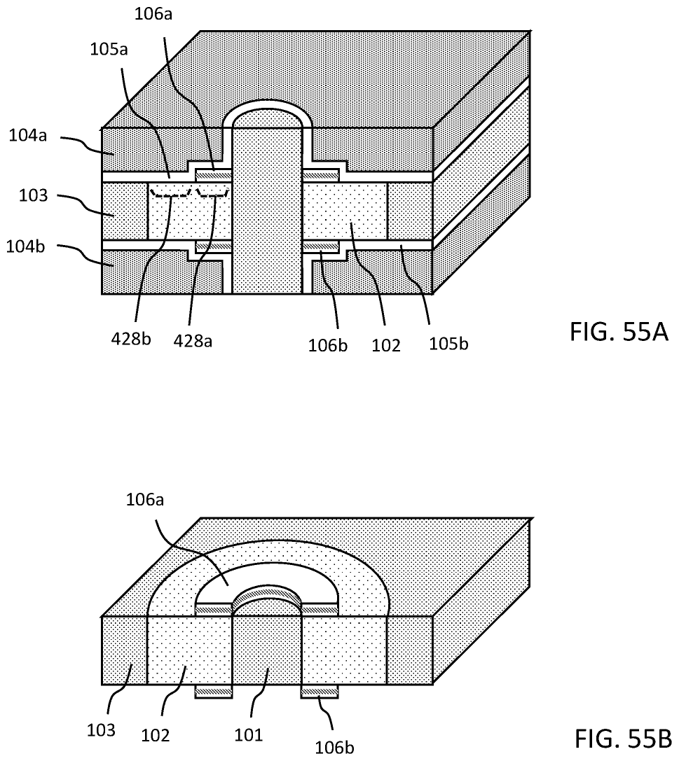

FIG. 55A shows another embodiment of a ‘split-gate’ cell structure constructed according to the invention. This embodiment is similar to the embodiment shown in FIG. 54A except that the charge-trapping layers or ferroelectric layers 106a and 106b are formed in the bit line 101 side instead of the source line 103 side. The channel portion 428b coupled to the gate dielectric layers 105a and 105b resolves over-erase conditions.

FIG. 55B shows the cell structure of the cell shown in FIG. 55A with the front gate 104a, the back gate 104b, and the gate dielectric layers 105a and 105b removed to show the structure of the layers 106a and 106b.

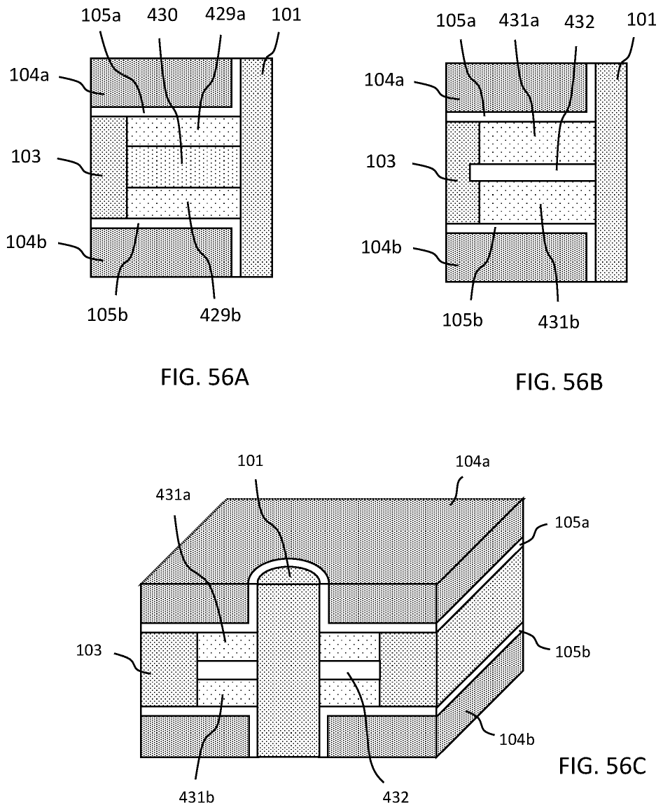

FIG. 56A shows another embodiment of a floating body cell structure constructed according to the invention. This embodiment is similar to the embodiment shown in FIGS. 1A-C except that the floating body of the cell comprises multiple regions, such as regions 429a, 429b, and 430. The regions 429a, 429b, and 430 are formed as semiconductor regions comprising material, such as silicon or polysilicon. In one embodiment, the regions 429a, 429b, and 430 have different types of doping. For example, the regions 429a and 429b have a first type of doping and the region 430 has a second type of doping.

In one embodiment, the first type of doping is P− type of lightly doping and the second type of doping is N+ type of heavy doping. The regions 429a and 429b with P− type of doping form potential wells for the storage of electric charge, such as holes. The region 430 with N+ type of doping forms a channel between the N+ type of bit line 101 and the N+ type of source line 103. The holes stored in the regions 429a and 429b decrease the threshold voltage of the channel region 430.

In another embodiment, the first type of doping is N+ type of doping and the second type of doping is P− type of doping. The regions 429a and 429b with N+ type of doping form channels between the N+ type of bit line 101 and the N+ type of source line 103. The region 430 with P− type of doping forms a potential well for the storage of electric charge, such as holes. The holes stored in the region 430 decrease the threshold voltage of the channel regions 429a and 492b.

FIG. 56B shows another embodiment of a floating body cell structure constructed according to the invention. As illustrated in FIG. 56B, the floating body comprises multiple semiconductor regions, such as region 431a and 431b. The regions 431a and 431b are isolated by an insulting layer 432, comprising material such as oxide or nitride. In one embodiment, the semiconductor regions 431a and 431b have the same type of doping. For example, the semiconductor regions 431a and 431b have P− type of light doping. The region 431a forms a channel under the front gate 104a. The region 431b under the back gate 104b forms a potential well to store electric charge, such as holes. The back gate 104b can be supplied with a negative voltage to attract the holes. The holes stored in the region 431b decrease the threshold voltage of the channel region 431a.

In another embodiment, the semiconductor regions 431a and 431b have the opposite type of doping. For example, the semiconductor regions 431a and 431b have N+ type and P− type of doping, respectively. The N+ type region 431a forms a channel under the front gate 104a. The region 431b under the back gate 104b forms a potential well to store electric charge, such as holes. The back gate 104b can be supplied with a negative voltage to attract the holes. The holes stored in the region 431b decrease the threshold voltage of the channel region 431a.

FIG. 56C shows a 3D cell structure of the cell embodiment shown in FIG. 56B.

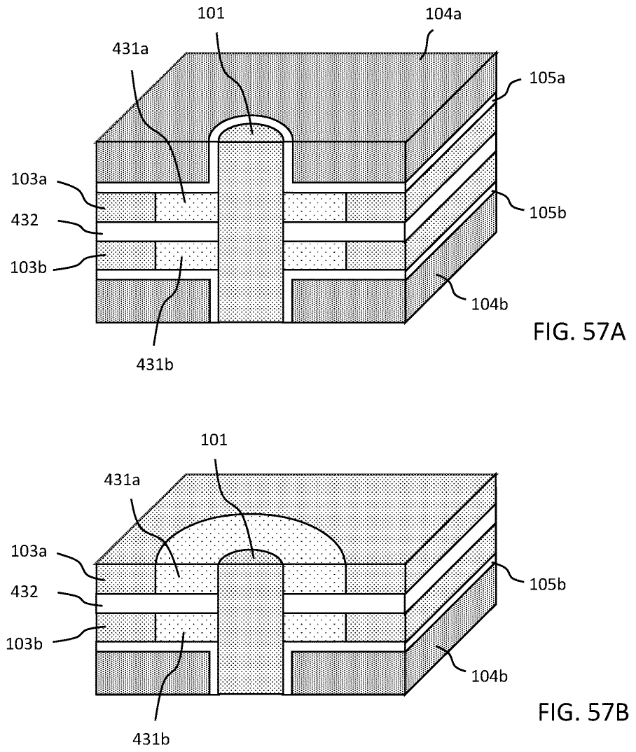

FIG. 57A shows another embodiment of a cell structure constructed according to the invention. This embodiment is similar to the embodiment shown in FIG. 56B except that an insulating layer 432, comprising material such as oxide or nitride, is formed as a continuous layer as shown. The insulting layer 432 divides the floating body into two regions 431a and 431b as shown. The region 431a is coupled to the front gate 104a to form a channel. The region 431b is coupled to the back gate 104b to form a potential well to store electric charges, such as holes. The back gate 104b can be supplied with a negative voltage to attract the holes. The holes stored in the region 431b decrease the threshold voltage of the channel region 431a.

The insulting layer 432 isolates the holes stored in the region 431b from the electrons flowing through the channel 431a to prevent the recombination of the holes and electrons. This configuration increases the data retention time of the cell.

In one embodiment, the regions 431a and 431b have N+ type of doping. The bit line 101 and the source lines 103a and 103b have N++ type of doping. This configuration forms a junction-less transistor cell. In another embodiment, the regions 431a and 431b have P− type of doping. The bit line 101 and the source lines 103a and 103b have N+ type of doping. This configuration forms a traditional transistor cell. In another embodiment, the regions 431a and 431b have P+ type of doping. The bit line 101 and the source lines 103a and 103b have P++ type of doping. This configuration forms a junction-less transistor cell. In another embodiment, the regions 431a and 431b have N− type of doping. The bit line 101 and the source lines 103a and 103b have P+ type of doping. This configuration forms a traditional transistor cell.

FIG. 57B shows the cell structure of FIG. 57A with the front gate 104a and the gate dielectric layer 105a removed.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A 3D stackable memory cell structure, comprising:
first material;
a floating body semiconductor material that surrounds a first portion of the first material;
a second material that surrounds a portion of the floating body semiconductor material;
a front gate material;
a first dielectric layer located between the front gate material and the floating body semiconductor material;
a back gate material;
a second dielectric layer located between the back gate material and the floating body semiconductor material; and
a second semiconductor material that surrounds a second portion of the first material and is directly connected to the floating body semiconductor material.

2. The 3D stackable memory cell structure of claim 1, wherein the second semiconductor material forms a pocket in the floating body semiconductor material and is directly connected to the first material.

3. The 3D stackable memory cell structure of claim 1, wherein the second semiconductor material is located between the first material and the floating body semiconductor material.

4. The 3D stackable memory cell structure of claim 1, wherein the second semiconductor material is formed as an isolated island region that is inside and directly connects to the floating body semiconductor material.

5. The 3D stackable memory cell structure of claim 1, wherein the second semiconductor material is formed as a layer located between the floating body semiconductor material and the second dielectric layer.

6. The 3D stackable memory cell structure of claim 1, wherein the second semiconductor material is formed as a well located between the floating body semiconductor material and the second material.

7. The 3D stackable memory cell structure of claim 1, wherein the second semiconductor material is formed as a layer located between the floating body semiconductor material and the second material, and wherein at least a portion of the second semiconductor material extends between the floating body semiconductor material and at least one of the first and second dielectric layers.

8. The 3D stackable memory cell structure of claim 1, wherein the second semiconductor material is formed in a horseshoe shape within the floating body semiconductor material, wherein the second semiconductor material has two surfaces that directly connect to the first material, and wherein the second semiconductor material divides the floating body semiconductor material into two regions.

9. The 3D stackable memory cell structure of claim 1, wherein the second semiconductor material is formed in a horseshoe shape within the floating body semiconductor material, wherein the second semiconductor material has two surfaces that directly connect to the first material, wherein the second semiconductor material has internal surfaces between the two surfaces, and wherein the first material extends to directly connect to the internal surfaces of the second semiconductor material.

10. The 3D stackable memory cell structure of claim 1, wherein the first material forms a vertical bit line and the second material forms a source line.

11. The 3D stackable memory cell structure of claim 1, wherein the second semiconductor material comprises silicon germanium (SiGe) material and the floating body semiconductor material comprises silicon (Si) material.

12. The 3D stackable memory cell structure of claim 1, wherein the floating body semiconductor material and the second semiconductor material each comprise selected semiconductor material that is selected from silicon (Si), polysilicon (Poly-Si), germanium (Ge), silicon germanium (SiGe), gallium nitride (GaN), gallium-arsenide (GaAs), indium silicon (InSi), germanium indium (GeIn), indium gallium arsenide (InGaAs), silicon carbide (SiC), and Indium gallium zinc oxide (IGZO).

13. The 3D stackable memory cell structure of claim 1, wherein the floating body semiconductor material and the second semiconductor material have the same type of doping.

14. The 3D stackable memory cell structure of claim 1, wherein the second semiconductor material comprises heavily doped P+ silicon germanium, the floating body semiconductor material comprises lightly doped P− silicon, the first material and the second material comprise heavily doped N+ silicon.

15. The 3D stackable memory cell structure of claim 1, wherein the first material comprises one of semiconductor or conductor material and the second material comprises one of semiconductor or conductor material.

16. A 3D stackable memory cell structure, comprising:
a first material;
an insulating layer that surrounds a first portion of the first material;
a first floating body semiconductor material that surrounds a second portion of the first material and is located above the insulating layer;
a second floating body semiconductor material that surrounds a third portion of the first material and is located below the insulating layer;
a second material that surrounds the first floating body semiconductor material;
a third material that surrounds the second floating body semiconductor material;
a front gate material;
a first dielectric layer located between the front gate material and the first floating body semiconductor material;
a back gate material; and
a second dielectric layer located between the back gate material and the second floating body semiconductor material.

17. The 3D stackable memory cell structure of claim 16, wherein the first material forms a vertical bit line and the second and third materials form source lines.

18. The 3D stackable memory cell structure of claim 16, wherein the insulating layer forms a continuous layer and comprises an oxide material or a nitride material.

19. The 3D stackable memory cell structure of claim 16, wherein the first material comprises one of semiconductor or conductor material, the second material comprises one of semiconductor or conductor material, and the third material comprises one of semiconductor or conductor material.

21. The 3D stackable memory cell structure of claim 16, wherein the insulating layer directly connects to the first portion of the first material.

22. The 3D stackable memory cell structure of claim 16, wherein the first floating body semiconductor material directly connects to the second portion of the first material and the insulating layer.

23. The 3D stackable memory cell structure of claim 16, wherein the second floating body semiconductor material directly connects to the third portion of the first material and the insulating layer.

24. The 3D stackable memory cell structure of claim 16, wherein the first dielectric layer directly connects to the front gate and the first floating body semiconductor material.

25. The 3D stackable memory cell structure of claim 16, wherein the second dielectric layer directly connects to the back gate and the second floating body semiconductor material.

26. A 3D stackable memory cell structure, comprising:
a first material;
an insulating layer that surrounds a first portion of the first material;
a first floating body semiconductor material that surrounds a second portion of the first material and is located above the insulating layer;
a second floating body semiconductor material that surrounds a third portion of the first material and is located below the insulating layer;
a second material that surrounds the first floating body semiconductor material, the second floating body semiconductor material, and the insulating layer;
a front gate material;
a first dielectric layer located between the front gate material and the first floating body semiconductor material;
a back gate material; and
a second dielectric layer located between the back gate material and the second floating body semiconductor material.

27. The 3D stackable memory cell structure of claim 26, wherein the first material forms a vertical bit line and the second material forms a source line.

28. The 3D stackable memory cell structure of claim 26, wherein the insulating layer forms a continuous layer and comprises an oxide material or a nitride material.

29. The 3D stackable memory cell structure of claim 26, wherein the first material comprises one of semiconductor or conductor material and the second material comprises one of semiconductor or conductor material.

30. The 3D stackable memory cell structure of claim 26, wherein the insulating layer directly connects to the first portion of the first material.

31. The 3D stackable memory cell structure of claim 26, wherein the first floating body semiconductor material directly connects to the second portion of the first material and the insulating layer.

32. The 3D stackable memory cell structure of claim 26, wherein the second floating body semiconductor material directly connects to the third portion of the first material and the insulating layer.

33. The 3D stackable memory cell structure of claim 26, wherein the first dielectric layer directly connects to the front gate and the first floating body semiconductor material.

34. The 3D stackable memory cell structure of claim 26, wherein the second dielectric layer directly connects to the back gate and the second floating body semiconductor material.

35. The 3D stackable memory cell structure of claim 26, wherein the second material directly connects to the first floating body semiconductor material, the second floating body semiconductor material, and the insulating layer.
